(19) United States
(12) Patent Application Publication
(10) Pub. No.: US 2026/0006942 A1
(43) Pub. Date: Jan. 1, 2026

(54) PATTERNED OPTOELECTRONIC DEVICE

(71) Applicant: FUSION BIONIC GMBH, Dresden (DE)

(72) Inventors: Tim KUNZE, Dresden (DE); Sabri ALAMRI, Dresden (DE)

(21) Appl. No.: 19/108,187

(22) PCT Filed: Sep. 4, 2023
(86) PCT No.: PCT/EP2023/074186

§ 371 Date: Mar. 3, 2025

(30) Foreign Application Priority Data
Sep. 2, 2022 (LU) 103002
Sep. 2, 2022 (LU) 103003
Sep. 2, 2022 (LU) 103004

(51) Int. Cl. H10F 77/30; B23K 26/067; B23K 26/362; B23K 101/40; H10F 71/00; H10H 20/01; H10H 20/84

(52) U.S. Cl. CPC H10F 77/315; B23K 26/0676; B23K 26/362; H10F 71/134; H10H 20/034; H10H 20/84; B23K 2101/40

(57) ABSTRACT

The present invention relates to an optoelectronic device comprising a substrate, in particular a cover layer, an optoelectronically active layer and a contacting layer, the outer and/or inner surface of which has a patterned region with a dot structure of cones or inverse cones. With such a dot structure, the optical properties and wetting properties of the optoelectronic device can be advantageously adjusted in a targeted manner. In particular, it is possible to improve light coupling into or light extraction from optoelectronic devices and thus efficiency. The invention also relates to an optoelectronic module, a method of manufacturing an optoelectronic device and the use of a patterned substrate for an optoelectronic device.

### TECHNICAL FIELD

The present invention relates to an optoelectronic device comprising a substrate, in particular a cover layer, an optoelectronically active layer and a contacting layer, whose outer and/or inner surface and/or in the volume, in particular within a plane in the volume, has a patterned region with a dot structure of cones or inverse cones. The optical properties and wetting properties of the optoelectronic device can be advantageously adjusted in a targeted manner by means of such a dot structure. The invention also relates to an optoelectronic module, a method of manufacturing an optoelectronic device and the use of a patterned substrate for an optoelectronic device.

Optoelectronic devices are used both for environmentally friendly energy generation using sunlight and for the efficient generation of electromagnetic radiation. As one of the most important issues for the technology of the future is the generation of energy from renewable sources in conjunction with the efficient use of the energy generated, optoelectronic devices offer great potential.

A departure from fossil fuels should both reduce dependence on natural resources and reduce or avoid the climate-damaging emissions, so photovoltaic devices, also known as photovoltaic cells or solar cells, can make an important contribution here. Photovoltaics is already a widely used technology for generating energy by converting electromagnetic radiation into electrical energy. In the form of photovoltaic cells and modules consisting of several photovoltaic cells, individual devices are used in technical devices for direct power supply as well as large systems for the general generation of electrical energy.

In addition to energy generation, another starting point for the energy transition is saving electrical energy by using efficient appliances and light sources. For example, the use of light-emitting diodes (LEDs) has already enabled inefficient light sources such as light bulbs to be replaced.

Both in the case of energy generation using electromagnetic waves and in the case of light sources emitting electromagnetic waves, the efficiency of the technology is heavily dependent on how well the electromagnetic waves can be coupled into the Device (photovoltaics) or out of the Device (LEDs). The transmission of light through the outer layers of the device is therefore a basic problem, the solution of which strongly influences the efficiency of such devices. Reflection from the layer materials at the interface(s) and absorption processes due to the presence of dirt particles are relevant to the impairment of efficient light yield.

It is known, for example, from Klemens Ilse et al. (“Techno-Economic Assessment of Soiling Losses and Mitigation Strategies for Solar Power Generation” from Joule 3, pages 2303-2321 Oct. 16, 2019, Elsevier Inc.) that soiling of photovoltaic systems with photovoltaic modules leads to efficiency losses of at least 3% to 4%. This already results in an economic loss of 3 to 5 billion euros. Taking into account further costs, such as the very costly cleaning of such systems, some estimates also assume values of up to 7 billion euros.

Reflection losses, which occur at the existing interfaces, also reduce the proportion of electromagnetic radiation used or to be used.

### PRIOR ART

There are various approaches to optimizing the devices in order to improve the proportion of electromagnetic waves that can penetrate the outer layers and thus optimize the optical properties of the devices.

For example, the encapsulations of photovoltaic devices are provided with an anti-reflection coating. Patterned anti-reflection films are also known, which are subsequently applied to the devices and ensure a larger proportion of the light is coupled into photovoltaic devices, thus increasing their efficiency.

An anti-reflection coating, which can also be used for solar cells, is also described in DE 196 42 419 A1. A porous coating comprising an anti-reflection effect is applied. Disadvantageously, the materials used are environmentally harmful and high-cost. This negatively impacts both the ecological and economic balance of photovoltaic systems.

Furthermore, coatings are also used to generate anti-soiling properties of the devices. For example, such anti-soiling coatings are applied to the front glass. Disadvantageously, such coatings have to be applied in addition to the other layers, which is time-consuming and cost-intensive. Technologically, it is imperative to also optimize such coatings with anti-soiling properties for optical effects. If only anti-soiling properties are optimized, there is a risk of loss of efficiency due to, for example, strong reflection caused by the use of the additional material layer.

However, coatings optimized in many respects are also known. For example, Jaesung Son, et al. (“A practical superhydrophilic self-cleaning and antireflection surface for outdoor photovoltaic applications” from Solar Energy Materials and Solar Cells, Volume 98, March 2012, pages 46-51) also describe a lithographic process generating nanostructures by etching using an applied coating and a mask placed on top. The resulting coating ensures the surface exhibits superhydrophilic and therefore self-cleaning properties as well as an anti-reflection effect. The generation of such a coating is disadvantageously very complex. Furthermore, the materials used for the coating, as well as those for the etching process, are high-cost and environmentally harmful.

US 2016/293781 A1 shows three-dimensional structures on solar cells that have anti-reflection properties as well as hydrophobic properties. These are used to increase light coupling in solar cells and improve efficiency. To generate the structure, a nanoindentation arrangement is imprinted on the surface of an electrochemically polished aluminum foil layer. A type of stamp is used to generate the structures by means of silicon nanopillars arranged in a hexagonal pattern using chemical wet etching. The structures generated have the disadvantage of an uneven surface due to the etching process, which reduces the reproducibility of the effects. Furthermore, the process used here is not versatile, as a new stamp arrangement is required for each adjustment of the structure sizes.

A solar cell using a substrate in which an anti-reflection nanostructure is integrated is described in KR 2012 0060185 A. A manufacturing method is disclosed herein which aims to minimize the amount of reflected light generated due to a refractive index difference between a substrate and air. For this purpose, an anti-reflection nanostructure with a pitch or an average distance below an optical wavelength is formed on a substrate of a solar cell. The anti-reflection nanostructure is arranged periodically or aperiodically on both sides of a substrate and has an average distance below an optical wavelength. A transparent conductive oxide layer is formed on the substrate and an amorphous silicon layer of the p-i-n type is arranged on the transparent conductive electrode layer. A reflective layer is then formed on the back of the p-i-n type amorphous silicon layer. A corresponding structure for use on a cover layer or on a protective layer is described in KR 2012 0060182 A.

A DLIP process used to pattern a layer of aluminium-zinc oxide (AZO) is described in A. Lasagni, et al. (“High speed surface functionalization rising direct laser interference patterning, towards I m2/min fabrication speed with sub-pm resolution”, Proc. Of SPIE Vol. 8968 8968012-1, 2014 SPIE). Laser interference patterning is performed here either with two partial beams or via a diffractive beam splitter (DBS), resulting in a plurality of partial beams. The resulting structures are either linear or hexagonal. To generate the hexagonal structures, line interference patterns are generated one after the other at a rotation angle of 60°. The disadvantage of this method is that it requires multiple irradiation. It is therefore complex and error-prone. To set the interference period, suitable lenses with corresponding focal lengths are used in the method presented here. The disadvantage of this is that the interference periods can only be set for the existing lenses and must be readjusted as soon as the interference period is adjusted.

In document US 2018/006166 A1, a process is described in which a metal-based solar absorber is produced. The process described here can be used to selectively improve the solar absorption capacity. Furthermore, optimized thermal stability can be achieved. A laser interference lithography process is used for this, in which a structure is etched into the material through a mask created. The disadvantage is the generation of uneven structures and using toxic materials for the process.

An anti-reflection coating, in particular for solar cells, is disclosed in JP 2010 219495 A. The structures described have spacings of less than 400 nm or even less than 150 nm. Various methods are mentioned for generating the structures. For example, electron beam writing or laser interference for patterning is mentioned. The disadvantage of these methods is that they are generally complex and slow.

EP 1 630 612 A2 describes an interference patterning process in which two superimposed partial beams are used for patterning. The laser wavelength used is at wavelengths shorter than that of visible light. However, a light-sensitive film is patterned here, which then serves as a mask for etching. The disadvantage of etching is the generation of uneven structures and using toxic materials for the process.

Structures that lead to anti-reflection properties on a surface are also disclosed in EP 2 056 129 A1. However, the process used here is very complex and therefore slow and inefficient. In addition, the structure parameters can only be varied with great effort.

### Objective

The objective of the present invention is therefore providing an optoelectronic device with improved efficiency, which can be generated by a simple process.

In addition, it is the objective of the present invention to improve the optical properties of the optoelectronic device, wherein the surface of the optoelectronic device is robust, in particular with respect to external influences such as the environment and weathering, and the degradation of the materials over time is only slight.

Furthermore, it is the objective of the present invention to provide a method with which such optoelectronic devices can be generated in a targeted and reliably reproducible manner with predetermined properties.

### Solution

The objective is fulfilled by an optoelectronic device with the features of claim 1 as well as a module and a method with the features of the subsidiary claims. Further advantageous embodiments can be found in the subclaims, the description and the embodiment examples.

The objective is reached in particular by an optoelectronic device comprising the following:
a cover layer comprising an outer surface and an inner surface. The cover layer is at least partially transparent, preferably transparent, and the outer surface of the cover layer is designed to seal off the optoelectronic device from the environment. Furthermore, the optoelectronic device comprises at least one functional layer, which is preferably an optoelectronically active layer or a contacting layer, which is arranged at least partially on the inner surface of the cover layer. The functional layer is thus preferably arranged adjacent to the cover layer.

In the context of the invention, functional layers are layers which are essential for the function of an optoelectronic device. This includes the boundary layers, the optoelectronically active layers with p-n junctions or optional barrier layers or, according to the definition, the contacting layers.

According to the invention, the outer surface and/or the inner surface and/or in the volume, in particular within a plane in the volume, of the cover layer is formed from a patterned region and an unpatterned region. The patterned region has a first periodic dot structure and the first dot structure is formed from at least one first interference pixel (10) with a first interference period (p1). The first interference pixel (10) has a periodic lattice of at least three, preferably seven, particularly preferably 19, cones or inverse cones with a first interference period (p1). The interference period of the first periodic dot structure is in the region of 50 nm to 50 μm, i.e. in the micro- or sub-micrometer range.

The patterned region is formed by the different structures applied. These can be a single dot structure, several superimposed dot structures or even superimposed dot and line structures. Even if the patterned region consists of several individual patterned sub-regions, such as individual cones, which are not necessarily connected to each other, the entire portion of the surface that is patterned, whose surface has consequently changed due to treatment by means of a laser interference process, is regarded as a patterned region for the purposes of the invention. Each surface can therefore only have one patterned region.

Any part of the surface that cannot be assigned to the patterned region is then considered to belong to the unpatterned region.

According to a preferred embodiment of the invention, the invention relates to an optoelectronic device comprising at least the following components or layers
an optoelectronically active layer, a contacting layer and/or a cover layer, each of which comprises an outer surface and an inner surface independently of one another, wherein the optoelectronically active layer, the contacting layer and/or the cover layer (also in the patterned state) is at least partially transparent,
at least one functional layer which is arranged or applied at least partially on the inner and/or outer surface of the optoelectronically active layer, the contacting layer and/or the cover layer,
wherein the outer surface and/or inner surface of the optoelectronically active layer, the contacting layer and/or the cover layer are each formed independently of one another from a patterned region and an unpatterned region,
wherein the patterned region has a first periodic dot structure,
wherein the first dot structure is formed from at least one first interference pixel (10) with a first interference period (p1),
wherein the first interference pixel (10) comprises a periodic lattice of at least three cones or inverse cones,
wherein the interference period of the first periodic dot structure is in the region of 50 nm to 50 μm.

According to a preferred embodiment, the first interference period of the first periodic dot structure is in the region of 100 nm to 1,000 nm. Preferably, this allows the anti-reflection properties of the substrate, in particular the optoelectronically active layer, the contacting layer and/or the cover layer (as defined herein) to be adjusted.

According to a preferred embodiment, the first interference period of the first periodic dot structure is in the region of 200 nm to 50 μm, wherein the water contact angle of the outer surface of the cladding layer is less than 20° or greater than 150°. Hereby, the anti-soiling properties as well as the wetting properties of the cover layer (as defined herein) can be adjusted.

The present invention is based on the realization that the properties, in particular the transmission, of a surface can be positively influenced by applying a patterned region and that the light coupling into or light extraction from optoelectronic devices can be improved without the need to apply an additional layer.

In photovoltaic cells, optimized light coupling leads directly to an increased short-circuit current. As the materials generally do not need to be changed for this and therefore the layer transitions are not affected, especially if the outer surface of the cover layer is patterned, the fill factor of the current-voltage characteristic is not reduced. As the light extraction is also improved accordingly, this also applies to light-emitting devices. A core problem of photovoltaics and light-emitting devices, the compromise between improved transparency with as little change as possible, in particular no increase in sheet resistance, can thus be addressed. An optoelectronic device according to the invention with a cover layer having dot structures leads to increased efficiency, since the optical properties are improved due to a higher proportion of electromagnetic waves penetrating the cover layer, without reducing the electrical properties of the optoelectronic device.

A characteristic feature of the present patterned cover layer is that the patterned region has lattice structures. Cones or inverse cones are arranged periodically to each other at least in sections.

### General Advantages

The patterning of surfaces and/or interfaces of substrates of optoelectronic devices as described herein can advantageously be used to specifically influence the optical properties of the surface or interface or the properties of the surface when wetted with liquids, such as water, or also with respect to small particles.

The optical properties are preferably influenced in such a way that a larger proportion of the incident electromagnetic radiation, e.g. visible light, passes through a plane of the substrate, in particular the surface of the substrate. Thus the proportion of electromagnetic radiation passing through this surface can be increased. A possible patterning increases this proportion due to a changed, preferably gradual, refractive index of the substrate, which reduces the reflection at the surface. Furthermore, an applied grating leads to diffraction effects and a deflection of the direction of propagation of the light, i.e. the electromagnetic waves. This brings great advantages for photovoltaic devices and photovoltaic modules, as the path the light travels within the optoelectronically active layers is increased. As a result, a larger proportion of the incident light can be absorbed and a larger number of charge carriers are created, which improves the efficiency of the photovoltaic device or photovoltaic module. However, it is also possible to generate a structure which increases the proportion of electromagnetic radiation passing through the surface by multiple reflection within an inverse cone, leading to a kind of trap effect in which each time the electromagnetic wave strikes a point on the surface, particularly within the inverse cone, a further portion of the electromagnetic radiation passes through this surface.

Furthermore, the wetting properties of the surface can be advantageously adjusted so hydrophilic or superhydrophilic or even hydrophobic or superhydrophobic properties of the surface are generated. This allows anti-fogging effects, i.e. anti-coating effects and anti-soiling effects, to be generated on the surface of the cover layer. Furthermore, the grip or adhesion properties of the surface can be adapted by customizing the surface structure. In this way, the surface patterning can be specifically generated so that the adhesion of solid particles to the surface is reduced. In conjunction with the optimized wetting properties, dirt particles are thus washed off expeditiously.

Furthermore, the structure can be applied/generated directly (i.e. without the need to apply the structure indirectly via another layer) to a surface of a cover layer of an optoelectronic device. Since the patterning is not dependent on the refractive index or the adhesion of certain coating materials to the optoelectronic device, this structure can therefore be used more flexibly than conventional chemical structuring or nanostructuring, in which metal gratings have to be applied to the arrays.

The stability of the dot structures generated in this way should also be mentioned, as they are more resistant than conventional coatings because they are applied directly to the surface of a cover layer of an optoelectronic component and/or incorporated into the optoelectronic component and cannot become (detached) from the surface to be coated over time and the material stress caused by use, in particular mechanical material stress. In addition, the structures are resistant to chemicals such as solvents and glass cleaners.

If the patterning is carried out in the volume, i.e. inside a substrate of the optoelectronic component, in particular in the transparent or partially transparent or translucent cover layer, the resulting patterning (i.e. the dot structure of the patterned substrate) is less sensitive to impact and abrasion than conventional coatings. Texturing, i.e. the insertion of a dot structure inside or in the volume of the material, is interesting for applications such as product protection, optical data storage, decoration, etc. Even if texturing inside a component or inside a layer does not lead to an improvement in anti-fogging or anti-soiling properties, the diffraction efficiency can still be increased due to the interaction of the light with the structure inside. Thus, a layer, in particular cover layer and/or functional layer with anti-reflection properties can also be achieved.

In contrast to conventional methods (such as etching, sandblasting, polymer coatings) for applying/introducing a structure (e.g. roughness) to a substrate, a further advantage of the optoelectronic component with patterned cover layer defined herein or the application method is that only certain sections/regions of a layer of a cover layer can be patterned in a targeted and/or partial manner without great effort. For example, the time-consuming preparation and arrangement of a mask for application to a surface to be textured, which for example shields/protects certain regions of the surface from treatment, can be dispensed with. In addition, the structure parameters (e.g. the interference period, the structure depth, the diameter, the shape and the size of the inverse cones) and thus also the associated properties can be adapted in a targeted and customized manner.

Further advantageous embodiments and further developments are shown in the sub-claims and in the description with reference to the figures.

### DETAILED DESCRIPTION OF THE INVENTION

### Effects

It is an object of the present invention to provide patterned regions on surfaces and/or in the volume, in particular within a plane in the volume, of optoelectronic devices or optoelectronic modules, such as the optoelectronically active layer, the contacting layer and the cover layer, and thereby to adjust the optical effects and/or the wetting effects of these devices or modules, in particular their layers. It is understood that the adjustment of the optical effects, in particular the anti-reflection properties, the reduction of reflection due to the trap effect and light path lengthening due to diffraction at the grating (each as defined herein) as well as the adjustment of the wetting effect by forming suitable patterned and unpatterned regions on the outer surface and/or inner surface and/or in the volume, in particular within a plane in the volume, of a substrate (as defined herein), in particular the functional layer (such as optoelectronically active layer, boundary layer), the contacting layer and the cover layer can each be adjusted independently of one another. Accordingly, the structure parameters, in particular the interference periods, the structure depths, the diameters of the base area of the cones or inverse cones, the proportion of the surface patterned in this way and/or within a plane in the volume of each layer, the degree of disorder within a patterned region as well as the periodicity or non-periodicity of the global dot structure on the outer surface and/or inner surface and/or in the volume can be set independently of one another, in particular within a plane in the volume, of a substrate, in particular the functional layer (such as optoelectronically active layer, boundary layer), the contacting layer and the cover layer, can each be set independently of one another, so that the individual sections herein, even if they are formulated specifically for one layer, can also be related to the other layers of the optoelectronic component or the optoelectronic module.

### Optical Effects

By patterning a cover layer of an optoelectronic component, preferably a photovoltaic cell, also known as a solar cell, or a light-emitting diode, also known as an LED, different effects can be achieved on the cover layer, which can improve the efficiency of the optoelectronic components during operation in particular. A key aspect of photovoltaic cell technology is to optimize the coupling of light into the optoelectronically active layer. As the number of charge carriers generated increases with an increase in the number of coupled photons, i.e. light particles, the electrical current generated can be increased by improving the coupling of the light into the optoelectronically active layer. In contrast, the efficiency of light-emitting diodes increases with improved light extraction. In either case, improved passage of the electromagnetic radiation, i.e. the light, through the cover layer of the optoelectronic component is crucial.

Therefore, the proportion of light reflected at the surface or interface is advantageously reduced, as a result of which a higher proportion reaches the optoelectronically active layer. Two different effects can be used for this, which can be achieved by different patterning, i.e. also with different interference periods or structure depths.

### Wetting Effects

An improvement in light input or light output can also be achieved by avoiding effects that prevent efficient transmission at the surface or interface. For example, anti-soiling properties on the outside of the cover layer can ensure that fewer dirt particles lead to impairments. Such wetting effects are based on hydrophilic or superhydrophilic or on hydrophobic or superhydrophobic surfaces. Optimization of the wetting properties primarily plays a role on the surface of the optoelectronic component. On a superhydrophobic surface, for example, the lotus effect takes effect on contact with a liquid, preferably water, and small dirt particles adhere to the drops of liquid that move along the surface and are repelled by the surface. Superhydrophilic surfaces also exhibit such an effect, whereby a uniform film of liquid removes the dirt particles.

### Optoelectronic Device

The optoelectronic device basically has at least one optoelectronically active layer and at least two contacting layers which are suitable for conducting the charge carriers into the optoelectronic device, as in the case of a light-emitting diode, or out of the optoelectronic device, as in the case of a photovoltaic cell. For the purposes of the invention, an optoelectronic device is a single optoelectronic cell, wherein an optoelectronic module is formed from several (i.e. at least two) optoelectronic cells. By connecting a plurality of optoelectronic cells in series, the achieved efficiency of the emission and/or absorption of electromagnetic radiation within a module can be improved, in particular increased.

The optoelectronic device (device for short) can be a radiation-emitting device or a photovoltaic device.

The optoelectronic device may be a photovoltaic device, a light emitting diode (LED) or an organic photodiode (OPD), wherein the optoelectronically active layer is correspondingly formed as a region which can emit and/or absorb electromagnetic radiation, preferably light, during operation. The light may be in the spectral region optically visible to humans or in the region of infrared or ultraviolet radiation, as defined herein. Optoelectronic devices that emit electromagnetic radiation, preferably light, can be, for example, light emitting diodes (LEDs) or organic light emitting diodes (OLEDs). An electromagnetic radiation-absorbing optoelectronic device can be, for example, a solar cell or a photodiode, e.g. an organic photodiode (OPD) or organic photocell.

A radiation-emitting component in the sense of the invention is a single radiation-emitting cell, whereby a radiation-emitting module is formed from several (i.e. at least two) radiation-emitting cells. By connecting several radiation-emitting cells in series, the achieved emission of electromagnetic radiation within a module can be improved, in particular increased.

For the purposes of the invention, a photovoltaic component is a single photovoltaic cell, wherein a photovoltaic module is formed from several (i.e. at least two) photovoltaic cells. By connecting several photovoltaic cells in series, the voltage achieved within a module can be improved, in particular increased.

According to one embodiment of the invention, an optoelectronic device is designed as a layer stack, the layers of which are arranged adjacent to one another in a stacking direction (S) and wherein the layer stack comprises at least three layers extended over a surface, in particular a first layer terminating the optoelectronic device (herein also referred to as “first terminating layer”), a second layer terminating the optoelectronic device (herein also referred to as “second terminating layer”) and a functional layer arranged or applied between the first and the second terminating layer, the functional layer preferably being an optoelectronically active layer or a contacting layer.

According to a preferred embodiment, the first or the second terminating layer is formed as a cover layer of the optoelectronic device, wherein according to the preceding selection (i.e., whether the first or the second terminating layer is the cover layer) the other terminating layer is preferably formed as a carrier layer. In this case, it may be provided that the functional layer is an optoelectronically active layer, wherein a contacting layer may be arranged in the stacking direction (S) between the cover layer and the optoelectronically active layer as well as between the optoelectronically active layer and the carrier layer, in each case independently of one another, in accordance with the preceding selection.

According to a further embodiment, the optoelectronic device can be rigid or mechanically flexible (so that the optoelectronic device can therefore be unrolled or rolled up non-destructively from a roll). According to a further development, the optoelectronic device is designed to be flexible and/or non-destructively bendable. For example, the optoelectronic device is a flexible organic light-emitting diode (OLED).

Preferably, the substrate, in particular the optoelectronically active layer, the contacting layer and/or the cover layer, is flexible, preferably in the form of a film. This allows the substrate to be easily adapted to the optoelectronic device. The deformability of optoelectronic devices made of flexible materials, such as organic semiconductors, is thus advantageously maintained.

The objective is also solved by an optoelectronic module which has at least two optoelectronic devices according to the invention which are in electrical contact with one another. Each optoelectronic device can have a separate cover layer. Thus, optoelectronic devices according to the invention can be connected to form an optoelectronic module. However, it is also possible to achieve the advantages of the invention if at least two optoelectronically active (partial) layers are arranged on a cover layer to form a (separate/independent) optoelectronic device in each case. This can lead to a more efficient manufacturing process.

### Optoelectronically Active Layer

The optoelectronic device has at least one functional layer. For the purposes of the invention, the functional layer is a substrate which has or consists of at least one optoelectronically active layer which is suitable for generating or detecting electromagnetic radiation or for converting electromagnetic radiation into electric current. The electromagnetic radiation may be, for example, light in the visible region, UV light and/or infrared light (each preferably as defined herein).

For the purposes of the invention, an optoelectronically active layer is a layer, which can also be formed as a layer stack, which consists of materials or material combinations which, due to their properties, allow a conversion of electrical energy into electromagnetic waves or photons or vice versa. A possible suitable base material is, for example, silicon as an inorganic semiconductor. Organic semiconductors and/or typical materials of thin-film solar cells, such as CdTe, are also possible.

According to one possible embodiment, the optoelectronically active layer comprises a layer structure based on heterojunction technology. In heterojunction technology, at least a first optoelectronically active layer and a second optoelectronically active layer are applied adjacent to each other. It is characterized by the energy levels, in particular the band gap, differing. The first optoelectronically active layer and the second optoelectronically active layer can be made of two different materials, for example GaAs and InGaAs. Another possibility is using the same material in the layers, which is present in different crystalline forms. For example, one embodiment of a heterojunction provides for the first optoelectronically active layer to be made of crystalline silicon and the second optoelectronically active layer to be made of amorphous or polycrystalline silicon. Further layers, for example a third optoelectronically active layer, can also be arranged within the heterojunction. In each case, two adjacent layers of the heterojunction have different energy levels. This allows charge carriers to be generated more efficiently and transported to the outer contacts. This has the advantage of increasing the efficiency of the optoelectronic device.

According to a particularly advantageous embodiment of the invention, the optoelectronic device comprises an optoelectronically active layer according to the technology of heterojunction using silicon, as proposed for example in U.S. Pat. No. 5,648,675 A.

Preferably, the optoelectronic device comprises as optoelectronically active layer a first layer which is formed from a crystalline, doped, preferably n-doped or p-doped, particularly preferably n-doped, layer. Furthermore, a second layer adjacent to the first layer is provided, which is formed as an amorphous or polycrystalline silicon layer. A third layer of doped and intrinsic, amorphous or polycrystalline silicon is also provided on the side of the first layer facing away from the second layer. Preferably, the second and third layers are thinner than the first layer.

The optoelectronically active layers of the optoelectronic device can comprise various materials, such as inorganic semiconductor materials, for example silicon, cadmium telluride (CdTe), gallium arsenide (GaAs). Other possible materials are organic semiconductor materials, such as organic polymers, conjugated polymers, organic oligomers, organic monomers, organic small, non-polymer molecules (“small molecules”, e.g. fullerenes) or combinations thereof. In addition, perovskites, in particular of the general formula ABX3, can be considered as suitable materials for optoelectronically active layers.

According to one embodiment, the optoelectronically active layer is part of a sequence of optoelectronically active layers, in particular a semiconductor layer sequence. The sequence of optoelectronically active layers may comprise in particular a plurality of optoelectronically active layers of organic semiconductor materials and/or inorganic semiconductor materials, for example electron transport layers, electroluminescent layers and/or hole transport layers.

The optoelectronically active layer can be based on an organic semiconductor material and/or an inorganic semiconductor material. According to one embodiment, the optoelectronically active layer is an inorganic semiconductor material, which preferably comprises silicon, CdTe, GaAs or CIS (CuInS2, copper indium sulfide), CIGS (Cu(In,Ga)(S,Se)2, such as copper indium gallium diselenide or copper indium disulfide).

The optoelectronically active layer can, for example, be formed as a layer of a semiconductor layer sequence.

According to a further embodiment, the optoelectronically active layer, preferably the semiconductor layer sequence, comprises an organic semiconductor material. In particular, the semiconductor layer sequence can comprise a sequence of organic, optoelectronically active layers, so that the optoelectronic device is designed as an organic light-emitting diode (OLED) or as an organic photodiode (OPD).

According to a preferred embodiment of the invention, the optoelectronically active layer comprises a phosphor. The phosphor may, for example, be present in the form of phosphor particles dispersed in a matrix material. Thus, the phosphor can preferably be present as a slurry in the matrix material. This allows a uniform distribution of the phosphor and thus a uniform excitation of the phosphor and also a uniform light emission to be achieved. Silicone, epoxy or a hybrid can be used as matrix material, for example. Epoxy-silicone or silicone-polyester can be used as hybrids.

The phosphor can also be introduced into a matrix material together with scattering particles. This ensures uniform light emission.

The optoelectronic device is preferably designed as a light-emitting diode (LED) or laser diode or photovoltaic cell. According to an advantageous embodiment, the photovoltaic cell is a tandem cell. In such a tandem cell, the efficiency is increased by using different optoelectronically active materials because the different materials absorb particularly well in different regions. Good light coupling is particularly relevant for photovoltaic cells optimized in this way. This effect can be further enhanced by triple cells, in which three different materials contribute to absorption.

According to the invention, the optoelectronically active layer comprises an outer side with an outer surface (herein also referred to as “outer surface”) which, in the sense of the invention (when used as intended), represents an interface facing the cover layer or the environment upstream in the stacking direction (S).

In addition, the optoelectronically active layer comprises an inner side with an inner surface (also referred to herein as “inner surface”) which, in the sense of the invention (when used as intended), represents an interface facing towards the interior of the optoelectronic device, i.e. an interface facing away from the cover layer or environment in the stacking direction (S), environment in the stacking direction (S), wherein the inner surface of the optoelectronically active layer forms the interface between the optoelectronically active layer and the layer upstream in the stacking direction (S) or another component of the optoelectronic device.

According to one embodiment of the invention, the outer surface and/or inner surface and/or volume, in particular within a plane in the volume, in particular the outer surface of the optoelectronically active layer is formed from a patterned region and an unpatterned region (as defined herein), wherein the patterned region comprises a first periodic dot structure, wherein the first dot structure is formed of at least a first interference pixel (10) having a first interference period (p1), wherein the first interference pixel (10) comprises a periodic lattice of at least three cones or inverse cones, wherein the interference period (p1) of the first periodic dot structure is in the micrometer or sub-micrometer range (as defined herein). This has the advantage that the optical properties of the optoelectronically active layer are influenced in such a way that a larger proportion of the incident electromagnetic radiation, for example visible light, at a plane of the optoelectronically active layer, in particular the surface of the optoelectronically active layer, passes through this plane. The proportion of electromagnetic radiation passing through this surface can therefore be increased. A possible patterning increases this proportion due to a changed, preferably gradual, refractive index of the substrate, which, for example, reduces the reflection (as defined herein) at the surface. Furthermore, an applied grating leads to diffraction effects and a deflection of the direction of propagation of the electromagnetic radiation, i.e. the electromagnetic waves. This brings great advantages for photovoltaic devices and photovoltaic modules, for example, as the path the light travels within the optoelectronic device is increased. As a result, a larger proportion of the incident light can be absorbed and a larger number of charge carriers are created, which improves the efficiency of the photovoltaic component or photovoltaic module. However, a patterning can also be generated which achieves an increase in the proportion of electromagnetic radiation traversing the surface by the fact that multiple reflection within an inverse cone leads to a kind of trap effect (as defined herein), in which each time the electromagnetic wave strikes a point on the surface, particularly within the inverse cone, a further portion of the electromagnetic radiation traverses this surface.

According to a further embodiment of the invention, the optoelectronic device can also comprise a boundary layer as a functional layer. In the boundary layer (p-n junction) between the n-type and p-type material, the mobile charge carriers cancel each other out, while the stationary charges (negative in the p-type material and positive in the n-type material) are retained. For this reason, the boundary layer is depleted of mobile charge carriers. Due to diffusion, a positively charged zone forms in the n-doped region and a negatively charged zone in the p-doped region. A space charge zone is therefore formed. The energy of irradiated photons adds energy to existing electrons, turning them into mobile charge carriers that move in the direction of the positively charged zone (an example of an optoelectronically active layer). At the same time, holes are generated, i.e. positively charged, mobile charge carriers, which in turn move in the direction of the negatively charged zone. Thus, the energy of the irradiated photons, i.e. the electromagnetic radiation, causes a flow of charge carriers. For the purposes of the present invention, the boundary layer is also understood as an optoelectronically active layer or can be a component thereof.

The boundary layer can be formed as a dielectric material, whereby the boundary layer can be electrically conductive, in particular through tunnel currents. In order to increase the surface area of the boundary layer to the adjacent optoelectronically active layers and thus improve the active area for charge exchange and consequently the charge exchange itself between n- and p-conductive material, it is suitable to form the boundary layer, in particular the inner and/or outer surface, from a patterned and an unpatterned region, wherein the patterned region comprises a periodic dot structure, in particular a first periodic dot structure as defined herein.

In particular, the possibility that hierarchical patterning (as defined herein) can be generated on the surface of the interface by means of laser pattern application methods, in particular direct laser interference patterning, offers the advantage that the surface available for charge transfer can be “roughened”, for example starting from the micrometer range down to the sub-micrometer range. This has the advantage of forming defined contacts or contact areas where the two surfaces lie against each other. In the regions where pins of one surface are arranged in the inverse pins of a second surface, defined contact areas are created in these regions.

Typical materials for such boundary layers, in particular so-called hole transport layers, can be MoOx, VOx, WOx CuOx and CuSCN or NiOx.

### Contacting Layer

The optoelectronic device preferably comprises at least a “first contacting layer” and a “second contacting layer”, which are suitable for conducting the charge carriers into the optoelectronic device, as in the case of a radiation-emitting device (e.g. a light-emitting diode), or out of the optoelectronic device, as in the case of a photovoltaic cell.

Preferably, the first contacting layer and the second contacting layer directly delimit (i.e. immediately adjacent to) the functional layers of the optoelectronic device, thus representing the direct termination to the functional layers, in particular optoelectronically active layers, in the stacking direction (S).

Preferably, the “first contacting layer” is arranged upstream of the functional layers of the optoelectronic device, in particular the optoelectronically active layers, the second contacting layer and optionally a cover layer, in the stacking direction (S) in the layer sequence.

Preferably, the “second contacting layer” is arranged downstream in the stacking direction (S) in the layer sequence of the first contacting layer and the functional layers of the optoelectronic device, in particular the optoelectronically active layers, and optionally upstream of a cover layer.

The contacting layers are preferably also functional layers, which are used for electronic contacting of the optoelectronically active layer of the optoelectronic device and preferably have a low resistance.

Optionally, the cover layer can be formed as one of the contacting layers and/or be adjacent to a contacting layer.

For the purposes of the invention, a contacting layer is always an electrical contacting layer with an electrical conductivity of at least one electrical conductivity of more than 1 S/cm, preferably 103 S/cm, particularly preferably 104 S/cm. The contacting layers preferably have a specific resistance of less than 10 1 Ωcm, preferably less than 10 2 Ωcm, particularly preferably less than 10 3 Ωcm.

Preferably, further contacting elements, such as metal wires, electrically connected to one of the contacting layers are arranged on the optoelectronic device. Such contacting elements are formed as contact fingers and/or busbars according to one possible embodiment, whereby the busbars ensure the charge carrier transport to the outside. It is also possible to arrange thin metal wires, which form a good compromise between charge carrier transport and low shading. Preferably, such metal wires are embedded in a film, such as in the so-called “smart-wire” technology, whereby the film comprising metal wires can be applied to a module comprising several photovoltaic cells, so that the several photovoltaic cells are then electrically connected by the metal wires. According to an advantageous embodiment, such a film comprising metal wires is the cover layer of an optoelectronic device.

The contacting elements can be formed independently of each other from a substrate and an intermetallic compound arranged on it. Suitable substrates are, in particular, substrates consisting largely of copper, steel or an iron alloy. The intermetallic compound preferably comprises at least one metal selected from the group consisting of Cu, Sn, Ag, Ni, Fe, Ru, Zr, Au or Al or the intermetallic compound is an alloy or an intermetallic compound with one or at least two of these metals. According to a preferred embodiment of the invention, the intermetallic compound contains tin (Sn) and copper (Cu), is an alloy of tin and copper, or consists essentially of tin and copper.

The substrate of the contacting elements may comprise a layer of an intermetallic compound in some areas and surface areas consisting of a metal or a (metal) alloy other than the intermetallic compound in some areas. The layer of the intermetallic compound can have a thickness of 500 nm to 20 μm, in particular 1 μm to 10 μm.

To form this layer of the intermetallic compound on the surface of the substrate, a metal layer comprising at least one metal selected from the group consisting of Cu, Sn, Ag, Ni, Fe, Ru, Zr, Au or Al is preferably applied to the substrate. By means of laser interference patterning, an energy input is generated on the generated surface and thus the formation of an intermetallic compound, preferably comprising at least one metal or at least two metals selected from the group Cu, Sn, Ag, Ni, Fe, Ru, Zr, Au or Al or comprising an alloy with one or at least two of these metals, is stimulated.

This can advantageously achieve a high conductivity, preferably at least 2×104 S/cm, particularly preferably at least 3×104 S/cm. A good conductivity can thus be achieved without using a large amount of expensive metals such as Cu, Sn, Ag, Ni, Fe, Ru, Zr, Au or Al. According to a preferred embodiment, the contacting element may comprise an outer surface and/or inner surface, preferably an outer surface, wherein the outer surface and/or inner surface, preferably an outer surface, is formed of a patterned region and an unpatterned region (each as defined herein), wherein the patterned region comprises a first periodic dot structure, wherein the first dot structure is formed of at least a first interference pixel having a first interference period (p1), and wherein the first interference pixel comprises a periodic lattice of at least three cones or inverse cones. Such a patterning has the advantage that a targeted roughening of the outer and/or inner surface of at least one of the contact partners, e.g. the contacting element, is achieved so that the effective surface, which is provided for the charge exchange or charge transfer between two contact partners, e.g. the contacting element and the contacting layer and/or the collector, is influenced in a targeted manner, in particular, defined contacts or contact areas are generated in this way. This has the advantage of reducing the electrical contact resistance and/or increasing the conductivity.

Contact partners can also be an optoelectronically active layer and a boundary layer arranged adjacent to it.

It is particularly preferable to form regions on the surface of one substrate that are complementary to regions, in particular to the contact area of the surface of the other substrate, which is preferably arranged opposite (so-called Lego principle). This allows an enlarged surface to be generated. Furthermore, the individual adjacent layers can be advantageously fixed together. This is due in particular to the fact that the dot structures allow fewer degrees of freedom in terms of displacement than is the case with line structures, for example.

This also allows defined contacts with specific properties to be formed that fit into one another.

In particular, the possibility that hierarchical patterning (as defined herein) can be generated on the surface of the interface by means of laser pattern application methods, especially direct laser interference patterning, offers the advantage that the surface available for charge transfer can be “roughened”, for example, starting from the micrometer range down to the sub-micrometer range. This has the advantage of forming defined contacts or contact areas where the two surfaces lie against each other. Due to the superimposed quasi-periodic line structures (LIPPS) within the inverse cones of a first surface and/or on the cones of the adjacent second surface, defined contact areas can also be generated in the regions in which cones of the second surface are arranged in the inverse cones of the first surface.

In one embodiment, the contacting layer, in particular the second contacting layer, is formed as a layer that is transparent to radiation generated in an optoelectronically active layer or to radiation incident from outside. The contacting layer particularly preferably contains a transparent conductive oxide (TCO). Transparent conductive oxides are transparent, conductive materials, usually metal oxides such as zinc oxide, tin oxide, cadmium oxide, titanium oxide, indium oxide or indium tin oxide (ITO). In addition to binary metal-oxygen compounds such as ZnO, ZnO:Al, SnO2 or In2O3, ternary metal-oxygen compounds such as Zn2SnO4, CdSnO3, ZnSnO3, MgIn2O4, GaInO3, Zn2In2O5 or In4Sn3O12 or mixtures of different transparent conductive oxides also belong to the group of TCOs. Furthermore, the TCOs do not necessarily correspond to a stoichiometric composition and can also be p-doped or n-doped. Such a contacting layer has the advantage that it can be transparent or partially transparent for radiation generated in the optoelectronically active layer or radiation incident into it.

According to the invention, the second contacting layer comprises an outer side with an outer surface (herein also referred to as “outer surface”), which in the sense of the invention (when used as intended) represents an interface facing the cover layer or the environment—but facing away from the optoelectronically active layer of an optoelectronic device.

In addition, the second contacting layer comprises an inner side with an inner surface (also referred to herein as “inner surface”) which, in the sense of the invention (when used as intended), forms an interface facing towards the interior of the optoelectronic device, i.e. the active region of the optoelectronic device, wherein the surface of the inner side of the second contacting layer forms the interface between the second contacting layer and the preceding layer (e.g. an optoelectronically active layer, as this is upstream in the stacking direction (S)) or another component of the optoelectronic device.

According to one embodiment of the invention, the outer surface and/or inner surface and/or volume, in particular a plane within the volume, of the contacting layer is formed of a patterned region and an unpatterned region (as defined herein), wherein the patterned region comprises a first periodic dot structure, wherein the first dot structure is formed of at least a first interference pixel (10) having a first interference period (p1), wherein the first interference pixel (10) comprises a periodic lattice of at least three cones or inverse cones, wherein the interference period (p1) of the first periodic dot structure is in the micrometer or sub-micrometer range (as defined herein). This has the advantage that the optical properties of the contacting layer, in particular of the second contacting layer, are influenced in such a way that a larger proportion of the incident electromagnetic radiation, for example visible light, passes through a plane of the contacting layer, in particular the surface of the contacting layer, through this plane. The proportion of electromagnetic radiation passing through this surface can therefore be increased. A possible structuring increases this proportion due to a changed, preferably gradual, refractive index of the substrate, which, for example, reduces the reflection (as defined herein) at the surface. Furthermore, an applied grating leads to diffraction effects and a deflection of the direction of propagation of the electromagnetic radiation, i.e. the electromagnetic waves. This brings great advantages for photovoltaic devices and photovoltaic modules, for example, as the path the light travels within the optoelectronically active layers is increased. As a result, a larger proportion of the incident light can be absorbed and a larger number of charge carriers are generated, which improves the efficiency of the photovoltaic device or photovoltaic module. However, a patterning can also be generated which achieves an increase in the proportion of electromagnetic radiation crossing the surface by the fact that multiple reflection within an inverse cone leads to a kind of trap effect (as defined herein), in which each time the electromagnetic wave strikes a point on the surface, particularly within the inverse cone, a further portion of the electromagnetic radiation crosses this surface.

### Cover Layer

In the sense of the invention, a “cover layer” is a substrate, in particular a partially transparent substrate, which is not an optoelectronically active layer in the sense of the invention and is preferably formed to seal off the optoelectronic device from the environment. In this case, the cover layer delimits the optoelectronic device, in particular the functional layers of the optoelectronic device, in at least one spatial direction, preferably in the stacking direction (S), i.e. in the spatial direction in which the individual layers are applied to one another, and in this spatial direction represents the termination to the functional layers, preferably directly with respect to the environment. Depending on the use of the optoelectronic device, the cover layer is designed for the incidence of light into and/or for the emission of light from the optoelectronic device(s). For example, the cover layer in a solar cell is the layer that separates the solar cell from its surroundings/environment and is the first layer through which the light entering the solar cell from outside passes. In contrast, the cover layer in a light-emitting diode (LED) is preferably the layer that separates the light-emitting diode from the surroundings/environment and is the last layer through which the light generated by and from the light-emitting diode passes when viewed from the inside of the light-emitting diode.

According to the invention, the cover layer comprises an outer side with an outer surface (also referred to herein as “outer surface”) which, in the sense of the invention (when used as intended), represents a side which is sealed off from the environment or from the environment surrounding the optoelectronic device, wherein the outer surface of the outer side of the cover layer defines the interface between the cover layer and the environment. For example, the environment surrounding the optoelectronic device is air. However, it may also be provided that the environment surrounding the optoelectronic device is also formed as a further layer, such as a carrier layer, for example if the optoelectronic device is arranged within a complex device, such as an optoelectronic module, preferably a solar cell module. In this case, the further layer adjacent to the cover layer can be one or more encapsulation layers.

Preferably, in the case of a photovoltaic cell, the cover layer forms the terminating layer through which the electromagnetic radiation penetrates into the device.

The cover layer comprises an inner side with an inner surface (also referred to herein as “inner surface”), which in the sense of the invention (when used as intended) represents a side/surface facing the interior of the optoelectronic device, i.e. the surface of the inner side of the cover layer forms the interface between the cover layer and the next following layer (e.g. a contact layer, an optoelectronically active layer, as these follow in the stacking direction (S)) or another component of the optoelectronic device.

The cover layer can also be the carrier layer on which the other functional layers are applied. Optionally, the cover layer is a layer suitable as a contacting layer for a photovoltaic cell, the resistance of which is at least sufficiently low that charge carriers generated can be effectively transported to existing contact fingers. Furthermore, a cover layer suitable as a contacting layer in a light-emitting diode can contribute to the transport of charge carriers to the optoelectronically active materials, in which the conversion of electrical energy takes place by emitting photons or electromagnetic waves.

One possible embodiment provides that both the inner and outer surfaces of the cover layer are formed from a patterned and an unpatterned region. In one possible embodiment, the first periodic dot structure comprises inverse cones on both the inner surface and the outer surface. Advantageously, both the inner surface and the outer surface can thus be patterned directly by means of a laser, preferably by means of a laser interference process, whereby the advantageous properties of the surfaces, in particular also the anti-reflection properties, are generated directly.

According to an alternative embodiment, the first periodic dot structure comprises cones on both the inner surface and the outer surface. Advantageously, both the inner surface and the outer surface can thus be patterned by means of a negative mold comprising inverse cones. As a result, the advantageous properties of the surfaces, in particular the anti-reflection properties, can be generated efficiently in fast processes, for example a roll-to-roll process for processing cover layers formed as films is possible.

A third possibility is that the first periodic dot structure comprises cones on the inner surface and the first periodic dot structure comprises inverse cones on the outer surface. In this way, a reduction in reflection due to the trap effect can be advantageously achieved both on the inner surface and on the outer surface. This reduction in reflection due to the trap effect can be achieved for light coupling from the outside, i.e. when the light first hits the outer surface, then passes through the cover layer and then enters the adjacent layers through the inner surface from the cover layer. This variant is therefore particularly suitable for photovoltaic devices or photovoltaic modules.

According to another possible variant, the first periodic dot structure comprises inverse cones on the inner surface and the first periodic dot structure comprises cones on the outer surface. As a result, a reduction in reflection due to the trap effect can be advantageously achieved both on the inner surface and on the outer surface. This reduction in reflection due to the trap effect can be achieved for light decoupling from the inside to the outside, i.e. when the light first hits the inner surface of the cover layer, then passes through the cover layer and then emerges from the cover layer through the outer surface. This variant is therefore particularly suitable for light-emitting devices or modules in which light, i.e. electromagnetic radiation, is generated within the functional layers.

According to an advantageous embodiment, the cover layer is designed as an optical element or spectral filter element. The optical element can be a spherical or aspherically shaped lens, for example. Embodiments in which the optical element is a stepped lens or a scattering plate are also conceivable. The spectral filter element is designed to minimize or completely eliminate the intensity of unwanted spectral components, e.g. parasitic luminescence (“defect luminescence”). An example of a spectral filter element is an optical short-pass filter or alternatively a band-pass filter with a corresponding lower band edge, which is arranged in the packaging (herein also as encapsulation) or directly in or on an optoelectronic device. The spectral filter element is particularly preferably a Bragg reflector (also Bragg mirror). The Bragg reflector preferably consists of alternating, thin layers of different refractive indices, which usually consist of dielectrics, whereby a part of the electromagnetic wave of the light is reflected at each boundary layer according to Fresnel's formulae. A spectral filter element, in particular a Bragg reflector, can be a stack of layers applied to a substrate. A spectral filter element integrated into the packaging, in particular a Bragg reflector, can be applied to a cover layer as a further layer of the cover layer. The surface and/or the volume, in particular a plane in the volume, of the optical element or spectral filter element can be smooth or patterned, depending on the function of the element. Advantageously, this can further optimize light coupling or light extraction. This further improves the efficiency of the optoelectronic device. Preferably, such an element is arranged on a light-emitting optoelectronic device, for example an LED or a laser diode. This allows the properties of the emitted light to be specifically influenced and adapted to the given application.

Patterning the outer surface and/or inner surface and/or the volume, in particular a plane in the volume, of an optical element or spectral filter element with a patterned and an unpatterned region (as described herein) allows, for example, light coupling into or light extraction from optoelectronic devices to be improved. Thus, it may be provided that a spectral filter element, which is arranged in a radiation-emitting device and is provided for the (back) reflection of certain spectral ranges, e.g. in the UV range, into the radiation-emitting device, is coated on its inner surface (i.e. on the optoelectronic device). the side facing the optoelectronic device) is formed from a patterned and an unpatterned region which allows improved light coupling, in particular by achieving anti-reflection properties and/or reduced reflection due to the trap effect with structure parameters (in each case as defined herein) into the spectral filter element.

Preferably, such a cover layer designed as an optical element or spectral filter element comprises an average structure depth d₅₀ of maximum 2 μm, particularly preferably maximum 1 μm. Advantageously, the properties of the optical element, such as transparency and the influence on the direction of propagation of light or a light beam, hardly change. Thus, the function of the optical element is retained, even if it comprises an outer surface and/or an inner surface with patterned and unpatterned regions. If the inverse cones or cones of the dot structure are additionally formed with side surfaces that form a smooth surface, this effect of retaining the properties of the optical element is further enhanced and the difference, in particular in the transparency, of an optical element with at least one patterned surface and an optical element whose surfaces comprise only unpatterned regions hardly differ, preferably by no more than 10%, preferably 5%.

Another option is to form the cover layer from glass or materials comprising gas. The choice of this material leads to a high transparency and at the same time stable behavior. The glass can be selected from the group consisting of mineral glass, quartz glass, sapphire glass (Al2O3), aluminosilicate glass, zirconia (ZrO2), glass-ceramic systems (composite material made of glass and crystals), such as the MAS system (MgO×Al₂O₃×nSiO2 system), the ZAS system (ZnO×Al₂O₃×nSiO2 system), the LAS system (Li₂O×Al2O3×nSiO2 system) and mixtures thereof.

Optionally, the cover layer is designed as a contacting layer, whereby several cover layers according to the invention can also be arranged on an optoelectronic device, which are separated from each other, for example, by metal wires.

According to a preferred embodiment of the invention, the cover layer is designed as a single-layer or multi-layer cover layer which extends over the optoelectronic module and thus preferably over at least two optoelectronic devices. According to one embodiment, an optoelectronic module comprises several cover layers, each of which extends over at least two optoelectronic devices. The multiple cover layers preferably extend over different optoelectronic devices.

According to one embodiment of the invention, the cover layer can comprise a “first cover layer” and a “second cover layer”, wherein,
the “first cover layer” is arranged downstream of the functional layers in the stacking direction (S) and upstream of the second cover layer and preferably delimits the functional layers of the optoelectronic device directly (i.e. immediately adjacent to the functional layers), and thus represents the direct termination to the functional layers in the stacking direction (S), and
the “second cover layer” is arranged downstream of the functional layers and the first cover layer in the stacking direction (S) and preferably represents the direct termination of the individual upstream layers of the optoelectronic device in the stacking direction with respect to the environment.

Both the first cover layer and the second cover layer comprise an outer surface and an inner surface. Thus, the outer surface and/or the inner surface of the first cover layer and/or the outer surface and/or the inner surface of the second cover layer may be formed of a patterned region and an unpatterned region (as defined herein).

According to a preferred embodiment of the invention, the outer surface and/or the inner surface of the first cover layer is formed of a patterned region and an unpatterned region.

According to a preferred embodiment of the invention, the outer surface and/or the inner surface of the second cover layer is formed of a patterned region and an unpatterned region. With the aid of a patterning of the outer surface and/or the inner surface of the second cover layer as described herein, the optical properties of the surface or interface or the properties of the surface when wetted with liquids, such as water, or also with respect to small particles can be advantageously influenced in a targeted manner. For example, the outer surface of the second cover layer may be formed from a patterned and an unpatterned region, in particular to form anti-reflection properties and/or anti-soiling properties (as defined herein).

According to a preferred embodiment of the invention, at least the inner surface of the first cover layer and the outer surface of the second cover layer are formed from a patterned and an unpatterned region (as defined herein). In this case, it is suitable that the inner surface of the first cover layer is already patterned before it is applied to the layer stack, that it is formed from a patterned region and an unpatterned region. The patterned region can be applied to the outer surface of the second cover layer after the second cover layer has been applied to the stack of layers, or the outer surface of the second cover layer is already patterned before it is applied to the stack of layers.

It may be provided that the second cover layer is formed as a single-layer or multi-layer encapsulation of the optoelectronic device or the optoelectronic module, which protects the functional layers of the optoelectronic device or the optoelectronic module, comprising several optoelectronic devices, from environmental influences such as moisture. Preferably, a cover layer formed as an encapsulation layer limits the optoelectronic device or module with respect to the surrounding air. In this case, it is advantageous that the outer surface and/or the inner surface, in particular the outer surface, of the second cover layer is formed from a patterned and an unpatterned region, in particular for forming anti-reflection properties and/or anti-soiling properties (as defined herein).

According to a preferred embodiment of the invention, the second cover layer is formed as a single-layer or multi-layer encapsulation as the terminating layer of a single optoelectronic device (so-called single-cell encapsulation). Thereby, the first cover layer may be formed as a contacting layer.

According to a preferred embodiment of the invention, the second cover layer is formed as a single-layer or multi-layer encapsulation as the terminating layer of the optoelectronic module (as defined herein) as an arrangement of at least two optoelectronic devices.

For example, the second cover layer may be formed as a multilayer encapsulation comprising a layer sequence comprising at least one barrier layer and at least one planarization layer. Either a barrier layer or a planarization layer can be arranged on the outer side of the encapsulation. The outer side of the encapsulation is the side of the encapsulation facing away from an element to be encapsulated.

Preferably, the second cover layer, which is designed as a single-layer or multi-layer encapsulation, comprises a low water permeability and/or gas permeability, in particular oxygen permeability, which is particularly advantageous for the encapsulation of organic light-emitting diodes (OLEDs), as this reliably protects the organic layers of an OLED from water and oxygen degradation.

According to one embodiment, the barrier layer may comprise a metal oxide. The metal oxide may be selected from a group comprising aluminum oxide, zirconium oxide, hafnium oxide, tantalum oxide, zinc oxide, lanthanum oxide, titanium oxide and combinations thereof. The barrier layer may comprise at least two sub-layers, each sub-layer comprising a metal oxide.

For the second cover layer, which is preferably formed as a single-layer or multi-layer encapsulation, the thickness may be selected in the region of 50 nm to 1.5 μm inclusive, particularly preferably in the region of 50 nm to 1.0 μm inclusive, in particular 100 nm to 500 nm inclusive, most preferably in the region of 200 nm to 300 nm.

In a preferred embodiment, a protective layer can be formed on the optoelectronic device. In particular, the protective layer is formed as a (partial) layer of the second cover layer, which can preferably be formed as a single-layer or multi-layer encapsulation. According to a further embodiment, a starting material can be applied to the existing layers of the encapsulation to form the protective layer, which is hardened, for example. The starting material may comprise, for example, an adhesive, synthetic resin, acrylic and/or epoxy and/or may be curable by means of UV light. The selective curing of the first section can be carried out, for example, by placing a mask over the base material and irradiating sections of the protective layer exposed in the mask. Subsequently, the remaining UV activator substances can be destroyed so that the cross-linking of the material differs locally from one or more neighboring sections.

### Substrate

For the purposes of the invention, the term substrate refers to a material or a material composition from which the layers of the optoelectronic device, in particular the optoelectronically active layer, the contacting layer and/or the cover layer, are formed, and whose surface has an extension in several spatial directions. A substrate, preferably an extensive and/or transparent substrate, may be a planar substrate or a curved substrate, for example a parabolic substrate. For the purposes of the invention, extensive also means that the extent of a substrate, preferably an extensive and/or transparent substrate, for example a planar substrate in the x and y directions, or the extent of a curved substrate along its radius of curvature is greater than the extent of the region in which the at least three sub-beams interfere with each other.

In a preferred embodiment, the substrate is a substrate whose expansion in the x and y directions or whose expansion along a radius of curvature is less than or equal to the expansion of the region in which the at least three sub-beams interfere with each other. Homogeneous patterning of the substrate is possible in one processing step (during a laser pulse).

In a particularly preferred embodiment, the substrate is an extensive substrate whose extent in the x and y directions or whose extent along a radius of curvature is greater than the extent of the region in which the at least three sub-beams interfere with each other. By moving the substrate in the x and y plane, extensive, homogeneous structuring of the substrate is possible in several processing steps (with several laser pulses). The substrate can be moved by rotation or translation or by a superposition of rotation and translation.

For the purposes of the invention, the term substrate refers to a solid material which is transparent or partially transparent (translucent), with e.g. a reflective surface. Examples of such materials are polymers, ceramics, epoxies and glasses. According to a preferred embodiment of the invention, the substrate reflects electromagnetic radiation in the wavelength range from 100 nm to 10 m, for example visible light in the wavelength range from 380 nm to 780 nm, infrared radiation in the wavelength range from 780 nm to 50 μm or microwave radiation, in particular radar radiation in the wavelength range from 1 mm to 10 m. The patterning of the substrate defined herein allows the optical properties of the substrate to be influenced in a targeted manner, such as generating anti-reflection properties.

With regard to the substrates which can be processed by applying the laser interference patterning method according to the invention with a dot structure as defined herein, in particular with anti-reflection properties, anti-soiling properties and/or can a trap effect, there is a wide choice of transparent and translucent but also non-transparent materials within the scope of the present invention. Such suitable materials or material compositions which can be used in optoelectronic components are known to the person skilled in the art and are described herein by way of example.

The substrate can be designed as a flexible and/or bendable substrate, such as a polymer film, which is also suitable as a carrier material.

### Transparency

Preferably, the substrate, e.g. the cover layer, consists of a transparent material. A material or substrate is transparent in the sense of the present invention if it has a high transmittance for at least a sub-range of the spectrum of electromagnetic radiation between 1 nm and 1 m. Such partial ranges are, for example, electromagnetic radiation in the region of ultraviolet (UV) light from 100 nm to 380 nm, in particular UV-A from 315 nm to 380 nm or UV-B from 280 nm to 315 nm or UV-C from 100 nm to 280 nm, visible light from 380 nm to 780 nm or in a region that also includes infrared light from 780 nm to 5.000 nm or in a region of infrared light (thermal radiation) or in a region of microwave radiation, in particular radar radiation in the wavelength range from 1 mm to 10 m or also another partial range which is adapted according to the desired application, in particular to the wavelength of the laser source. Such a sub-range preferably has a width of at least 10% or 50% of the wavelength, which forms the lower limit of the sub-range. For the purposes of the invention, a high transmittance in a partial range is a transmittance of at least 50% or preferably at least 70% or particularly preferably at least 80% or at least 90% for each wavelength in the partial range, i.e. for the entire spectrum in the partial range. In contrast, a substrate is said to be partially transparent if it comprises at least a certain transmittance, preferably at least 20% for each wavelength in the partial range, i.e. for the entire spectrum in a partial range described herein.

Preferably, the substrate, in particular the optoelectronically active layer, the contacting layer and/or the cover layer, particularly preferably the contacting layer and/or the cover layer, very particularly preferably the cover layer, is transparent, i.e. has a transmittance of at least 50% in a sub-range of the electromagnetic spectrum, preferably in the range of visible light or near-infrared light or the UV range, in particular UV-A and/or UV-B and/or UV-C, has a transmittance of at least 50%, preferably at least 70%, particularly preferably at least 80%, at least 90% for each wavelength in the partial range.

However, a transparent substrate can also be described as a substrate which selectively has a high transmittance for certain wavelength ranges in the visible light range, e.g. the substrate has a high transmittance for electromagnetic radiation with wavelengths in the range from 500 nm to 800 nm. The transmittance can vary over the wavelength range that is transmitted, e.g. not less than 70% for wavelengths in the range from 380 nm to 500 nm and not less than 90% in the range from 500 nm to 750 nm. For example, the substrate transmits radiation with wavelengths of 380 nm to 780 nm. It comprises particularly high transmission, for example a transmittance of 90%, at wavelengths from 450 nm to 690 nm; the transmittance at wavelengths below and above this is, for example, 70%.

It is understood that the transparent substrate, the outer surface and/or inner surface and/or volume of which, in particular a plane in the volume, is formed from a patterned and an unpatterned region, thus after patterning thereof (i.e. after application of a first, second and/or further dot structure as defined herein) continues to be transparent or at least partially transparent, in particular retains its transparent properties.

For the purposes of the present invention, a transparent material includes transparent materials, in particular glass, such as e.g. borosilicate glasses, quartz glasses, alkaline-earth-alkali-silicate glasses (e.g. soda-lime glass), aluminosilicate glasses, metallic glasses, but also solid polymers such as e.g. polycarbonates, such as Makrolon® and Apec®; polycarbonate blends, such as Makroblend® and Bayblen®; polymethyl methacrylate, such as Plexiglas®; polyester; polyethylene terephthalate, polypropylene, polyethylene as well as transparent ceramics such as e.g. spinel ceramics, such as Mg—Al spinel, ALON, aluminum oxide, yttrium aluminum garnet, yttrium oxide or zirconium oxide or mixtures thereof. Polycarbonates are homopolycarbonates, copolycarbonates and thermoplastic polyester carbonates.

According to a particularly preferred embodiment, the transparent material comprises a glass (as defined herein) or a solid polymer (as defined herein). The silicate framework of glass preferably provides a transmission window for wavelengths in the range between 170 nm and 5,000 nm, i.e. wavelength range that includes visible light in the range of 380 nm to 780 nm and includes infrared radiation.

Advantageously, the structures according to the invention can be applied to transparent or at least partially transparent substrates, in particular to cover layers or to contacting layers or to optoelectronically active layers. The difficulty here lies in the fact that transparent or partially transparent substrates generally do not absorb or at least absorb little in the wavelength range of the laser light. This challenge arises in particular with glass or a solid polymer, but also with other transparent or partially transparent substrates.

It is therefore a great challenge to generate a precise, in particular a reliably reproducible material change on the surface or in the volume of the substrate. In order to nevertheless ensure an energy input into the substrate, it is expedient to utilize non-linear optical effects, such as frequency doubling, which is why the substrates according to the invention are generated under high energy input at very short laser pulse durations (in each case in particular as defined herein).

Precise focusing on transparent or partially transparent substrates is a further challenge. According to an advantageous embodiment, the solution is that a beam splitter element is designed to be displaceable along the optical path of the excitation laser so that the interference period can be adjusted, with the remaining optical elements being fixed.

Alternatively, the substrate can also comprise a non-transparent material. For example, such a patterned substrate is suitable as a negative mold for the indirect application or generation of structures on another, preferably transparent or translucent, substrate.

### Dot Structure/Interference Pattern

For the purpose of the present invention, the term “inverse cone” refers to structures with a circular, elliptical, polygonal, such as octagonal, hexagonal, pentagonal, triangular or substantially rectangular base (with reference to the surface of the substrate), in particular with a circular or elliptical base, which converge in a conical or pyramidal, particularly conical shape in the vertical direction into the substrate and have a rounded cone tip or a truncated cone, in particular a rounded cone tip, at their saddle point. Preferably, the patterning of the surface of a substrate with inverse cones, i.e. the application of the patterned regions comprising a first, second, third and/or further interference pixel, is carried out in particular on the optoelectronically active layer, the contacting layer and/or the cover layer by a mechanical process, laser pattern application process and/or by means of chemical (post) treatment.

In a preferred embodiment, the inverse cones are preferably generated during the patterning process by means of laser pattern application methods, in particular direct laser interference patterning, i.e. when a laser pulse hits the substrate to be patterned as a result of a high-intensity region hitting the substrate, whereby the regions between the inverse cones on or within the substrate ideally remain essentially unpatterned due to destructive interference whose intensity is zero. Consequently, by focusing the laser (sub-) beams on or within the substrate, the negative of what the intensity distribution specifies is formed. The described shape of the inverse cones refers to dot structures that are arranged on the surface of the substrate. An arrangement of the dot structures in or along a plane within the volume results in a shape which is more symmetrical, i.e. more like the shape of an ellipsoid.

For the purposes of the invention, dot structures generated within a volume by means of laser interference patterning are also referred to as inverse cones.

Inverse cones with an elliptical base can be generated, for example, by tilting the substrate in relation to the angle of incidence of the focused laser (sub-) beam(s).

For the purposes of the present invention, “cones” are structures with a circular, elliptical, triangular or essentially rectangular base, in particular with a circular base, which protrude from the substrate in a conical shape in the vertical direction and have a rounded conical tip or a truncated cone, in particular a rounded conical tip, at their saddle point. Cones can be inserted into or applied to a surface by applying a negative mold comprising inverse cones. Suitable methods for this are, for example, imprint lithography, e.g. nano-imprint lithography (as defined herein).

The periodic dot structures defined herein, which are preferably formed from cones and/or inverse cones (corresponding to the orientation to the surface of a layer in the optoelectronic device), have the advantage over (periodic) line or wave structures that the individual depressions or elevations span a lateral surface which preferably extends radially over the cone cross-section (diameter of the base surface of the cone or inverse cone) up to the saddle point. This enables adjusting the optical effects defined herein, such as the anti-reflection properties, the extension of the light path due to diffraction at the grating and the reduced reflection due to the trap effect, and wetting effects independently of the orientation of the respective layer of the optoelectronic device in space and of the angle of incidence of the electromagnetic radiation. For example, electromagnetic radiation, in particular light in a photovoltaic cell, can be coupled into the photovoltaic cell or into the individual layers in an improved manner through the periodic dot structures, regardless of the orientation of the photovoltaic cell to the angle of incidence of the electromagnetic radiation. This eliminates the need for time-consuming alignment of the photovoltaic cell or the individual layers arranged therein according to the angle of incidence of the electromagnetic radiation.

According to a preferred embodiment of the invention, for adjacent layers whose surfaces are formed from a patterned and an unpatterned region, it is provided that the interface is patterned in such a way that one of the two adjacent layers comprises inverse cones, whereas the adjacent layer comprises cones. Preferably, the pegs of one layer are complementary to the inverse pegs of the adjacent layer, particularly preferably complementary to the inverse pegs of the adjacent layer in such a way that each peg of one surface is arranged in an inverse peg of the other surface (so-called “Lego principle”). Such a complementary layer stack of at least two layers also has the advantage that the layers arranged adjacent to each other interlock, which leads to an interlocking of the layers with each other and thus to increased stability of the layer structure. In contrast to (periodically arranged) line or wave structures, this has the great advantage that the layers cannot be displaced relative to each other in a spatial direction and/or are not connected to each other over long distances, in particular over the width/length of a layer via only one web formed by the line or wave structure.

According to a preferred embodiment of the invention, for adjacent layers whose surfaces are formed from a patterned and an unpatterned region, it is provided that, with respect to the direction of incidence of electromagnetic radiation, preferably light, on the interface between the two layers, the layer from which the electromagnetic radiation emerges and passes into the adjacent layer comprises a patterned region formed from cones (as defined herein). In contrast, the patterned region of the layer adjacent to this layer into which the light enters is formed of inverse cones. For example, if an optoelectronically active layer is arranged adjacent to a contacting layer within a photovoltaic cell, the interface between the two layers preferably comprises cones or inverse cones, the inverse cones being formed in the outer surface of the optoelectronically active layer, the inner surface of the contacting layer comprising a patterned region formed of cones complementary thereto.

For the purposes of the invention, the period of the structure is referred to as the interference period (pn). It is generally dependent on the patterning of a mask, the negative of the desired periodic dot structure on a molding tool or the wavelength of the interfering laser beams, the angle of incidence of the interfering laser beams and the number of interfering laser beams.

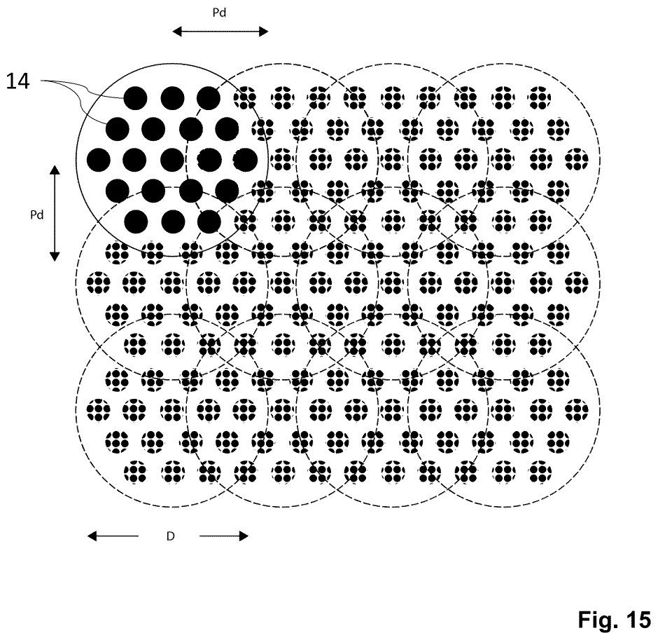

The term “interference pixel”, e.g. first, second, third and/or further interference pixel, denotes in the sense of the present invention a periodic pattern or grid of at least three cones or inverse cones, preferably of at least seven cones or inverse cones, most preferably at least 19 cones or inverse cones on the surface of a substrate, which are formed within an interference pixel (cf. FIG. 15). An interference pixel is preferably characterized by the fact that the cones or inverse cones are aligned repetitively to each other so that, in the presence of three cones or inverse cones, they are aligned to each other so that their vertices (in the case of cones their height centers or in the case of inverse cones their centers of the depressions) have the same distance to each other (so-called interference period). If there are seven cones or inverse cones, these are aligned with each other so that one cone or inverse cone is arranged centrally in the lattice, whereas the six remaining cones or inverse cones are arranged around the center so that each of the vertices (in the case of cones their height centers or in the case of inverse cones their centers of the recesses) of the six remaining cones or inverse cones comprises the same distance to the cone or inverse cone in the center and to at least two of its neighboring cones or inverse cones (so called interference period).

Preferably, the periodic pattern or grating of the interference pixel, in particular comprising inverse cones, is generated by mechanical methods, laser patterning application methods and/or by means of chemical (post) treatment, in particular by direct laser interference patterning. In the case of direct laser interference patterning, the periodic pattern or grating, in particular the first periodic dot structure, preferably also a superimposed dot or line structure or all superimposed dot and/or line structures, is preferably generated by superimposing at least three, particularly preferably at least four laser (partial) beams as a result of focusing (bundling) these laser (partial) beams onto the surface or into the interior of the substrate, whereby the partial beams interfere constructively and destructively on the surface or in the interior of the substrate.

The use of laser patterning application processes, in particular direct laser interference patterning for direct production or indirect production (e.g. in the case of imprint lithography, in particular nanopile lithography) for the production of patterned and unpatterned regions on the surface of a substrate has the advantage that the cones or inverse cones of a periodic dot structure within a type of interference pixel comprise identical or almost identical dimensions. Preferably, the coefficient of variation, i.e. the value resulting from the quotient of the standard deviation and the average value, of the cone cross-section (diameter of the base area of the cone or inverse cone) is max. 15.0% or less, more preferably max. 10.0% or less, even more preferably max. 5.0% or less, in particular max. 2.5% or less, even more preferably max. 1.0% or less. This makes it possible to produce cones or inverse cones that are almost identical to each other in terms of shape. This also allows better detectability of the patterned substrate according to the invention compared to conventional methods for patterning/coating substrates (e.g. etching, particle blasting, polymer coating).

The dot structures generated in this way within an interference pixel are in the form of periodically arranged cones or inverse cones, whereby the interference period is used to generate a structure on a surface of the substrate, i.e. the distance between the vertices of two adjacent cones or inverse cones—i.e. their height centers or centers of the indentations, in relation to cones formed by an interference pixel, is on a statistical average in the range from 1 μm to 50 μm, preferably in the range from 5 μm to 50 μm, more preferably in the range from 10 μm to 30 μm.

In a preferred embodiment, by moving the substrate in relation to the focusing point, which generates the interference pixel, in combination with pulsed laser (sub-) beams, an extensive, optionally homogeneous and periodic dot structure can be generated on the surface or inside a substrate, preferably extensive and/or transparent substrate.

As an alternative to moving the substrate in relation to the focusing point, the focusing point can also be moved over the sample or the substrate (e.g. using scanner-based methods).

Moving the substrate to be patterned, preferably extensive and/or transparent substrate, in the laser beam can be comparatively time-consuming and slow due to the relatively large masses moved in the process. It is therefore advantageous to provide the substrate, preferably extensive and/or transparent substrate, in a fixed position during processing and to realize the extensive patterning of the substrate by focusing the sub-beams on the surface or the volume of the substrate by manipulating the sub-laser beams with optical elements (focusing mirrors or galvo mirrors (laser scanners)) in the beam direction. As the masses moved in this process are relatively small, this is possible with far less effort, which is to say much faster. Preferably, the substrate is stationary during the process. It is also possible to switch between moving the substrate and guiding the focusing point over the substrate, which means that large substrates, for example over 200 mm×200 mm, can be patterned efficiently and yet in a defined and reproducible manner.

Advantageously, the individual pixels of one type of interference pixel, e.g. a first interference pixel, a second interference pixel and/or a further interference pixel, which are arranged adjacent to each other in a repetitively offset manner, can form either a periodic or a non-periodic global dot structure globally (i.e. over the extent of the plane/surface to be patterned), which thus forms the patterned region. A periodic global dot structure is either a fully periodic global dot structure or a quasi-periodic global dot structure. A fully periodic global dot structure is generated or exists if the preceding pixel and the following pixel of a type of interference pixel are each shifted by a whole multiple (e.g. 2, 3, 4, 5) of the interference period (pn) in a spatial direction relative to each other. This results in a fully periodic pattern over the extent of the plane to be patterned, the period of which corresponds to the interference period (pn). A quasi-periodic global dot structure is generated or is present if the preceding pixel and the following pixel of one type of interference pixel are each shifted by an equal multiple (e.g. 0.5; 1.3; 2.6) of the interference period (pn), deviating from an integer multiple, in a spatial direction relative to one another. In contrast, a non-periodic global dot structure is generated or is present if the interference period of the subsequent pixel is varied in relation to the neighboring preceding pixel and/or neighboring pixels arranged repetitively offset to each other are rotated, e.g. successively rotated.

According to a preferred embodiment of the present invention, the global dot structure formed by adjacent repetitively offset pixels of a type of an interference pixel is a fully periodic global dot structure or a quasi-periodic global dot structure (each as defined above).

The inventors of the present invention have further found that, in addition to periodicity, the structure depth (i.e., the depth of the inverse cones measured from their saddle point of the indentation to the apex) also has an influence on the optical properties (as defined herein) or the wetting properties.

According to an advantageous embodiment of the invention, an optoelectronic device with a patterned substrate, in particular with an optoelectronically active layer, a contacting layer and/or a cover layer is also included, wherein the surface consists of a patterned and an unpatterned region, wherein the patterned region is formed by a first periodic dot structure with a first interference period in the micro- or sub-micrometer range. The periodic dot structure is formed from inverse cones, the inverse cones being arranged periodically with respect to each other at a distance relative to their respective saddle point or center of height (circular base) in accordance with the optical property to be adapted in each case or the wetting effect to be achieved in the region as defined in each case herein. The first periodic dot structure consists of one interference pixel or several interference pixels arranged offset to each other. A substrate patterned in this way is characterized in that it has a periodic dot structure with exactly one interference period. There are no superimposed periodic structures that have a second interference period. This results in more precise control of the substrate properties, in particular the transparency of the substrate, which is not impaired by the patterning due to the low structure depths resulting from the fact that each interference pixel is only irradiated once.

Preferably, the patterned region of the surface of the substrate further comprises a second periodic dot structure, wherein the second periodic dot structure is formed from at least one second interference pixel (11) with a second interference period (p2), wherein the second interference pixel (11) comprises a periodic lattice of at least three cones or inverse cones with a second interference period (p2). The patterned region is thus formed from a superposition of at least two periodic dot structures. The second interference pixel is then preferably offset, as the second periodic dot structure has an interference period that differs from the first interference period.

Optionally, the patterned region has a periodic line structure with an interference period in the micrometer or sub-micrometer range; there is then a superposition of a periodic dot structure and a periodic line structure.

According to one possible embodiment, the cones or inverse cones of the patterned region of a substrate have side surfaces. The side surfaces have a superimposed quasi-periodic or periodic line structure or a smooth surface. The superimposed quasi-periodic line structure is preferably generated by LIPSS. Alternatively, the superimposed quasi-periodic or periodic line structure can also be generated by subsequent patterning of the surface of the substrate, e.g. by further scanning of the surface of the substrate using a laser pattern application process, in particular direct laser interference patterning, whereby the structural parameters of the superimposed quasi-periodic or periodic line structure are selected to be smaller than those of the cones or inverse cones.

A smooth surface of the side faces (lateral surface) of the cones or inverse cones is preferably achieved by irradiating the individual cones or inverse cones no more than four times, in particular no more than three times, preferably no more than twice, and most preferably only once, during patterning by means of laser pattern application methods, in particular by means of direct laser interference patterning. Preferably, each interference pixel is generated by single irradiation.

For the purposes of the invention, a surface is considered to be smooth if the average roughness value (Ra) according to DIN EN ISO 4287:2010 is less than 200 nm, preferably less than 50 nm, particularly preferably less than 20 nm, most preferably less than 5 nm.

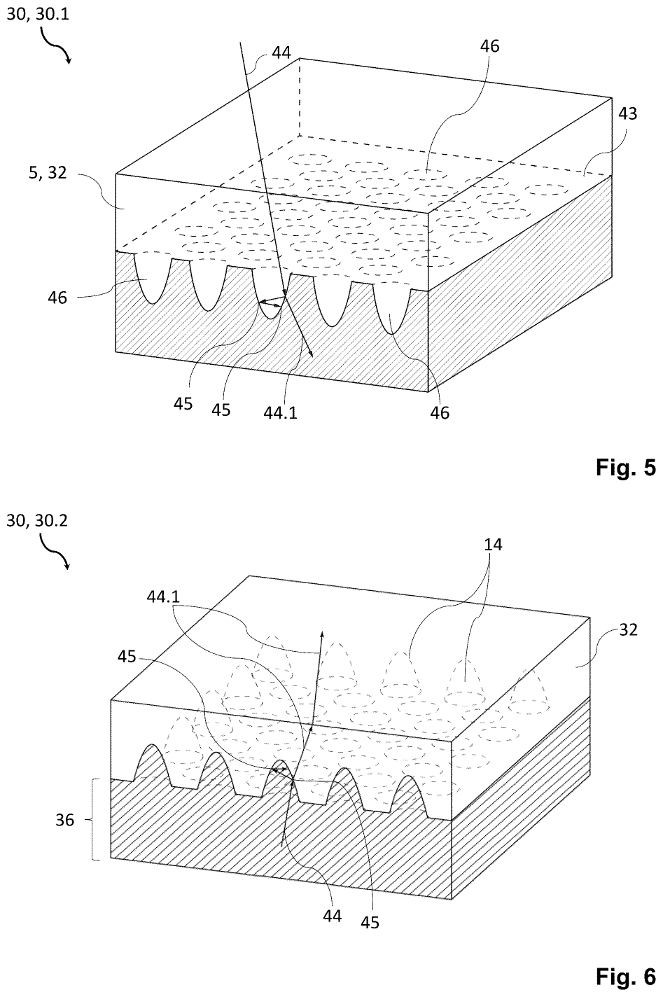

A smooth outer surface of the cones and/or inverse cones has the advantage over a rough surface that electromagnetic radiation is not or cannot be diffusely scattered back at the surface, especially when irradiated. The lateral surface of the cones or inverse cones thus serves, for example When utilizing the trap effect, the lateral surface of the cones or inverse cones serves as a quasi-homogeneous mirror surface, which reflects the proportion of reflected incident electromagnetic radiation within the cones and/or inverse cones, in particular inverse cones, up to the saddle point, whereby at each further reflection point within the lateral surface a proportion of (remaining) electromagnetic radiation couples into the substrate, the outer surface and/or inner surface of which is formed from such a patterned and an unpatterned region (see, for example, FIGS. 4 to 6).

Preferably, any overlap of several interference pixels of one type is avoided. If an overlap of the interference pixels does occur, multiple irradiation of the same cone or inverse cone is avoided so that the inverse cones of the overlapping, subsequently applied interference pixel are generated in the regions between the previously applied inverse cones, i.e. in the unpatterned region. This allows a superimposed structure of several periodic dot structures to be achieved without the LIPSS occurring. This enables reliable generation of the specified properties due to increased reproducibility of the process. This can be realized, for example, by applying a structure shifted by 30% of the interference period with the same interference period. Multiple irradiation of the inverse cones can then be avoided, although there is an overlap of the interference pixels.

Preferably, the base of the cone or inverse cone is circular or elliptical. The circular line then has no unevenness, as is usually the case when etching through a mask with circular or elliptical openings.

As an alternative to the application of cones or inverse cones to the outer and/or inner surface of a substrate, the present invention also includes patterning in the volume of a substrate, in particular in the volume of a functional layer, in particular an optoelectronically active layer, a contacting layer and/or a cover layer (each as defined herein). If the patterning is carried out in the volume, i.e. inside the substrate, preferably flat and/or transparent substrate, in particular in the transparent material, the resulting patterning (i.e. the periodic dot structure of the patterned substrate) is less sensitive to impact and abrasion than conventional coatings. The inventors have found that the patterning (also referred to herein as texturing) inside the material (i.e. below the surface) introduces the properties described herein, in particular the anti-reflection properties, light path lengthening due to diffraction at the grating and/or the reduced reflection due to the trap effect into the material of the substrate.

The present invention therefore also comprises an optoelectronic device having at least the following components or layers:
an optoelectronically active layer, a bonding layer and/or a cover layer, each having an outer surface and an inner surface independently of each other, wherein the optoelectronically active layer, the contacting layer and/or the cover layer (also in the patterned state) is at least partially transparent,
at least one functional layer which is arranged or applied at least partially on the inner and/or outer surface of the optoelectronically active layer, the contacting layer and/or the cover layer,
wherein the volume, in particular a plane in the volume, of the optoelectronically active layer, the contacting layer and/or the cover layer is formed independently of each other from a patterned and an unpatterned region,
wherein the patterned region has a first periodic dot structure,
wherein the first dot structure is formed from at least one first interference pixel with a first interference period (p1),
wherein the first interference pixel comprises a periodic lattice of at least three cones or inverse cones,
wherein the interference period (p1) of the first periodic dot structure is in the region of 50 nm to 50 μm.

The patterned regions, in particular the dot structures, especially preferably the cones and/or inverse cones in the volume of the substrate, in particular within a plane in the volume of the substrate, can each assume the structural parameters defined herein independently of one another. In order to avoid duplication, the patterned regions, in particular the dot structures, especially preferably the cones and/or inverse cones in the volume of the substrate are used synonymously with the patterned regions, in particular the dot structures, especially preferably the cones and/or inverse cones on the surface of the substrate, so that the same structural parameters and configurations apply. In particular, patterning within a plane in the volume of the substrate introduces the same optical properties, in particular the anti-reflection properties, light path lengthening due to diffraction at the grating and/or reduced reflection due to the trap effect, into the material of the substrate. Reference is made herein to the explanations of the respective optical properties and the preferred structural parameters. In connection with dot structures in the volume, in particular within a plane in the volume, the term surface (unless stated separately) is understood to be synonymous with the plane arranged in the volume of the substrate.

Preferably, patterning is carried out within the volume of the substrate using laser pattern application methods, in particular direct laser interference patterning.

For patterning within the volume of a substrate, it may be appropriate to use the laser pulse duration and/or laser pulse energy preferred herein. This low laser pulse duration and/or laser pulse energy per laser pulse can prevent or at least minimize undesired and/or uncontrolled melting of the substrate (e.g. in the form of a structural or chemical transformation), in particular as a result of local overheating, e.g. due to excessive energy input. This is particularly advantageous for the “sensitive” materials used in the substrates or of which the substrates are made.

### Antireflection

With transparent and semi-transparent substrates, some of the incident electromagnetic radiation is partially reflected at the interfaces depending on the material composition and partially absorbed when passing through the substrate depending on the composition and thickness of the substrate. The remainder of the electromagnetic radiation is transmitted through the substrate and emerges on the opposite side of the substrate. The transmittance (as a measure of the permeability of a medium/substrate) is therefore less than 100%. For example, the transmittance of commercially available flat glass is 83%-90% depending on the thickness of the glass. When light is incident perpendicularly, around 8% of the light is reflected to the air or another medium at the two boundary surfaces of commercially available flat glass, which are preferably arranged opposite each other in a layer, in particular plane-parallel, and which correspond to the outer surface and the inner surface when the substrate is formed as a cover layer.

In the sense of the invention, anti-reflection properties herein refer in particular to the increased transmission or diffraction of incident electromagnetic radiation with wavelengths in the spectral range optically visible to humans, in particular 380 to 780 nm, or in the region of ultraviolet radiation (in particular 100 to 380 nm) or infrared radiation (in particular 780 to 10,000 nm).

The structure parameters defined herein for generating a surface which has anti-reflection properties, such as the interference period and structure depth, in particular the interference period, advantageously allow the proportion of reflected radiation at an interface of a substrate to be reduced by at least 50%, preferably at least 70%, more preferably at least 80%, most preferably at least 90%, in particular at least 95%. Using the example of glass as the substrate to be patterned, this can advantageously reduce the proportion of reflected light at one of the interfaces, i.e. at the inner and/or outer surface of the cover layer, to less than 4%, particularly preferably to less than 2.4%, especially preferably to less than 1.6%, particularly preferably to less than 0.8%, especially preferably to less than 0.4%. The adjustment of the anti-reflection properties by forming suitable pattern and unpatterned regions on the outer surface and/or inner surface of a substrate (as defined herein) is of great importance, in particular for the cover layer and/or the contacting layer, in particular for the cover layer, since electromagnetic radiation escapes from the optoelectronic device into the environment (in particular in the case of radiation-emitting cells) or enters it from the environment (in particular in the case of photovoltaic cells) through this layer(s).

Nevertheless, the adjustment of the anti-reflection properties can be provided by forming a suitable patterned and unpatterned region, in particular a patterned region, on the outer surface and/or inner surface of an optoelectronically active layer, as this can prevent or at least reduce radiation losses due to reflection at the interface of the optoelectronically active layer (in particular when electromagnetic radiation enters a photovoltaic cell or when electromagnetic radiation emerges from a radiation-emitting cell, in particular a light-emitting diode).

### Structure Depth

For generating a surface which has anti-reflection properties, the inverse cones of an interference pixel according to a preferred embodiment of the present invention have a mean structure depth or profile depth in the statistical mean d50 in the region of 5 nm to 10 μm, in particular in the region of 10 nm to 5 μm, especially preferably in the region of 50 nm to 800 nm, most preferably from 100 nm to 500 nm. The structure depth of the inverse cones of an interference pixel is generally described by the mean structure depth (d50), which defines within an interference pixel the proportions of cones with a certain structure depth smaller or larger than the specified value for the structure depth.

According to a preferred embodiment of the present invention, the inverse cones have a cones have a structure depth in the region from 5 nm to 800 nm, particularly preferably from 5 nm to 500 nm, very particularly preferably from 5 nm to 200 nm, in particular in the region from 5 nm to 150 nm or in the region from 10 nm to 100 nm. The fact that the inverse cones have such a low structure depth has the advantage that even very thin substrates, in particular the substrates of optoelectronic devices, such as the optoelectronically active layer, the contacting layer and/or the cover layer, in particular functional layers as defined herein, with pronounced anti-reflection properties can be obtained without impairing the properties of the substrates. Such low structure depths can preferably be obtained by means of laser patterning application processes, in particular direct laser interference patterning.

For the purposes of the invention, a patterned substrate with anti-reflection properties also describes such a substrate which has a patterned region consisting of superimposed structures, wherein a further structure is thus superimposed on the first periodic dot structure, wherein at least one structure has dimensions in the micro- or sub-micrometer range, and wherein at least one structure is formed from cones or inverse cones (as defined herein) which can be generated in particular by interfering laser beams. Preferably, the further structure is a line structure or a further periodic dot structure of cones or inverse cones.

For example, when using interfering laser beams, the patterned region, in particular the dot structure, can be optimally adapted to the requirements of the respective application by designing the parameters accordingly (selection of the laser radiation source, arrangement of the optical elements). Preferably, an optoelectronic device with a cover layer with an inner surface and/or outer surface with anti-reflection properties has a periodic dot structure that forms the patterned region.

In contrast to conventional processes for influencing the surface or interface properties (e.g. etching, sandblasting, polymer coatings), it is not necessary to pattern the entire surface when using laser pattern application processes, in particular direct laser interference patterning. The proportion of the surface patterned in this way (degree of coverage of cones per unit area, which is determined by the number and diameter of the inverse cones), i.e. the proportion on the patterned substrate, is preferably 3% to 99%, particularly preferably 5% to 80%, very particularly preferably 7% to 70%, especially 10% to 50%. This not only allows better detectability compared to conventional methods for patterning/coating substrates, but also has the advantage over them that fewer defects or more susceptible structures are introduced into the plane of a substrate, in particular into the surface, in order to achieve the properties defined herein.

### Interference Period

Preferably, anti-reflection properties are achieved on a surface in that the patterned region is formed by a periodic dot structure in the nanoscale (sub-micrometer range) of inverse cones or cones with average dimensions in the sub-micrometer range or at least has such a periodic dot structure in the nanoscale. The periodic dot structure of an interference pixel has in particular an interference period, i.e. an average distance in relation to the respective saddle point or height center of two adjacent inverse cones or cones of an interference pixel, of 100 nm to 1,000 nm, particularly preferably 200 nm to 700 nm, very particularly preferably from 200 nm to 450 nm.

The periodic dot structure in the nanometer range is preferably formed in such a way that the patterned substrate transmits electromagnetic radiation with a wavelength of more than 550 nm at a periodic dot structure of less than 1,000 nm, preferably more than 500 nm at a periodic dot structure of less than 750 nm, most preferably more than 450 nm at a periodic dot structure of less than 600 nm. Depending on the structure depth of the inverse cones, wavelengths in the red and/or yellow light spectrum, the green light spectrum and even the blue light spectrum can be transmitted into the substrate due to the anti-reflection properties.

According to a preferred embodiment of the invention, the surface for generating a surface having anti-reflection properties preferably has a dot structure formed as periodically arranged inverse cones, wherein the distance between the apexes of adjacent inverse cones (i. i.e. height centers or centers of the elevations) are arranged in the statistical mean in the region of 50 nm to 50 μm, preferably in the region of 50 nm to 20 μm, more preferably in the region of 100 nm to 1,000 nm, particularly preferably in the region of 100 nm to 600 nm.

In the sense of the invention, anti-reflection properties herein refer to the increased transmission or diffraction of incident electromagnetic radiation with wavelengths in the region of visible light, in particular with wavelengths in the region of 400 nm to 780 nm, as well as to the region of infrared radiation or thermal radiation, in particular with wavelengths in the region of 780 nm to 10 μm, preferably 780 nm to 0.1 mm. The substrate is characterized in that the periodic dot structure it comprises preferably has dimensions, i.e. interference periods, in the sub-micrometer range, particularly preferably in the nanometer range. Particularly preferred are the dimensions of the periodic dot structure in the range of the wavelength of electromagnetic radiation in the range of visible light. Thus, the dimensions of the periodic dot structure are preferably in the range of 630 nm to 700 nm for emitting or diffracting red light, in the range from 590 nm to 630 nm for emitting or diffracting red and orange light, in the range from 560 nm to 590 nm for emitting or diffracting red, orange and yellow light, in the range from 500 nm to 560 nm for emitting or diffracting red, orange, yellow and green light, in the range from 475 nm to 500 nm for emitting or diffracting red, orange, yellow, green and turquoise light, in the range from 450 nm to 475 nm for transmitting or diffracting red, orange, yellow, green, turquoise and blue light, in the range from 425 nm to 450 nm for transmitting or diffracting red, orange, yellow, green, turquoise, blue and indigo light, in the range from 400 nm to 425 nm for transmitting or diffracting red, orange, yellow, green, turquoise, blue, indigo and violet light. Thus the anti-reflection properties of the substrate can be controlled by changing the dimensions of the periodic dot structure.

According to a preferred embodiment, the optoelectronic device is a light-emitting diode (LED). A periodic dot structure can be provided on the inner surface of the contacting layer and/or the cover layer. The periodic dot structure on the inner surface of the contacting layer and/or the cover layer can be formed so that high-energy light, in particular UV light or blue light, is reflected back into the LED, whereas light of a specific wavelength in the visible region generated by the optoelectronically active layer, in particular by phosphors in an optoelectronically active layer, can escape through the contacting layer and/or the cover layer into the environment. Preferably, the reflected high-energy light can be used to further excite the phosphors. Therefore, the dimensions of the periodic dot structure are preferably greater than 450 nm, particularly preferably greater than 475 nm, most preferably greater than 500 nm. It may be provided that the dimensions of the periodic dot structures (irrespective of the aforementioned limit ranges) are preferably a maximum of 1,000 nm, particularly preferably a maximum of 900 nm, most preferably a maximum of 800 nm, in particular a maximum of 700 nm.

In one embodiment of the invention, the method and device disclosed herein are suitable for generating a substrate comprising a periodic dot structure in the nanometer range, which has been generated, for example, by means of laser interference patterning, and which is characterized by anti-reflection properties. In the sense of the invention, anti-reflection properties herein also refer to the increased transmission or diffraction of incident electromagnetic radiation with wavelengths in the range of non-visible light, in particular in the region of ultraviolet radiation (UV radiation), in particular with wavelengths in the region of 100 nm to 380 nm. The substrate is characterized by the periodic dot structure it comprises preferably comprising dimensions in the nanometer range. A substrate thus patterned can be used advantageously in regions where protection against UV radiation is necessary.

However, the periodic dot structure for generating the anti-reflection properties can also be overlaid with another dot structure and/or line structure for influencing other properties, such as the wetting properties. The resulting global dot structure, i.e. the resulting dot structure that forms the patterned region, can then be fully periodic or quasi-periodic or non-periodic.

These anti-reflection properties are achieved if the dimensions of the structure generated, i.e. the interference period and dimensions of the individual cones, are in ranges smaller than the wavelength of visible light, i.e. preferably below 700 nm, preferably below 500 nm. In physics, reflection is the bouncing back of an electromagnetic wave at an interface of materials with different refractive indices. The angle of reflection and the angle of transmission of light in transparent substrates can generally be calculated using Snellius' law of refraction as follows

$${n}_{1} sin {δ}_{1} = {n}_{2} sin {δ}_{2}$$

where n1 and n2 indicate the refractive index of air and the substrate and δ1 and δ2 indicate the angles of the incident and reflected beam respectively.

Due to the periodic dot structure on the surface or in the volume of the substrate, preferably an extensive and/or transparent substrate, the refractive index of the substrate changes in such a way that a gradual refractive index ensues. As a result, light with wavelengths greater than the structural period p of the periodic dot structure is increasingly transmitted. Light with wavelengths shorter than or equal to the periodic dot structure is diffracted at the surface.

In the context of the invention, anti-reflection properties refer to periodic dot structures whose dimensions lie within the range of the incident electromagnetic wave, so that the incident wave is diffracted away from the observer in such a way that no reflection is perceived as “disturbing”. In addition, the term anti-reflection properties in the sense of the invention also includes that the refractive index at the boundary between the first medium, for example air, and the substrate, preferably extensive and/or transparent substrate, is gradual, so that there is no clear transition from one medium to the other for the incident electromagnetic wave and the incident electromagnetic wave is increasingly transmitted.

The refractive index of the patterned substrate is gradual due to the generated periodic dot structure, preferably a first periodic dot structure. It decreases over the height of the structure so that there is no clear air-medium transition. This results in increased transmission of incident electromagnetic waves with a wavelength greater than the interference period of the generated dot structure, and diffraction of incident electromagnetic waves with a wavelength in the range of the interference period of the generated dot structure.

### Light Path Lengthening Through Diffraction at the Grating

According to an advantageous embodiment, the patterned region of an inner surface and/or outer surface of a cover layer of a photovoltaic device or a photovoltaic module has a periodic dot structure or is formed from a periodic dot structure. This periodic dot structure acts as a periodic grating and leads to an extension of the light path. This results in improved absorption and therefore better efficiency, as explained below.

In order to ensure maximum irradiation of the light into the photovoltaic device, the aim is to achieve an angle of incidence of the light into the outer surface of the optoelectronic device that is as perpendicular as possible. As a result, however, the path that the light travels through the optoelectronically active layer is not optimal and is actually too short to ensure optimal absorption of the light by the optoelectronically active layer, in particular the absorption layer. Due to the necessary short charge carrier transport path within the optoelectronically active layer, in particular the absorption layer—in order to prevent recombination of the charge carriers—it is not a suitable option to increase the thickness of the optoelectronically active layer, in particular the absorption layer.

Nevertheless, the present invention can advantageously contribute to an extension of the path that the light travels through the optoelectronically active layer, in particular the absorption layer.

Periodic dot structures arranged on an outer surface and/or inner surface of a cover layer of a photovoltaic device or a photovoltaic module act as a diffraction grating on incident light, resulting in diffraction effects. As a result, some of the light is deflected in its direction of propagation. As a result, some of the light does not pass through the optoelectronically active layer perpendicularly, but at a certain deflected angle. The resulting lengthening of the light path can advantageously increase the proportion of absorbed light, in particular without negatively influencing the charge carrier extraction.

Furthermore, the adjustment of the light path extension by diffraction at a grating can also be generated by forming a suitable patterned and unpatterned region, in particular a patterned region, on the outer surface and/or inner surface of an optoelectronically active layer. A periodic structure generated at the interface to the optoelectronically active layer leads to a suitable deflection of the direction of propagation of the electromagnetic radiation when electromagnetic radiation enters a photovoltaic cell and thus to the above-mentioned lengthening of the light path and the associated increase in absorption and consequently also in efficiency.

### Reduced Reflection Due to the Trap Effect

The reduction of reflection due to the trap effect (as defined herein) by forming suitable patterned and unpatterned regions on the outer surface and/or inner surface of a substrate is of great importance, especially for the optoelectronically active layers, in particular for the optoelectronically active layers in photovoltaic cells, since within this layer(s) the absorption and/or interaction between the electromagnetic radiation entering the optoelectronic device or optoelectronic module and the light-absorbing material within the optoelectronic layer is of great importance for a high efficiency of the optoelectronic device or optoelectronic module. optoelectronic module and the light-absorbing material within the optoelectronic layer ensures a high efficiency of the optoelectronic device.

Nevertheless, the described reduction of reflection due to the trap effect can increase the light extraction of a light-emitting device or a module comprising several light-emitting devices. Advantageously, an increase in the efficiency, in particular the light output/light release of the light-emitting device or light-emitting module can thus be achieved.

According to a preferred embodiment of the invention, the patterned regions which lead to a reduction in reflection due to the trap effect are arranged within the patterned regions in such a way that, with respect to the direction of incidence of electromagnetic radiation, preferably light, inverse cones are arranged at this interface into which the light enters so that these are formed into the substrate, in particular into the optoelectronically active layer.

According to a preferred embodiment of the invention, for adjacent layers whose surfaces are formed from a patterned and an unpatterned region, it is provided that, with respect to the direction of incidence of electromagnetic radiation, preferably light, on the interface between the two layers, the layer from which the electromagnetic radiation emerges and passes into the adjacent layer comprises a patterned region which is formed from cones (as defined herein). In contrast, the patterned region of the layer adjacent to this layer into which the light enters is formed of inverse cones. If, for example, an optoelectronically active layer is arranged adjacent to a contacting layer within a photovoltaic cell, the interface between the two layers preferably comprises cones or inverse cones, wherein the inverse cones are formed in the outer surface of the optoelectronically active layer, and wherein, complementary thereto, the inner surface of the contacting layer comprises a patterned region formed of cones (so-called “Lego principle”).

According to an advantageous embodiment, the structures are generated on an outer surface and/or inner surface of a cover layer and/or a contacting layer.

Such a structure for reducing reflection due to the trap effect can also be generated by forming a suitable patterned and unpatterned region, in particular a patterned region, on the outer surface and/or inner surface of an optoelectronically active layer. A reduction in reflection is particularly relevant at an interface to the optoelectronically active layer.

According to an advantageous embodiment, the optoelectronic device is a photovoltaic device and the dot structures generated on the optoelectronically active layer are inverse cones.

According to an alternative embodiment, the optoelectronic device is a light-emitting device, preferably an LED, and the dot structures generated on the optoelectronically active layer are cones.

Thus, the described reduction in reflection due to the trap effect can increase the light coupling in the case of a photovoltaic device or a module comprising several photovoltaic devices and the light decoupling in the case of a light-emitting device or a module comprising several light-emitting devices. This has the advantage of increasing the efficiency of the optoelectronic devices or optoelectronic modules.

When utilizing the trap effect, the lateral surface of the cones or inverse cones serves as a mirror surface, preferably a quasi-homogeneous mirror surface, which reflects the proportion of reflected incident electromagnetic radiation within the cones and/or inverse cones, in particular inverse cones, up to the saddle point, whereby at each further reflection point within the cladding surface a proportion of (remaining) electromagnetic radiation couples into the substrate, the outer surface and/or inner surface of which is formed from such a patterned and an unpatterned region (see, for example, FIGS. 4 to 6). FIGS. 4 to 6). According to a preferred embodiment of the invention, the outer surface of the cones or inverse cones is smooth.

### Structure Depth

For generating a surface comprising properties for reducing the reflection due to the trap effect, the cones or inverse cones of an interference pixel according to a preferred embodiment of the present invention have a mean structure depth or profile depth in the statistical mean d50 in the region of 0.05 μm to 20 μm, particularly preferably in the region of 0.05 μm to 10 μm, very particularly preferably of 0.1 μm to 5 μm, in particular 0.1 μm to 2 μm. The structure depth of the inverse cones of an interference pixel is generally described by the mean structure depth (d50), which defines within an interference pixel the proportions of cones with a certain structure depth smaller or larger than the specified value for the structure depth. A structure depth designed in this way has the advantage, for example, that a high proportion of remaining electromagnetic radiation, which is not yet coupled into the substrate during the first interaction with the surface of the substrate, is forwarded to the saddle point of the cone or inverse cone by further interaction with the cladding surface within the cone or inverse cone and as a result (no longer escaping the cone or inverse cone) is transmitted to its saddle point. cone) into the substrate with an efficiency of more than 90%, preferably more than 95%, particularly preferably more than 98%, most preferably more than 99%.

For the purposes of the invention, the structure depth of a dot structure comprising cones is the mean structure depth of a dot structure comprising cones, i.e. the statistical mean of the distance from the surface to the height center of the cones. Even if the cones basically protrude from the structure, the mean distance of the height centers of the cones to the surface is nevertheless referred to as the structure depth or mean structure depth d50 in analogy to the inverse cones.

For the purposes of the invention, a patterned substrate or a cover layer with properties for reducing reflection due to the trap effect also describes such a substrate which comprises a patterned region consisting of superimposed structures, wherein a further structure is superimposed on the periodic dot structure, wherein at least one structure comprises dimensions in the micro- or sub-micrometer range, and wherein at least one structure is formed from cones or inverse cones (as defined herein) which can be generated in particular by interfering laser beams. Preferably, the further structure is a line structure or a further periodic dot structure of cones or inverse cones.

For example, a global dot structure, in particular the global dot structure of superimposed structures, can be optimally adapted to the requirements of the respective application when using interfering laser beams by choosing the parameters accordingly (selection of the laser radiation source, arrangement of the optical elements). Preferably, an optoelectronic device with a cover layer comprising a surface or interface with properties for reducing reflection due to the trap effect comprises a periodic global dot structure.

In contrast to conventional processes for influencing the surface or interface properties (e.g. etching, sandblasting, polymer coatings), it is not necessary for the entire surface to be patterned (and/or coated as in conventional processes). The proportion of the surface patterned in this way (degree of coverage of cones per unit area, which is determined by the number and diameter of the inverse cones), i.e. the proportion on the patterned substrate, is preferably 3% to 99%, particularly preferably 5% to 80%, very particularly preferably 7% to 70%, especially 10% to 50%. This not only allows better detectability compared to conventional methods for patterning/coating substrates, but also has the advantage over them that fewer defects or more susceptible structures are introduced into the plane of a substrate, in particular into the surface, in order to achieve the properties defined herein.

According to a preferred embodiment of the present invention, the patterned substrate does not merely comprise a single interference pixel of one type, for example a first interference pixel, a second interference pixel and/or a third interference pixel, but rather several interference pixels of one type, for example several first interference pixels and/or several second interference pixels are each arranged independently of one another within a plane in at least one spatial direction (x and/or y orientation), particularly preferably in two spatial directions (two-dimensional), adjacent to one another in a repetitive offset manner. Thus, for example, it may be provided that in a first step at least a plurality of first interference pixels (10) are applied within a plane in at least one spatial direction adjacent to one another in a repetitive offset manner to a plane on a surface or in the volume of the substrate to be patterned (see, for example, FIG. 15) and in a second step a plurality of second interference pixels (11) are applied superimposed on these plurality of first interference pixels (10) within a plane in at least the same spatial direction adjacent to one another in a repetitive offset manner. Nevertheless, it may be provided that these several first interference pixels (10) and several second interference pixels (11) are applied alternately, i.e. alternately—i.e. a first interference pixel, then a second interference pixel and again from the front—to the plane.

This advantageously increases the region in which the reflection is reduced by the trap effect. Furthermore, an arrangement in which a plurality of interference pixels are arranged repetitively offset to one another in at least one spatial direction opens up a number of adjustable degrees of freedom, which can be used to efficiently influence the properties of the surface.

By arranging several first interference pixels (10) and several second interference pixels (11), targeted properties, in particular a reduction in reflection, i.e. a reduction in light that is neither transmitted nor absorbed, can be achieved/applied over a large region, in particular over a large area on a plane of the substrate that is spanned by a surface of the substrate or within the volume of the substrate. Such patterning with several first interference pixels (10) and several second interference pixels (11) can be achieved, for example, by scanning the substrate with a polygon scanner.

The superimposed interference pixels of different types, e.g. a first interference pixel, a second interference pixel and/or a further interference pixel, can form either a periodic or a non-periodic global dot structure globally (i.e. over the extent of the plane to be patterned). A fully periodic global dot structure is generated or exists if the pixels of an interference pixel of a first type and the superimposed pixels of an interference pixel of another type are each shifted relative to each other by a whole multiple (e.g. 2, 3, 4, 5) of the interference period (pn) in one spatial direction. This results in a fully periodic pattern over the extent of the plane to be patterned, the period of which corresponds to the interference period (pn). A quasi-periodic global dot structure is generated or is present if the pixels of a first type and the superimposed pixels of an interference pixel of another type are each shifted relative to each other by an equal multiple (e.g. 0.5; 1.3; 2.6) of the interference period (pn) in a spatial direction that deviates from a whole multiple. In contrast, a non-periodic global dot structure is generated by the pixels of a first type and the superimposed pixels of an interference pixel of another type, or is present if the superimposed first interference pixels and the superimposed second interference pixels comprise different interference periods and/or the adjacent pixels of at least one type of interference pixel, which are arranged in a repetitively offset manner relative to one another, are applied in a twisted manner, e.g. successively twisted.

According to a preferred embodiment of the present invention, the global dot structures comprising at least a plurality of first interference pixels of at least a first interference period (p1) and a plurality of second interference pixels of at least a second interference period (p2) are quasi-periodic or non-periodic, particularly preferably non-periodic, wherein such a global dot structure is preferably formed from the superposition of at least one first interference pixel and one second interference pixel, which are each arranged in themselves in at least one spatial direction adjacent to each other in a repetitively offset manner and each form a periodic or quasiperiodic global dot structure in themselves.

It may be provided that first interference pixels (10) and/or second interference pixels (11) arranged adjacent to one another comprise varying structure parameters selected from the group comprising the interference period of the interference pixel, the structure depth of the inverted cones, the diameter of the inverted cones, the shape of the inverted cones and the size of the inverted cones. This can advantageously generate a high degree of disorder locally, i.e. non-periodic structures, thereby minimizing or preventing undesirable or disturbing optical effects, such as moiré effects or color effects caused by diffraction on applied microstructures.

According to a preferred embodiment of the invention, the interference periods of the dot structure of at least each further interference pixel of a type, e.g. each interference pixel of a first interference pixel, each interference pixel of a second interference pixel and/or each interference pixel of a third interference pixel, are essentially identical, i.e. differ by a maximum of 0% to 2.0%, particularly preferably by a maximum of 0% to 1.0%. It is particularly preferred that the interference periods are identical. In this way, the parameters of the laser interference patterning device for applying the interference pixels to the plane of the substrate can be kept constant, which minimizes the effort and the occurrence of faulty structures.

According to a preferred embodiment of the present invention, the adjacent interference pixels of one type, for example the first interference pixel, the second interference pixel and/or the third interference pixel, which are arranged repetitively offset relative to one another, are rotated relative to the preceding interference pixel of this one type about an axis of rotation (preferably about a centric axis) arranged within the interference pixel (i.e. a normal to the plane), for example alternately or successively rotated relative to the preceding one. Preferably, the subsequent interference pixel is rotated in relation to the preceding interference pixel of the interference pixels of one type in the region of 1° to 90°, furthermore in the region of 3° to 85°, particularly preferably by 5° to 80°, most preferably by 10° to 75°, in particular in the region of 15° to 60°. This generates a high degree of disorder, i.e. non-periodic structures, globally across a plane of the substrate that is spanned by a surface of the substrate or within the volume of the substrate, which also minimizes or prevents undesirable or disturbing optical effects, such as moiré effects or color effects caused by diffraction on applied microstructures.

The generation of patterned regions comprising a non-periodic global dot structure can be advantageous. A superposition of first and second interference pixels comprising identical interference periods can result in periodic dot structures in which the undesirable moiré effect occurs, so that according to an advantageous embodiment the interference periods of superimposed interference pixels are varied by a non-integer factor. A detrimental change in the color behavior, which can occur due to diffraction effects on the introduced structures, is also avoided by a high degree of disorder.

To generate a non-periodic global dot structure, the offset between the interference pixel of a first type and the interference pixel of a second type, e.g. the second interference pixel and the first interference pixel, is preferably in the region of 5%≤x≤50%, preferably in the region of 10%≤x≤50%, in particular in the region of 20%≤x<50%, particularly preferably in the region of 25%≤x≤45% of the interference period. If the periodic dot structure is designed so that an interference pixel of a further type is provided, at least a third interference pixel, this is arranged superimposed on the interference pixel of the previous type so that the offset between the interference pixel of the further type, e.g. the third interference pixel and the interference period, is less than 50%. the third interference pixel and the second interference pixel is preferably in the range of 5%≤x≤50%, preferably in the range of 10%≤x≤50%, in particular in the range of 20%≤x<50%, particularly preferably in the range of 25%≤x≤45% of the interference period. An offset which is below the interference period leads to an increase in the structure density or density of the dot structure, which results in an increase in the density of the cones or inverse cones potentially acting as traps and thus advantageously an improved light coupling or light extraction.

According to a preferred embodiment of the present invention, the patterned substrate, in particular the patterned cover layer and the dot structure applied to the surface of the cover layer, comprises at least one further type of interference pixel with a further interference period (pn), for example a third interference pixel (12) with a third interference period (p3), wherein the further, for example the third interference pixel (12) is arranged superimposed on the first interference pixel (10) and second interference pixel (11) in accordance with the aforementioned claims. As a result, further defects (i.e. dot structures in the micro- and sub-micrometer range) can be advantageously generated in the plane of the substrate to be patterned. A higher number of cones or inverse cones increases the number of traps, which advantageously reduces the amount of reflected light.

Advantageously, this can also increase the degree of disorder, i.e. non-periodic structures, which minimizes or prevents undesirable or disruptive optical effects, such as moiré effects or color effects caused by diffraction on applied microstructures.

### Interference Period

Preferably, properties in which the reflection is reduced due to the trap effect are achieved by the fact that the global dot structure forming the patterned region is a non-periodic global dot structure of inverse cones with average dimensions in the micrometer range. The periodic dot structure of an interference pixel comprises in particular an interference period, i.e. an average distance in relation to the respective saddle point or height center of two adjacent cones of an interference pixel of 1 μm to 50 μm, particularly preferably 1 μm to 30 μm, very particularly preferably 1 μm to 20 μm. A further structure in the nanometer range can be superimposed on this preferably non-periodic dot structure in the micrometer range, whereby the average dimension of the superimposed structure preferably comprises dimensions in the range of the laser wavelength λ, or λ/2, in particular from 100 nm to 1,000 nm, preferably from 200 nm to 500 nm, particularly preferably from 200 nm to 450 nm. For the purposes of the invention, such a structure is also referred to as a hierarchical structure.

Hierarchical patterning refers to a structure in which a first structure with dimensions in the micro- or sub-micrometre range, in particular in the micrometre range, which corresponds to an interference pattern, is superimposed by a further structure which comprises dimensions which are below the dimensions of the first structure and which is formed, for example, by a self-organization process. Preferably, the dimensions of the further structure, the structure in the nanometer range superimposed on the dot structure in the micrometer range, which is formed, for example, by a self-organization process, are in the region of 1% to 30%, particularly preferably in the region of 1% to 10% of the dimensions of the first structure, which corresponds to an interference pattern.

In particular, the structure superimposed on the dot structure in the micrometer range comprises a periodic wave structure in the nanometer range, preferably a fully periodic wave structure, wherein the material on the surface of the substrate in the region of the superimposed structure comprises a sequence of wave crests and wave troughs whose periodicity is in the sub-micrometer range, preferably in the range from 100 nm to 1,000 nm, particularly preferably from 200 nm to 500 nm, in particular in a range as defined herein for anti-reflection properties. This allows additional advantageous anti-reflection properties to be introduced in the patterned plane, in particular on the surface of the substrate. The structures in the nanometer range ensure that light incident on the substrate reflects less or reflects at such a flat angle that it does not have a “disturbing” effect when the material surface is viewed normally.

The periodic dot structure in the nanometer range is preferably designed so that the patterned substrate transmits electromagnetic radiation with a wavelength of more than 550 nm at a periodic dot structure of less than 1,000 nm, preferably more than 500 nm at a periodic dot structure of less than 750 nm, most preferably more than 450 nm at a periodic dot structure of less than 600 nm. Depending on the structure depth of the inverse cones, wavelengths in the red and/or yellow light spectrum, the green light spectrum and even the blue light spectrum can be transmitted into the substrate.

The average structure depth of this structure, which overlays the dot structure in the micrometer range, in the nanometer range is preferably in the region of 10 nm to 500 nm.

Due to the dimensions of the structure in the nanometer range superimposed on the dot structure in the micrometer range in relation to the dot structure in the micrometer range, it is advisable to apply this periodic nanometer structure, preferably a fully periodic wave structure, after the dot structure in the micrometer range has been applied, as otherwise the superimposed structure in the nanometer range could be destroyed by the application of the much larger dot structure in the micrometer range.

The wave structure superimposed on the periodic dot structure of inverse cones with average dimensions in the micrometer range can be formed during the patterning process, i.e. when a laser pulse impinges on the substrate to be patterned as a result of the occurrence of a region of high intensity, the patterning being effected by a self-organization process which is excited by the at least partial melting of the substrate material by means of a laser pulse in a region of high intensity. In particular, the wave structure is generated by utilizing laser-induced periodic surface structures (LIPSS), the occurrence of these surface structures being coupled to the generation of the dot structures by means of interfering laser beams.

Alternatively, the wave structure, which is superimposed on the dot structure according to the invention consisting of inverse cones with average dimensions in the micro- or sub-micrometer range, can also be produced by subsequently applying a further interference pixel to the surface of the (pre-patterned) substrate, whereby the structures generated with the further interference pixel comprise an interference period in relation to the cones formed by the further interference pixel in the statistical mean in the region of 100 nm to 1,000 nm, preferably in the region of 200 nm to 500 nm.

There are numerous technical applications for hierarchical structures, such as in the region of the production of substrates with hydrophobic or superhydrophobic as well as hydrophilic or superhydrophilic surfaces and substrates with anti-icing or anti-fogging properties in addition to the substrates mentioned at the beginning with properties for reducing reflection due to trap effects.

It is thus advantageously possible to pattern the surface of a substrate, for example with properties for reducing reflection due to trap effects caused by interfering laser beams and by utilizing laser-induced periodic surface structures, without having to accept a long processing time or a high number of successively executable process steps. The invention thus enables the simultaneous generation of hierarchical structures which can be used in the technical field both in the region of substrates with anti-reflection properties and in the region of self-cleaning, hydrophobic or superhydrophobic, as well as hydrophilic or super-hydrophilic substrates with anti-reflection properties and/or anti-fogging properties.

### Anti-Soiling/Wetting Properties

Particularly in the case of optoelectronic devices or optoelectronic modules that are used outdoors and are exposed to the environment, the layers or surfaces facing the environment quickly become dirty or tend to form condensation, especially in the form of fog or mist, which clogs the surface and reduces the transmission of light into or out of the optoelectronic cell. This reduces the efficiency of photovoltaic cells, for example. It therefore makes sense to modify the outer surface that seals off the optoelectronic device or the optoelectronic module from the environment in such a way that the wetting properties of the surface are improved or increased so that the substrate comprises anti-soiling properties and/or anti-fogging properties.

Due to the very small structure dimensions that can be generated, the device and method disclosed herein are also suitable for generating surfaces with hydrophobic and/or superhydrophobic as well as hydrophilic and/or super-hydrophilic properties. Advantageously, by applying the periodic dot structure to the surface of the substrate (as defined herein), in particular the periodic dot structures, the optical properties, in particular the original transparency of the substrate, are not impaired, in particular when applied to the outer surface of a cover layer.

Surfaces with anti-soiling properties are characterized by the fact that they comprise either highly hydrophobic or highly hydrophilic properties. The degree of hydrophobicity or hydrophilicity of a surface can be determined by means of the water contact angle of a surface wetted with water. A water contact angle of less than 90° is referred to as hydrophilic and a water contact angle of more than 90° is referred to as hydrophobic.

In the sense of the invention, a surface has an anti-soiling property if it comprises a water contact angle of less than 20° or greater than 130°, preferably less than 10° or greater than 140°, particularly preferably less than 5° or greater than 150° when wetted with water.

The water contact angle of a surface is determined using drop contour analysis. This image analysis method uses the shadow image of a drop placed or lying on the surface, whereby its shape on the surface is analyzed. A drop of 2 μl deionized water on the surface of the substrate is used. The ambient temperature is 22° C.

Another effect that can be achieved on the patterned surfaces is a reduced holding property of solid particles, in particular dirt and dust particles. As a result, a lower proportion of solid particles adhere to the surface. Advantageously, such a patterning applied to an outer surface of a cover layer leads to a cleaner outer surface of the cover layer and, in the case of materials that are at least partially transparent, preferably transparent, also to better transparency of the cover layer, as dirt and dust particles also absorb or reflect some of the light. This can improve the coupling of light in and out and increase the efficiency of the optoelectronic devices. Preferably, the interference period is selected to be smaller than the average particle size of the particles whose adhesion is to be reduced. As a result, adhesion is disrupted or can be greatly reduced. This effect is also known as the anti-soiling effect.

Especially for optoelectronic devices, where the transparency of the surfaces is very relevant, it is very problematic that particles, especially small particles such as dust, adhere very strongly to a surface. This applies in particular to dust particles with a diameter of 0.2 μm to 100 μm; dust particles with a diameter of 0.5 to 20 μm are also particularly relevant, and diameters of 1 to 10 μm are especially relevant. These particles reduce the transparency of the surface and thus reduce the efficiency of the optoelectronic device, in particular the photovoltaic device or the light-emitting diode. According to an advantageous embodiment, the first periodic dot structure or a line structure, preferably a superimposed line structure, comprises interference periods of less than 100 μm, preferably less than 20 μm and most preferably less than 10 μm. These particles reduce the transparency of the surface and thus reduce the efficiency of the optoelectronic device, in particular the photovoltaic device or the light-emitting diode. According to an advantageous embodiment, the first periodic dot structure or a line structure, preferably a superimposed line structure, comprises interference periods of less than 100 μm, preferably less than 20 μm and most preferably less than 10 μm. According to a particularly preferred embodiment, the interference periods are in a region of 50 nm to 5 μm. Due to the anti-soiling effect occurring on the surface with respect to dust particles with diameters larger than the respective interference period, the van der Waals forces acting between the dust particles and the surface of the cover layer are then reduced by the patterning. This leads to a reduction in the adhesion of the dust or particles, in particular the dirt particles, to the surface of the cover layer due to the reduced contact area between the dust particles and the surface.

The structure is selected so that the functional laser structure is just smaller than the average particle distribution. The greater the deviation from the mean particle size, the stronger the anti-soiling effect.

Preferably, the structure depth, in particular the mean structure depth in the statistical mean d50, of the first periodic dot structure and/or the superimposed line structure is in the range of 10 nm to 20 μm, preferably 20 nm to 1 μm, preferably in the range of 50 nm to 200 nm, i.e. in combination with the above-mentioned interference periods to optimize the anti-soiling effect. Advantageously, the anti-soiling effect can be achieved without significantly reducing the transparency. Advantageously, the human eye does not see the patterning, but the dust does “see” it. Such low structure depths also require only low laser pulse energies or laser pulse powers, so that the process speed can be advantageously very high with surface speeds of 0.01 m²/min and higher.

These structures can reduce the adhesion of moon dust, cement dust or desert dust. This type of structure can also ensure that the transparency is high, at least 50%, preferably at least 70%, particularly preferably at least 90%. A particularly advantageous feature is that the transparency of the unpatterned surface is preferably reduced by a maximum of 10% in a partial range of electromagnetic radiation by the patterning. Possible partial ranges are, for example, electromagnetic radiation in the range of ultraviolet (UV) light from 100 nm to 380 nm, in particular UV-A from 315 nm to 380 nm or UV-B from 280 nm to 315 nm or UV-C from 100 nm to 280 nm, visible light from 380 nm to 780 nm or in a range that also includes infrared light from 780 nm to 5.000 nm or in a range of infrared light (thermal radiation) or in a range of microwave radiation, in particular radar radiation in the wavelength range from 1 mm to 10 m, or also another sub-range which is adapted to the wavelength of the light source according to the desired application, in particular in the range of measurement technology. For example, a high transparency can also be selected in the near infrared, whereby the transparency in the visible range can be significantly lower.

This makes optoelectronic devices with such structures particularly suitable for applications in the automotive and aerospace industries for power generation and/or lighting.

However, the periodic dot structure for generating the anti-smudge properties and/or optimizing the wetting properties can also be superimposed with a further dot structure and/or line structure for influencing other properties, such as the wetting properties. The resulting global dot structure, i.e. the resulting dot structure that forms the patterned region, can then be fully periodic or quasi-periodic or non-periodic.

### Hydrophobic Properties

Hydrophobic properties depend on both the chemical and the surface properties, in particular the surface roughness, of a substrate. The inventors have now surprisingly found that by the method according to the invention, in particular hydrophobic substrates can be obtained by introducing micrometer and sub-micrometer scale patterning, in particular overlapping structures (as defined herein) substrate surfaces comprising superhydrophobic and self-cleaning properties. Substrates with superhydrophobic properties are particularly preferably substrates with a hierarchical surface patterning. Hierarchical surface patterning in this context means a surface on which there are regular structures with dimensions in the micrometer range, which in turn comprise a patterning with dimensions in the sub-micrometer range on their surface. Such hierarchical patterning can lead to a high surface roughness.

The inventors have also found that substrates which have been patterned primarily by a device or method disclosed herein are characterized by pronounced hydrophobic properties on the surface of a substrate. By means of the device and method disclosed herein for generating dot structures with dimensions in the micro- and/or sub-micrometer range, patterning is also possible for generating a surface texture, in particular a surface roughness on the surface of a substrate, which results in the substrate comprising hydrophobic or superhydrophobic properties. Hydrophobic material properties can be generated by using direct laser interference patterning to generate a structure with dimensions in the micro- and/or sub-micrometer range. In a preferred embodiment, a structure with dimensions in the micrometer range is first generated on the surface. Then, by moving the beam splitter element in the beam path of the laser, a structure with dimensions in the sub-micrometer range is generated on the surface of the first structure, preferably with multiple irradiation of the substrate. The hierarchical structure generated in this way has hydrophobic or superhydrophobic properties.

To generate a substrate with hydrophobic properties, it is also conceivable that only a dot structure with dimensions in the micro- or sub-micrometer range is generated without moving the beam splitter element in an intermediate step. The dimensions mentioned refer to the interference periods or the size of the intermediate unpatterned regions.

Advantageously, optoelectronic devices with hydrophobic and/or superhydrophobic properties can thus be generated by means of the same process and on the basis of the same device in a technically easily realizable manner by generating a periodic dot structure in the micro- or sub-micrometer range and/or a periodic dot structure with a hierarchical structure in the micro- and sub-micrometer range. By moving the beam splitter element, it is possible to realize at least two, but also any number of additional structures on the surface of the substrate without further changes to the structure, e.g. without replacing optical elements or moving the substrate. This increases both the precision in the alignment of the structures and the speed of the process compared to conventional methods or devices.

The inventors have established a connection between the surface properties of a substrate and the formation of ice on its surface. In particular, so-called anti-icing properties can be generated accordingly, for example on the outer surface of a cover layer, if the structure size on the surface of a substrate is sufficiently small. The results have shown that a substrate with superhydrophobic properties (preferably as defined herein) can also comprise anti-icing properties.

For the purposes of the invention, anti-icing properties are understood to mean that no or only very little water freezes on the surface of a substrate, this property being attributable to the surface properties, in particular the surface roughness.

Such a substrate can be advantageously used in the field of aerospace, wind turbines, automotive components or also telecommunications and antenna technology in order to protect exposed components from icing.

### Hydrophilic Properties

The inventors have further found that substrates patterned primarily by a device or method disclosed herein are characterized by pronounced hydrophilic properties on the surface of a substrate. By means of the device and method disclosed herein for generating dot structures with dimensions in the micro- and sub-micrometer range, patterning is also possible for generating a surface texture, in particular a surface roughness on the surface of a substrate, which results in the substrate comprising hydrophilic or super-hydrophilic properties.

Hydrophilic material properties can be generated by using direct laser interference patterning to generate a dot and/or line structure with dimensions in the micro- and/or sub-micrometer range. In a preferred embodiment, a structure with dimensions in the micrometer range is first generated on the surface. Then, by moving the beam splitter element in the beam path of the laser, a structure with dimensions in the sub-micrometer range is generated on the surface of the first structure, preferably with multiple irradiation of the substrate. The hierarchical structure generated in this way has hydrophilic or super-hydrophilic properties.

To generate a substrate with hydrophilic properties, it is also conceivable that only a structure with dimensions in the micro- or sub-micrometer range is generated without moving the beam splitter element in an intermediate step. According to one embodiment, the patterned region is generated by means of single irradiation, so that LIPSS structures are avoided. In this way, reliable and effective patterning can be achieved.

Advantageously, substrates with hydrophilic and/or super-hydrophilic properties can thus be generated by means of the same process and on the basis of the same device in a technically easily realizable manner by generating a periodic dot structure, in the micro- or sub-micrometer range and/or a periodic dot structure with a hierarchical structure in the micro- and sub-micrometer range is generated. By moving the beam splitter element, it is possible to realize at least two, but also any number of additional structures on the surface of the substrate without further changes to the structure, e.g. without replacing optical elements or moving the substrate. This increases both the precision in the alignment of the structures and the speed of the process compared to conventional methods or devices.

According to an advantageous embodiment of the method, in the laser interference method partial beams are generated by means of a beam splitter element (2) and the interference period (p) of an interference pixel, preferably the first interference period (p1) of the first interference pixel (10), is continuously adjusted by moving the beam splitter element (2). The other optical elements are preferably fixed.

An optoelectronic device produced by the method and device disclosed herein is furthermore suitable for further processing by means of a coating process, wherein the optoelectronic device can receive a physical and/or chemical coating. Such a coating can enhance the properties of the patterned substrate, for example the anti-reflection properties and/or hydrophilic and/or hydrophobic properties. The application of a chemical spray coating and/or the application of a coating by means of chemical vapor deposition and/or sputtering is conceivable.

The invention thus also comprises an optoelectronic device comprising a cover layer with a coating. A coating, preferably a protective coating, preferably a transparent protective coating, is arranged on the patterned surface of the cover layer. Such a coating, preferably a protective coating, preferably a transparent protective coating, is preferably very thin and comprises, for example, a thickness of 1 nm to 5 μm. This essentially preserves the structure of the patterned surface. Preferably, the coating, preferably protective coating, comprises a high hardness, which increases and thus improves the durability of the patterned surface of the cover layer or the optoelectronic device. It is relevant here that the underlying substrate already comprises a patterned surface, i.e. not only the coating is patterned. The combination of a patterned cover layer and a thin coating applied to it can generate special properties of the surface, in particular special wetting properties of the resulting patterned surface, through the surface modification in combination with the properties of the materials.

The coating is arranged on the optoelectronic device on the patterned cover layer in such a way that the first dot structure is formed in the coating and is also formed in the underlying layer adjacent to the coating, in particular the cover layer.

The water contact angle of the surface can be defined by the choice of coating material. The surface tension is modified by functional end groups within the coating, resulting in either hydrophilic or hydrophobic properties.

According to an advantageous embodiment, the material for the coating has hydrophobic wetting properties. As a result, a super-hydrophobic property can also be achieved on an underlying hydrophilic material, such as glass.

According to a further advantageous embodiment, the material for the coating has hydrophilic wetting properties. As a result, a particularly durable and stable superhydrophilic surface can be achieved.

Suitable materials for a hydrophobic coating are (nano) coatings based on silicon dioxide, fluorinated silanes and fluoropolymer coatings, manganese oxide-polystyrene (MnO2/PS) nanocomposites, zinc oxide-polystyrene (ZnO/PS) nanocomposites, coatings based on calcium carbonate and also carbon nanotube structure coatings, i.e. a coating which has carbon nanotubes, preferably transparent carbon nanotube structure coatings, preferably transparent carbon nanotube structure coatings.

Suitable materials for a hydrophilic coating are, for example, ceramic materials such as BeO-based, MgO-based, TiO2-based, AI203-based, ZrO2-based, ZnO-based, SnO-based, SiO2-based, aluminosilicate-based coatings, silicate-based coatings, spinel ceramics such as Mg—Al spinel, aluminum oxynitride (ALON), yttrium aluminum garnet, Yttrium oxide-based coatings, mixed oxide ceramics such as ATZ/ZTA, silicon carbide (SiC), tungsten carbide (WC), aluminosilicates, (layered) silicate materials and combinations thereof TiO2-based coatings, hydrogels/sol-gel coatings, acrylate-based polymers/acrylamide copolymers, polyurethane-based coatings or polyalcohol epoxide.

Coatings such as hydrogels, acrylate-based polymers and silicon dioxide-based coatings as well as carbon nanotubes are advantageously transparent at low thicknesses, in particular up to 5 μm, and thus have a high transmission. This makes it possible to generate cover layers with a coating having a high transmission (as described herein).

Advantageous modifications of the surface include the provision of hydrophobic polymers, such as alkyl chains and/or alkylsilane and/or fluorinated alkyl chains, preferably in the form of polymer brushes. Polymer brushes in the sense of the present invention are dense layers of polymer chains bonded or grafted to a surface, often at one end of the chains. The methods by which surfaces are modified to provide chemical attachment points for the chains are known to those skilled in the art and include, for example, bioconjugation, free radical/anionic/catonic chain polymerization, particularly preferably living chain polymerization and/or surface induced polymerization (SIP). This allows the surface properties such as wettability and adhesion to be subsequently improved after patterning and processing. Preferably, these layers have a layer thickness of 10 to 250 nm, particularly preferably of 20 to 150 nm. These layers are preferably transparent and facilitate influencing physical properties such as hydrophobicity, while the optical properties are not or hardly influenced.

In a particularly preferred embodiment, the coatings are advantageously designed so that a change in conditions, such as temperature or pH value, influences the surface properties.

Thus, the hydrophobicity of the material can be controlled, e.g. by increasing the temperature. This is advantageous for controlling wettability and adhesion.

Layer thicknesses can be determined using atomic force microscopy (AFM) and/or ellipsometry in the UV/Vis range.

### Structure Depth

For generating a surface comprising anti-soiling and/or anti-fogging properties, the inverse cones of an interference pixel according to a preferred embodiment of the present invention have an average structure depth or profile depth in the statistical mean d50 in the range from 0.05 μm to 20 μm, most preferably in the range from 0.05 μm to 10 μm, most preferably from 0.05 μm to 5 μm. profile depth in the statistical mean d50 in the region of 0.05 μm to 20 μm, particularly preferably in the region of 0.05 μm to 10 μm, very particularly preferably from 0.05 μm to 5 μm, in particular from 0.05 μm to 2 μm, more preferably in the region of 0.1 μm to 1 μm, very particularly preferably from 0.5 μm to 800 nm. The structure depth of the inverse cones of an interference pixel is generally described by the mean structure depth (d50), which defines within an interference pixel the proportions of cones with a certain structure depth smaller or larger than the specified value for the structure depth.

The low structure depths make it advantageous to maintain the optical properties, in particular the transparency of the unpatterned substrate, as the periodic dot structures introduced do not have a “disturbing” effect due to the low structure depth. The transparency of the patterned substrate differs from that of the unpatterned substrate of the same structure by a maximum of 10%, preferably by a maximum of 5% or 2%, whereby the transparency of the patterned substrate is preferably lower than that of the unpatterned substrate of the same material and structure. In particular, these shallow structure depths can be generated by single irradiation using a laser pulse with a low laser pulse energy.

In addition, these structure depths are characterized in that the lateral surface of the cones or inverse cones serves as a mirror surface, preferably a quasi-homogeneous mirror surface, which reflects the proportion of reflected incident electromagnetic radiation within the cones and/or inverse cones, as in the case of exploitation of the trap effect, in particular inverse cones, up to the saddle point, whereby at each further reflection point within the cladding surface a proportion of (remaining) electromagnetic radiation couples into the substrate, the outer surface and/or inner surface of which is formed from such a patterned and an unpatterned region (see, for example, FIGS. 4 to 6). FIGS. 4 to 6). According to a preferred embodiment of the invention, the outer surface of the cones or inverse cones is smooth.

Due to the two aforementioned advantages, the periodic structures defined herein in connection with anti-soiling properties and/or anti-fogging properties are particularly suitable for application to the outer surface of a cover layer of an optoelectronic device.

For the purposes of the invention, a patterned substrate, for example a cover layer with anti-soiling properties and/or anti-fogging properties, also describes such a substrate which comprises a patterned region consisting of superimposed structures, wherein a further structure is superimposed on the first periodic dot structure, wherein preferably at least one structure comprises dimensions in the sub-micrometer range, and wherein at least one structure is formed from cones or inverse cones (as defined herein), which can be generated in particular by interfering laser beams. Preferably, the further structure is a line structure or a further periodic dot structure of cones or inverse cones.

### Interference Period

In particular, the patterned region is a dot structure comprising inverse cones with mean dimensions in the micro- or sub-micrometer range, the structure of an interference pixel comprising in particular a mean distance in relation to the respective saddle point or height center of two adjacent cones of an interference pixel of 200 nm to 50 μm, preferably 200 nm to 20 μm, most preferably 200 nm to 10 μm. A further structure, preferably in the nanometer range, can be superimposed on this dot structure in the micrometer range, whereby the average dimension of the superimposed structure preferably comprises dimensions in the region of the laser wavelength λ, or λ/2, in particular from 100 nm to 1,000 nm, particularly preferably from 200 nm to 500 nm. For the purposes of the invention, such a structure is also referred to as a hierarchical structure.

The base area of the inverse cones is preferably 10% to 40% of the interference period of the periodic dot structure.

The present invention also concerns a patterned substrate (5) with a surface with anti-soiling properties, wherein the surface consists of a patterned and unpatterned region, whereby the patterned region is formed by a first periodic dot structure with a first interference period in the micro- or sub-micrometer range. Therein, the periodic dot structure is formed from inverse cones, and wherein the inverse cones are periodically spaced with a distance relative to their respective saddle point or center of height (circular base) in the range from 50 nm to 50 μm. A substrate patterned thus is characterized in that it has a first periodic dot structure with exactly one interference period. There are no superimposed periodic structures that have a second interference period. This results in more precise control of the substrate properties, in particular the transparency of the substrate, which is not impaired by the patterning due to the low structure depths resulting from the fact that each interference pixel is only irradiated once.

In addition, such a substrate offers good control of the hydrophilic properties of the substrate, as a specific water contact angle can be reliably generated on the substrate surface. Such reliable reproducibility of the water contact angle can be achieved by avoiding potentially occurring LIPSS structures by using single irradiation, i.e. a single laser pulse to generate the periodic dot structure, preferably the first periodic dot structure. Single irradiation prevents the occurrence of uncontrolled self-organization processes, which lead to LIPSS structures, also referred to as quasi-periodic wave structures in the sense of the invention.

LIPSS structures disadvantageously often occur when a dot structure, preferably a first dot structure, preferably a first periodic dot structure, within an interference pixel is irradiated several times in succession, i.e. with several pulses. The resulting self-organization processes are difficult to control, which has a negative impact on reproducibility.

Alternatively, a patterned substrate with anti-soiling properties can also be formed from several superimposed, preferably hierarchical structures, comprising at least a first structure with an interference period in the micro- and/or sub-micrometer range and a second structure with an interference period in the micro- and/or sub-micrometer range, wherein the first structure has interference periods and wherein the interference periods can be significantly larger than those of the second structure, in particular the line structure or dot structure, and wherein at least one structure is formed from inverse cones (as defined herein), which can be generated in particular by interfering laser beams. Preferably, the second structure has interference periods with dimensions in the range from 1% to 30%, in particular from 5% to 20%, preferably from 5% to 15% of the dimensions of the interference period of the first dot structure, preferably of the first periodic dot structure. Advantageously, the anti-fogging properties of a substrate can be additionally enhanced by such hierarchical structures, since a higher degree of hydrophilicity can be achieved. This is due to the fact that hierarchical structures significantly increase surface roughness compared to conventional structures in the micro- or sub-micrometer range.

Preferably, the interference period of the first structure, in particular the first periodic dot structure, is in the range from 50 nm to 2 μm, preferably in the range from 100 nm to 1 μm, particularly preferably in the range from 100 nm to 700 nm, most preferably in the range from 200 nm to 500 nm. Thus, the diffraction effects in the visible range can be advantageously reduced so that a rainbow-like shimmer of the surface is prevented.

According to a further embodiment, the interference period of the first structure, in particular the first periodic dot structure, is in the range from 9.5 μm to 50 μm, particularly preferably in the range from 10 μm to 40 μm or 12 μm to 40 μm, most preferably in the range from 15 μm to 30 μm.

According to a further embodiment, the superimposed structure has a quasi-periodic line structure, the line structure being in the form of a wave structure, the material on the surface of the substrate in the region of the superimposed structure having a sequence of wave crests and wave troughs whose interference period is in the sub-micrometer range, preferably in the range from 100 nm to 700 nm, particularly preferably in the range from 100 nm to 500 nm, very particularly preferably in the range from 100 nm to 300 nm. In the sense of the invention, the term quasi-periodic refers to regularly repeating structural features which, however, in contrast to a truly periodic structure, exhibit deviations in the interference period, although these deviations are in a range significantly smaller than the dimensions of the structural features, preferably in the range of 1% to 5% of the dimensions of the structural features. Defects in the structure uniformity, i.e. a missing wave crest or a missing wave trough, are also possible.

The wave structure is formed during the patterning process, i.e. during the impingement of laser pulses, in particular as a result of multiple irradiation, into the substrate to be patterned as a result of the occurrence of a region of high intensity, the patterning taking place by a self-organization process which is stimulated by the at least partial melting of the substrate material by means of laser pulses in a region of high intensity. In particular, the wave structure is generated by utilizing laser-induced periodic surface structures (LIPSS), whereby the occurrence of these surface structures is coupled to the generation of the dot structures, preferably the first periodic dot structures, by means of interfering laser beams. This means in particular that the quasi-periodic wave structures only occur in the areas of the intensity maxima within an interference pixel, in particular within the inverse cones of the first periodic dot structure. The proportion of unpatterned regions occurring in the intensity minima remains the same in relation to patterning by means of a simple periodic dot structure, preferably the first periodic dot structure.

According to one embodiment, the hierarchical structures are generated by multiple irradiation of the same interference pixel with identical process parameters, wherein the process parameters relate to the pulse energy, pulse duration and/or the arrangement of optical elements. Advantageously, this enables patterning that requires a low intensity of the incident laser (partial) beams, which protects the optical elements that are part of the laser patterning device used for patterning.

According to a further embodiment, the hierarchical structures are generated by single irradiation of the same interference pixel using laser (partial) beams with high intensity. Advantageously, a two-dimensional patterning of a substrate, for example with anti-fogging properties, is thus possible by means of interfering laser beams and by utilizing laser-induced periodic surface structures, without having to accept a long processing time or a high number of successively executable process steps. The invention thus enables the simultaneous generation of hierarchical structures which can be used in the technical field both in the area of substrates with anti-fogging properties and in the area of self-cleaning, hydrophobic or superhydrophobic or hydrophilic or super-hydrophilic substrates, optionally also with anti-icing and/or anti-reflection properties.

According to a further embodiment, the hierarchical structures are generated by multiple irradiation of the substrate with deviating process parameters, whereby the process parameters deviate in particular in such a way that a second periodic structure with a deviating interference period is generated. The second periodic structure is a line structure or a dot structure, preferably a dot structure. In the context of the invention, a line structure refers to a so-called 1D structure consisting of parallel structure peaks and structure valleys, which are arranged in a regular sequence of one peak and one valley each. In this embodiment, the second periodic structure is generated analogously to the first periodic dot structure by direct laser interference structuring. The interference period of the second periodic structure can be set using the process parameters. The generation of the second periodic structure is not coupled to the generation of the first periodic structure. Therefore, a substrate patterned thus has a lower proportion of unpatterned surface compared to a substrate patterned only with a first periodic dot structure, since the unpatterned region remaining after the first periodic dot structure has been generated is partially patterned when the second periodic structure is generated with lower interference periods.

Preferably, the proportion of the patterned area, in particular the surface area of the substrate, is 5% to 100%, preferably 10% to 70%, particularly preferably 20% to 50% of the total surface area of the substrate.

The inventors have established a connection between the surface properties of a substrate and the formation of condensation, in particular in the form of fog or mist, on its surface. In particular, so-called anti-fogging properties can be generated if the structure size on the surface of a substrate is sufficiently small. Research results have shown that a substrate with hydrophilic and/or super-hydrophilic properties can also exhibit anti-fogging properties.

For the purposes of the invention, an optoelectronic device with anti-fogging properties describes an optoelectronic device with a cover surface, preferably made of a partially transparent or transparent substrate, with a periodic dot structure with interference periods in the micro- or sub-micrometer region, i.e. in the region of 50 nm to 50 μm. These anti-fogging properties are achieved when the dimensions of the generated structure, i.e. the interference period and the dimensions of the individual inverse cones, increase the surface roughness of the substrate so that the hydrophilic properties of the unpatterned surface are enhanced so that contact angles in the range of 0° to 20°, preferably 0° to 15°, particularly preferably 0° to 10°, most preferably 0° to 5° are formed when wetting with water, thus creating a super-hydrophilic surface. The increased surface roughness is based on the fact that the surface texture is changed in the micro- or sub-micrometer range by the periodic dot structure introduced into the substrate, in particular on the fact that the surface of the substrate has indentations due to the periodic dot structure introduced.

According to a further embodiment of the invention, the interference period of the periodic dot structure is in the range from 50 nm to 2 μm, preferably from 100 nm to 1 μm, more preferably in the range from 100 nm to 700 nm, most preferably in the range from 100 nm to 500 nm. The inventors have discovered that antibacterial properties can be detected on the surface of a substrate at interference periods below 2 μm. Advantageously, a substrate patterned in this way comprises antibacterial, i.e. antiseptic, properties in addition to pronounced anti-fogging properties.

In a preferred embodiment, the periodic dot structure comprises dimensions which are significantly larger, at least 10% to 30% larger, than the bacteria deposited on it. As a result, the bacteria deposited on the surface are isolated and thus rendered harmless. Cell division of the bacteria within the dot structures and the associated outgrowth of the bacteria from the dot structures is prevented due to the dimensions. In a particularly preferred embodiment, the periodic dot structure, preferably the first periodic dot structure, has dimensions that are significantly smaller, at least 10% to 30% smaller, than the bacteria deposited on it. This prevents the bacteria from adhering to the surface and the surface is kept sterile.

According to a further embodiment of the invention, the patterned substrate according to the invention has a periodic dot structure, which is formed from cones. The structural properties, such as the interference period and the hydrophilic properties, in particular the water contact angle, which forms on the surface of the substrate upon wetting, are identical to the properties defined herein of a patterned substrate which has a periodic dot structure, preferably a first periodic dot structure, wherein the dot structure, preferably the first periodic dot structure, is formed from inverse cones. The periodic dot structure produced in this way, preferably a first periodic dot structure, having regularly spaced pegs, is therefore just as suitable for generating a substrate with anti-fogging properties as the periodic dot structure defined herein, preferably a first periodic dot structure, having inverse cones. The structural properties are unchanged.

Furthermore, the cover layer patterned according to the invention is suitable for further processing, for example chemical and/or physical treatment is suitable. In particular, chemical spray coatings and/or sol-gel processes are suitable for increasing the properties defined herein, which are obtained with the patterning according to the invention, or for modifying the properties of the patterned substrate by applying other layers (e.g. anti-reflection properties and/or hydrophobic or superhydrophobic and/or hydrophilic or super-hydrophilic properties).

It may also be possible to subsequently modify the patterned substrates by etching with acids (e.g. hydrofluoric acid) or by leaching the surface in basic solutions. Selective etching is preferable. In this way, acids or bases preferentially attack the generated structural valleys/minima, i.e. the inverse cones. In addition, the degree of etching or the etching speed can be adjusted via the density of the microstructures (degree of coverage of cones per unit area, which is determined by the number and diameter of the inverse cones).

In laser interference patterning, the interference maxima or regions of high intensity of the interference image of several superimposed laser (partial) beams are converted into three-dimensional dot structures in the form of inverse cones on a surface of the substrate or in a plane within the volume of the substrate.

The physical/chemical effects for generating the dot structures only occur above a certain energy threshold, i.e. above a certain intensity threshold. This energy threshold limits the size of the interference pixel, as the intensity of the maxima decreases towards the edges of the superimposed laser (partial) beams. If the intensity at the edges is too weak, no patterning in the sense of the invention takes place in these regions.

The interference image depends on the properties of the superimposed laser (partial) beams. Thus, the structure depth can be influenced by the energy input, i.e. also by the wavelength of the laser (partial) beam. However, the properties of the resulting dot structure when irradiated with a certain pulse length, i.e. the properties of the individual interference pixels, also depend on the properties of the substrate.

According to a preferred embodiment of the present invention, an interference pixel, for example a first, a second and/or a third interference pixel, is applied to the surface of a substrate by means of laser interference patterning by irradiating the substrate with several laser (partial) beams at an angle to the surface of the substrate of 45° to 90° (perpendicular), preferably at an angle of 60° to 90°, particularly preferably at an angle of 75° to 90°, for example at an angle of 76°, 77°, 78°, 79°, 80°, 81°, 82°, 83°, 84°, 85°, 86°, 87°, 87°, 99°, 99° and 99°. In each case in an angle range from/to 76°, 77°, 78°, 79°, 80°, 81°, 82°, 83°, 84°, 85°, 86°, 87°, 88°, 99°, 90°. It is particularly preferred that an interference pixel is applied to the surface of a substrate essentially perpendicularly along a normal to the surface, i.e. at an angle of 90°±1°.

According to an advantageous embodiment of the invention, the “fakir effect” is generated on a surface by selectively roughening an outer and/or inner surface, preferably an outer surface. The aspect ratio of the first dot structure or a second dot structure or a line structure is preferably at least 0.5, preferably at least 1.0. According to a preferred embodiment, the aspect ratio is at most 0.1 and in particular only 0.005. This can be achieved, for example, by an interference period of 20 μm and a structure depth of 100 nm. This can advantageously reduce the adhesion of dust particles, in particular desert sand, especially Kalahari sand. The use of such structures in the extra-terrestrial region also offers many advantages, such structures also significantly reduce the adhesion of particles such as those found on the moon or on Mars if the structure sizes are adapted to the average particle sizes. The aspect ratio is the quotient of structure depth, in particular mean structure depth, and interference period. This means that the structures formed are comparatively deep in relation to a given interference period, which reduces the contact surface and thus reduces the adhesion of liquids and particles, such as bacteria.

### Method

The present invention also includes a method of manufacturing an optoelectronic device according to the invention, in which the outer surface and/or the inner surface of an optoelectronically active layer, a contacting layer and/or a cover layer is formed from a patterned and an unpatterned region. The corresponding aforementioned layer, preferably a transparent layer, comprises a periodic dot structure with dimensions in the micro- and/or sub-micrometer range, which is preferably produced by means of mechanical processes, laser pattern application processes and/or by means of chemical (post) treatment, in particular by direct laser interference patterning.

For the purposes of the invention, the method of manufacturing an optoelectronic device comprises the following steps:

A first layer terminating the optoelectronic device and comprising an inner surface, which can also be referred to as the inner side, is provided. A functional layer, preferably an optoelectronically active layer or a contacting layer, is applied to at least a partial area of the inner surface of the first terminating layer. Furthermore, a second layer terminating the optoelectronic device is applied to at least a partial area of the functional layer. The first or second cover layer is designed as a cover layer comprising an outer surface and an inner surface of the optoelectronic device. The outer surface and/or the inner surface of the cover layer is formed from a patterned and an unpatterned region or the outer surface and/or the inner surface, preferably the outer surface, of the cover layer is patterned following step (c) in such a way that the surface thus patterned is formed from a patterned and an unpatterned region. The patterned regions are preferably generated by means of laser interference patterning. An optoelectronic device can therefore be generated first, the at least one cover layer of which is then patterned, or the patterning of the cover layer, i.e. the generation of the patterned and the unpatterned region, can be carried out first, after which the cover layer generated in this way is integrated with a patterned and an unpatterned region into an optoelectronic device. In any case, the patterned region according to the invention leads to an improvement in the properties of the patterned surface and thus to an increase in efficiency.

Furthermore, the invention relates to a method of manufacturing an optoelectronic device which is characterized in particular by anti-reflection properties and/or anti-soiling properties and/or a reduced reflection due to the trap effect and/or a light path extension due to diffraction at the grating, and comprises the following steps:
a) providing a first terminating layer comprising an inner surface,
b) applying a functional layer, preferably an optoelectronically active layer or a contacting layer, to at least a portion of the inner surface of the first terminating layer,
c) applying a second terminating layer to at least a partial area of the functional layer,
wherein the first or the second terminating layer is formed as a cover layer of the optoelectronic device,
wherein the functional layer, preferably the optoelectronically active layer or the contacting layer, and/or the cover layer comprises an outer surface and an inner surface
wherein the outer surface and/or the inner surface of the functional layer, preferably the optoelectronically active layer or the contacting layer, and/or the cover layer is formed independently of each other from a patterned and an unpatterned region, or
wherein the outer surface and/or the inner surface of the functional layer, preferably the optoelectronically active layer or the contacting layer, and/or the cover layer is patterned in each case independently of one another after the application of the respective layer, in particular immediately after the application of the respective layer (i.e. before the application of the next layer which is used to build up the layer stack), or following step (c), in such a way that it is formed from a patterned and an unpatterned region,
wherein the patterned region comprises a first periodic dot structure independently of each other,
the first dot structure being formed from at least one first interference pixel (10) having a first interference period (p1),
wherein the first interference pixel (10) comprises a periodic lattice of at least three cones or inverse cones, wherein the first interference period of the first periodic dot structure is in the region of 50 nm to 50 μm.

According to a preferred embodiment, the first interference period of the first periodic dot structure is in the region of 100 nm to 1,000 nm. This preferably allows the anti-reflection properties of the substrate, in particular the optoelectronically active layer, the contacting layer and/or the cover layer (as defined herein) to be adjusted.

The subsequent patterning of the already existing devices has the great advantage that already existing devices or optoelectronic modules can also be patterned by means of the method according to the invention and thus their optical properties can be improved due to improved light coupling or decoupling. An increase in efficiency can therefore also be achieved subsequently using the method according to the invention.

Irrespective of this, subsequent patterning, i.e. after application of the respective layer to be patterned, for example immediately after application of the respective layer or following step (c), offers the advantage that the process step of patterning the layer to be patterned can be integrated into the ongoing production process/assembly of an optoelectronic device. Patterning can preferably be carried out using laser structure application methods, in particular direct laser interference patterning. This eliminates the need to transport or relocate the device or individual prefabricated layers. In addition, the parameters of the optoelectronic device, in particular the individual layers of the optoelectronic device, can be better matched to each other by patterning during the process. It may be provided that either the patterning of the outer surface and/or the inner surface and/or within the volume of the functional layer, preferably the optoelectronically active layer or the contacting layer, and/or the cover layer is carried out independently of each other.

According to the invention, the patterned region comprises a first periodic dot structure, wherein the first dot structure is formed from at least one first interference pixel with a first interference period. The first interference pixel in turn comprises a periodic lattice of at least three, preferably seven, periodically arranged cones or inverse cones. The interference period of the first periodic dot structure is in the micro- and/or sub-micrometer region, preferably in the region of 50 nm to 50 μm, particularly preferably in regions as defined herein.

Preferably, the patterning of the surface of a substrate, i.e. the application of the patterned regions comprising a first, second, third and/or further interference pixel, in particular the optoelectronically active layer, the contacting layer and/or the cover layer, is carried out by a mechanical process, laser pattern application process and/or by means of chemical (post) treatment.

For the production of substrates whose outer surface and/or inner surface is formed from a patterned and an unpatterned region, lithography, in particular photolithography or imprint lithography, such as nano-imprint lithography, can be used as a mechanical process, for example. In lithography, a sacrificial layer is usually arranged on the surface of the substrate to be patterned. The sacrificial layer serves to mask the surface to be patterned and can be removed after lithography, in particular completely. For example, the sacrificial layer can be applied to the surface to be patterned and subsequently patterned. The lateral structure of the sacrificial layer can then be transferred to the surface of the substrate, in particular by means of an etching process.

In photolithography, the sacrificial layer is usually a photosensitive resist layer whose chemical properties are locally modified by irradiation through a correspondingly patterned mask, such as a metal mask, which enables the patterned regions to be formed in the sacrificial layer. This process can be used to structure surfaces with structure sizes of a few micrometers in the lateral direction. Both regular and irregular structures can be produced in this way.

Imprint lithography, e.g. nano-imprint lithography, is a microforming process or a contact patterning process in which the surface of a substrate, e.g. the sacrificial layer, is patterned using a forming tool that is suitably patterned. This forming tool, such as a suitably patterned stamp, is pressed into the sacrificial layer. The sacrificial layer can, for example, contain a thermoplastic polymer (Thermoplastic Nano Imprint Lithography, T-NIL) or a photosensitive material (Photo Nano Imprint Lithography, P-NIL). Nano imprint lithography can be used to pattern surfaces in a particularly simple way. In particular, especially small lateral structure sizes, i.e. structures below 1 μm down to the region below 10 nm, can be produced. Nano-imprint lithography is therefore particularly suitable for the production of structure sizes that are in the order of magnitude of the wavelength of radiation in the infrared, visible or ultraviolet spectral range, for example for the production of structures for a photonic grating. Such a method is particularly suitable if the patterned regions of the surface of the substrate are to comprise a periodic dot structure (as defined herein) formed from cones. To produce the molding tool, it is suitable to apply the negative of the desired periodic dot structure to the substrate of the respective layer of the optoelectronic device, in particular a periodic structure formed from cones, for the indirect application or generation of structures on another substrate, for example by laser pattern application processes, in particular direct laser interference patterning, and to transfer this to the surface of the substrate to be patterned.

In a preferred embodiment of the invention, the patterning of the surface of the substrate can be carried out by means of laser pattern application processes, in particular direct laser interference patterning. A periodic intensity distribution is generated on the surface of the substrate or in its volume by interference of pulsed laser beams by splitting the original laser beam into several partial beams and then superimposing these partial beams at any fixed point (focusing point) on the surface of the substrate or in the volume of the substrate.

A patterned region on an outer or inner surface of a cover layer formed from a substrate can be generated as follows:

A substrate (5), preferably extensive and/or transparent substrate, is provided, which is located on a holding device. A laser beam is emitted from a laser radiation source (1). The laser beam is divided by a beam splitter element (2) and at least three, preferably four, sub-beams. The sub-beams hit a focusing element (4), which focuses (bundles) the at least three, particularly preferably four sub-beams on the surface or inside the substrate (5), preferably extensive and/or transparent substrate, so that the sub-beams interfere constructively and destructively on the surface or inside the substrate. Thus, a periodic dot structure in the micro- or sub-micrometer range is generated on the surface or inside the substrate (5), preferably extensive and/or transparent substrate, by laser interference processing. The method is characterized in that the at least three sub-beams are superimposed in such a way that a 2D pattern is created.

According to a variant of the method, the periodic dot structure, preferably the first dot structure, is generated on the outer surface and/or inner surface of the cover layer within an interference pixel by means of a single laser pulse, referred to herein as single irradiation. Single irradiation means that the interference pixel is only exposed once within a processing step using a single laser pulse. A dot structure with an interference period is therefore created within an interference pixel by exposing it with just one laser pulse. Interference pixels arranged next to each other preferably do not overlap, so that a resulting inverse cone is not illuminated again. The maximum laser pulse energy depends on the pixel size and the material. Preferably, the minimum pulse energy is 200 μJ. A high process speed can therefore be achieved. In addition, the use of single irradiation prevents the occurrence of quasi-periodic wave structures, so-called LIPSS, due to uncontrolled self-organization processes, which change the optical properties of the substrate surface in such a way that the transparency and reproducibility of the water contact angle are impaired. Consequently, the occurrence of LIPSS structures can be prevented by single irradiation. As a result, significantly more precise process control can be achieved and a specific property can be reliably generated.

The fact that the periodic dot structure within an interference pixel is generated by applying a single laser pulse by means of single irradiation also has the advantage that very shallow structure depths can be generated, which is particularly advantageous for thin substrates.

Preferably, single irradiation produces low structure depths, which can be adjusted according to the material or the material composition of the substrate. For example, structure depths in the region of 0.05 μm to 2 μm, preferably 0.1 μm to 1 μm, can be achieved. For example, this can also be used to structure substrates that are characterized in particular by anti-reflection properties, whereby the structure depths are in the region of 5 nm to 200 nm, particularly preferably in the region of 5 nm to 150 nm, most preferably 10 nm to 100 nm. The use of a single laser pulse and the lack of pulse overlap between neighboring interference pixels ensures that the structure depths of the periodic dot structure, preferably the first periodic dot structure, are small. Advantageously, this ensures that the optical properties of the substrate, in particular its transparency, are not impaired compared to the unpatterned substrate. In particular, the transparency of the patterned substrate differs from that of the unpatterned substrate of the same structure by a maximum of 10%, preferably by a maximum of 5% or 2%, with the transparency of the patterned substrate preferably being lower than that of the unpatterned substrate of the same material and structure.

In particular, in this method the same interference pixel is processed by means of multiple irradiation. Thus, as a result of the successive multiple irradiation, in particular at least three, especially preferably at least four consecutive pulses, with identical process parameters of an interference pixel, a quasi-periodic line structure superimposed on the periodic dot structure, preferably the first periodic dot structure, is formed as a wave structure by self-organization processes. In the context of the invention, process parameters refer to the setting of the distance between the beam splitter element and the focusing element, the laser pulse duration, the laser pulse energy, the laser wavelength and/or the position of the interference area on the substrate. Self-organization processes refer in particular to so-called LIPSS, as known from the prior art. LIPSS occur as a result of partial heating of the substrate surface and subsequent solidification of the same in the form of regular, quasi-periodic (as defined herein) wave structures.

Hierarchical structures on the surface of the substrate can thus be generated quickly and effectively. It is not necessary to readjust the laser interference device and/or realign the substrate. In addition, the structure parameters of the periodic dot structure, in particular the structure depth, can also be adjusted. Preferably, a shallow structure depth is achieved by adjusting the process parameters, in particular the laser pulse energy, in such a way that the energy input from the multiple irradiation per interference pixel remains as low as possible.

In particular, achieving the desired interference periods of the LIPSS generated by the self-organization processes depends on the material properties of the substrate to be patterned and the properties of the laser beam used for patterning, in particular on the wavelength of the laser beam. A desired interference period can therefore be set via a suitable selection of the laser radiation source.

According to a further embodiment of the invention, a further periodic dot structure or periodic line structure with an interference period different from the interference period of the first periodic dot structure is applied to the substrate by multiple irradiation with different process parameters. The deviating process parameters relate in particular to the distance between the beam splitter element and the focusing element, as a result of which the interference period of the additional periodic dot structure or line structure is changed in comparison to the first periodic dot structure. However, an additional change in the laser pulse duration and/or energy is also possible.

In this way, a flexible second structure with dimensions in the micrometer and/or sub-micrometer range can be advantageously applied to the substrate, which is independent of the first periodic dot structure. This ensures simple alignment of the interference pixels on the substrate. In addition, the proportion of the patterned region on the substrate surface is increased so that specific properties can be achieved, such as the trap effect to reduce reflection.

The advantage of such a method is that the interference periods can be precisely controlled by adjusting the beam splitter element and that the desired interference periods can be set independently of the material properties and the properties of the laser beam used for patterning.

By moving the beam splitter element along its optical axis, the interference period or interference period of the respective interference pixel can be infinitely adjusted. At least two, but also any number of further structuring on the surface of the substrate can be realized without further changes to the structure, e.g. without replacing optical elements or moving the substrate. Preferably, the additional optical elements are fixed when setting or changing the specified or achievable interference period. This increases both the precision in the alignment of the structures and the speed of the process compared to conventional methods or devices.

The laser pulse duration is preferably 50 fs to 1 ns, particularly preferably 50 fs to 10 ps. This short laser pulse duration can prevent or at least minimize undesired and/or uncontrolled melting of the substrate (e.g. in the form of a structural or chemical transformation), in particular as a result of local overheating, e.g. due to excessive energy input. This is particularly advantageous in the case of the “sensitive” materials used herein, which the substrates have or of which the substrates consist.

The laser wavelength is preferably 200 nm to 10 μm, preferably 266 nm to 1064 nm.

The laser pulse energy is preferably 50 μJ to 20 mJ, preferably 300 μJ to 800 μJ, particularly preferably 500 to 800 μJ. This low laser pulse energy per laser pulse can prevent or at least minimize undesired and/or uncontrolled melting of the substrate (e.g. in the form of a structural or chemical transformation), in particular as a result of local overheating, e.g. due to excessive energy input. This is particularly advantageous for the “sensitive” materials used in the substrates or of which the substrates are made.

The present invention also relates to a method of manufacturing an optoelectronic device by laser interference patterning, in particular by a method disclosed herein, comprising the following steps:
a) providing a cover layer or substrate (5), preferably comprising a transparent material,
b) b) applying at least a first interference pixel (10) with a first interference period (p1) on an outer or an inner surface of the cover layer, in particular by means of laser ablation,
c) applying at least one second interference pixel (11) with a second interference period (p2) to the surface of the cover layer processed in step b), in particular by means of laser ablation,
wherein the first and second interference pixels each independently comprise a periodic lattice of at least three inverse cones with a first interference period (p1) and a second interference period (p2), respectively,
wherein the dot structure is formed by superimposed application of the second interference pixel (11) with the first interference pixel (10) within a plane on a surface or in the volume of the substrate,
wherein the ratio of the first interference period (p1) to the second interference period (p2) is in the range of 20:1 to 1:20, preferably in the range of 10:1 to 1:10, particularly preferably in the range of 5:1 to 1:5, in particular 3:1 to 1:3.

In a particularly advantageous way, a patterning can be produced on the substrate, in particular on an at least partially transparent cover layer of an optoelectronic component, which has anti-glare properties.

In the context of the invention, glare refers to the reflection of light from a light source (e.g. the sun) on a transparent substrate, e.g. a window or a screen, which can make it difficult to see what is happening on the screen.

These glare effects can be reduced with the help of an anti-glare treatment of the surfaces (typically produced by coatings in the state of the art). An anti-glare structure scatters incident light on the surface so that reflection can be significantly reduced.

According to a preferred embodiment of the invention, the interference periods of the dot structure of the first interference pixel and the period of the second interference pixel are identical.

According to a preferred embodiment of the present invention, the method according to step c) comprises applying at least one further type of interference pixel with a further interference period (pn), e.g. a third interference pixel (12) with a third interference period (p3) to the surface of the cover layer processed in steps b) and c), in particular the surface of the substrate (5), in particular by means of laser ablation, the further, e.g. the third interference pixel (12) being arranged superimposed on the first interference pixel (10) and second interference pixel (11) in accordance with the features defined herein. The ratio of the further interference period (pn) to the other interference periods is preferably in the range from 20:1 to 1:20, preferably in the range from 10:1 to 1:10, particularly preferably in the range from 5:1 to 1:5, in particular 3:1 to 1:3, whereby the properties defined herein, in particular the anti-glare properties or the reduction of reflection due to the trap effect of the cover layer, can be optimized.

According to a further embodiment of the method, the method additionally comprises the following steps:
providing a further, i.e. second, substrate, the second substrate preferably being transparent, and
embossing the first substrate onto the further substrate, so that a periodic dot structure is formed on the second substrate, which is formed from cones. The first substrate is used as a negative mold for the second substrate. Advantageously, the first substrate can thus be used for embossing any number of further substrates, which can significantly accelerate the process of generating a patterned substrate with anti-fogging properties.

According to a preferred embodiment, in order to apply a periodic structure to a substrate, the periodic dot structure is first generated on a negative mold by means of a laser interference process (as defined herein) and applied by means of the negative mold to the substrate to be patterned, in particular the functional layer, such as the optoelectronically active layer or the contacting layer, or the cover layer, for example by means of imprint lithography processes, such as nanopile lithography.

The inventors of the present invention have discovered that, in addition to the periodicity, the structure depth (i.e. the depth of the inverse cones, measured from the saddle point of the indentation to the apex) also has an influence on the properties, in particular the optical properties or the wetting properties, for example the anti-reflection properties (as defined herein). For example, the structure depth or profile depth of the inverse cones (elevations and depressions) is on statistical average in the range of 0.05 μm to 2 μm, preferably in the range of 0.1 μm to 1 μm.

Preferably, an apparatus is used to produce a patterned substrate (5), preferably extensive and/or transparent substrate, which comprises two deflecting elements (6), (7). The deflecting elements (6), (7) are arranged in the optical path (3) of the laser between the beam splitter element (2) and the focusing element (4). The deflecting elements (6), (7) serve to widen the diffraction angle of the at least three, particularly preferably four sub-beams, in which they interfere on the surface or in the interior of the substrate (5), preferably extensive and/or transparent substrate. By adjusting the distances between the optical elements, it can be ensured that only the beam splitter element (2) needs to be movable along its optical axis in order to change the interference period. This enables easier adjustment processes during machining.

In a particularly preferred embodiment, a transparent material is provided as an extensive substrate. Due to the translucency of the transparent material, laser interference processing inside the substrate is possible, preferably with an embodiment of the above-mentioned apparatus.

In a preferred embodiment, an apparatus is used for producing a patterned substrate, preferably extensive and/or transparent substrate, which uses a pulsed laser radiation source (1). In a particularly preferred embodiment, an apparatus for producing a patterned substrate, preferably extensive and/or transparent substrate, is used which has a holding device for the substrate which is freely movable in the xy plane, perpendicular to the optical path (3) of the laser beam emitted by the laser radiation source (1).

The pixel density Pd, i.e. the distance at which an interference pixel of width D can be applied to the substrate, preferably extensive and/or transparent substrate, can be adjusted via the frequency of the laser radiation source (1), f, and the speed of movement of the holding device, v:

$$Pd = v / f$$

If the width of the interference pixel, D, is greater than the pixel density Pd, neighboring interference pixels overlap within an area. This area is known to the skilled person as the pulse overlap, OV. It can be calculated as:

$$OV = ( D - Pd ) / D$$

In a preferred embodiment, in the process for producing a patterned substrate, preferably extensive and/or transparent substrate, Pd is smaller than D. The resulting pulse overlap OV leads to multiple irradiation of the substrate, preferably extensive and/or transparent substrate. Preferably, non-textured surfaces can thus be avoided.

In a particularly preferred embodiment, the same interference pixels are irradiated several times in the process for producing a patterned substrate, preferably extensive and/or transparent substrate. This makes it possible to increase the depth of the resulting microstructures.

The advantage of a patterned substrate, preferably extensive and/or transparent substrate, produced by such a method is the high regularity of the generated periodic dot structures with structure dimensions in the micrometer or sub-micrometer range. A periodic dot structure produced in this way with dimensions in the micro- or sub-micrometer range preferably has a coefficient of variation (a value resulting from dividing the standard deviation by the average value) of the cone cross-section of 15% or less, more preferably 10% or less, even more preferably 5% or less.

Multiple irradiation of a substrate is particularly suitable for producing hierarchical structures. Multiple irradiation of the same interference pixel causes at least partial melting of the substrate material, whereby a wave structure is formed during the patterning process, i.e. when a laser pulse hits the substrate, as a result of the occurrence of a high intensity region. The structure, in particular the wave structure, is formed by a self-assembly process. In particular, the wave structure is superimposed on a periodic dot structure in the micro- or sub-micrometer range, which can be generated by means of laser interference patterning. Thus, a hierarchical patterning can be generated in a substrate with one process step. According to a preferred embodiment of the invention, multiple irradiation, preferably 2-fold to 400-fold, in particular 20-fold to 300-fold, particularly preferably 50-fold to 200-fold irradiation of the same interference pixel is therefore carried out on the substrate, whereby a wave structure (as defined herein) is formed, in particular a periodic dot structure is formed from superimposed structures, wherein at least one structure has dimensions in the sub-micrometer range, in particular a quasi-periodic wave structure, and wherein at least one structure is formed from inverse cones. The time offset between the individual pulses is particularly preferably in the range of the pulse duration of the laser pulse, preferably in the range from 50 fs to 1 ns, particularly preferably in the range from 10 fs to 50 ps, very particularly preferably in the range from 10 fs to 10 ps.

Hierarchical patterning refers to a pattern in which a first structure with dimensions in the micro- or sub-micrometer range, which corresponds to an interference pattern, is superimposed by a further structure which has dimensions which are below the dimensions of the first structure and which is formed by a self-assembly process. Preferably, the dimensions of the further structure, which is formed by a self-assembly process, are in the range of 1% to 30% of the dimensions of the first structure, which corresponds to an interference pattern.

In addition, the method defined herein makes it possible to provide a substrate with hierarchical patterns by means of the same apparatus and, moreover, in the same process step, whereas conventional processes proceed successively, i.e. are not capable of simultaneously generating a first structure with dimensions in the micro- or sub-micrometer range, which corresponds to an interference pattern, and a further structure, which is formed by a self-assembly process.

Moving the substrate to be patterned, preferably extensive and/or transparent substrate, in the laser beam is comparatively time-consuming and slow due to the relatively large masses moved in the process. It is therefore advantageous to provide the substrate, preferably extensive and/or transparent substrate, in a fixed position during processing and to realize the extensive patterning of the substrate by focusing the sub-beams on the surface or the volume of the substrate by manipulating the laser sub-beams with optical elements (focusing mirrors or galvo mirrors (laser scanners)) in the beam direction. As the masses moved in this process are relatively small, this is possible with far less effort or much faster. Preferably, the substrate is stationary during the process.

The two-dimensional patterning of the substrate is of course also possible in principle by moving the substrate in the laser beam.

The invention also relates to a method of manufacturing an optoelectronic component which is characterized in particular by anti-reflection properties, reduced reflection due to the trap effect and/or light path lengthening due to diffraction at the grating, and comprises the following steps:
a) providing a first terminating layer having an inner surface,
b) applying a functional layer, preferably an optoelectronically active layer or a contacting layer, to at least a portion of the inner surface of the first terminating layer,
c) applying a second terminating layer to at least a partial area of the functional layer,
wherein the first or the second terminating layer is designed as a cover layer of the optoelectronic component,
the volume, in particular a plane in the volume, of the functional layer, preferably the optoelectronically active layer or the contacting layer, and/or of the covering layer being formed in each case independently of one another from a patterned and an unpatterned region, or
wherein the volume, in particular a plane in the volume, of the functional layer, preferably the optoelectronically active layer or the contacting layer, and/or the cover layer is patterned in each case independently of one another at step (c) in such a way that it is formed from a patterned and an unpatterned region,
the patterned region in each case independently of one another having a first periodic dot structure,
the first dot structure being formed from at least one first interference pixel with a first interference period (p1),
wherein the first interference pixel comprises a periodic lattice of at least three cones or inverse cones,
wherein the first interference period of the first periodic dot structure is in the range from 50 nm to 50 μm.

According to a preferred embodiment, the first interference period of the first periodic dot structure is in the range from 100 nm to 1,000 nm. Preferably, the anti-reflection properties of the substrate, in particular of the optoelectronically active layer, the contacting layer and/or the cover layer (as defined herein) can thereby be adjusted.

A patterned optoelectronic device generated by the method and apparatus disclosed herein is further suitable for further processing by means of a coating process, wherein the optoelectronic device may receive a physical and/or chemical coating. Such a coating can enhance the properties of the patterned substrate, for example the anti-reflection properties and/or hydrophilic and/or hydrophobic properties. The application of a chemical spray coating and/or the application of a coating by means of chemical vapor deposition and/or sputtering is conceivable.

The invention thus also comprises a method in which the patterned optoelectronic device is coated after patterning according to one of the types of coating mentioned herein. As a result, the patterning, in particular the first periodic dot structure, then also occurs in the coating, but also in the underlying cover layer.

### Apparatus

### Laser Radiation Source

The apparatus for generating a patterned substrate with anti-fogging properties comprises a laser radiation source (1) that emits a laser beam. The radiation profile of the emitted laser beam corresponds either to a Gaussian profile or a top-hat profile, particularly preferably a top-hat profile. The top-hat profile is helpful in order to pattern or cover a substrate surface to be patterned more homogeneously and, if necessary, to enable a faster patterning rate.

In a particularly preferred embodiment, the laser radiation source (1) is a source that generates a pulsed laser beam. The pulse width of the pulsed laser radiation source is, for example, in the range from 10 femtoseconds to 100 nanoseconds, in particular 50 femtoseconds to 10 nanoseconds, most preferably 50 femtoseconds to less than 100 picoseconds.

Unless expressly stated otherwise, the term laser beam or sub-beam does not refer to an idealized beam of geometric optics, but to a real light beam, such as a laser beam that does not have an infinitesimally small beam cross-section, but an extended beam cross-section (Gaussian distribution profile or an intrinsic top-hat beam).

Top-hat profile or top-hat intensity distribution refers to an intensity distribution that can essentially be described by a rectangular function (rect (x)), at least with regard to one direction. Real intensity distributions that show deviations from a rectangular function in the percentage range or sloping edges are also referred to as top-hat distributions or top-hat profiles. Methods and apparatuses for generating a top-hat profile are well known to those skilled in the art and are described, for example, in EP 2 663 892. Optical elements for transforming the intensity profile of a laser beam are also already known. For example, diffractive and/or refractive optics can be used to transform laser beams with a Gaussian-shaped intensity profile into laser beams that have a top-hat-shaped intensity profile in one or more defined planes, such as a Gauss-to-top hat focus beam shaper from TOPAG Lasertechnik GmbH, see e.g. DE102010005774A1. Such laser beams with top-hat-shaped intensity profiles are particularly attractive for laser material processing, especially when using laser pulses that are shorter than 50 ps, as the essentially constant energy or power density enables particularly good and reproducible processing results to be achieved.

The laser radiation source (1) comprised by the apparatus according to the invention can have an intensity of 0.01 to 5 J/cm², particularly preferably 0.1 to 2 J/cm², very particularly preferably 0.1 to 0.5 J/cm². The apparatus according to the invention allows the intensity of the laser radiation source to be flexibly selected within a range. The beam diameter plays no role in the generation of the interference pattern on the substrate, preferably extensive and/or transparent substrate. Due to the preferred arrangement of the optical elements in the optical path of the laser, no unit is required to control the intensity of the laser beam.

The laser radiation source is preferably configured to emit wavelengths in the range from 200 nm to 15 μm (e.g. CO2 lasers in the range from 10.6 μm), most preferably in the range from 266 nm to 1,064 nm. Suitable laser radiation sources include UV laser beam sources, laser radiation sources (155 to 355 nm) that emit green light (532 nm), diode lasers (typically 800 to 1000 nm) or laser radiation sources that emit radiation in the near infrared (typically 1064 nm), in particular with a wavelength in the range of 200 to 650 nm. Lasers suitable for microprocessing are known to the skilled person and include, for example, HeNe lasers, HeAg lasers (approx. 224 nm), NeCu lasers (approx. 249 nm), Nd:YAG lasers (approx. 355 nm), YAG lasers (approx. 532 nm), InGaN lasers (approx. 532 nm).

According to a further embodiment, the apparatus according to the invention has at least one further laser radiation source which is designed such that it generates a laser beam which interferes with the laser beam of the first laser radiation source or the laser beam of the first laser radiation source, which is divided into sub-beams, in an interference region. The additional laser radiation source has the same properties as described above, although these may be similar to or different from those of the first laser radiation source.

### Optical Elements

The present invention comprises a plurality of optical elements. These elements are primarily prisms and lenses.

These lenses can be refractive or diffractive. Spherical, aspherical or cylindrical lenses can be used. In a preferred embodiment, cylindrical lenses are used. This makes it possible to compress the overlapping areas of the sub-beams (also referred to herein as interference pixels) in one spatial direction and stretch them in another. If the lenses are not spherical/aspherical but cylindrical, this has the advantage that the beams can be deformed at the same time. This allows the processing spot (i.e. the interference pattern created on the substrate) to be deformed from a point to a line containing the interference pattern. With sufficient energy from the laser, this line can be in the range of 10-15 mm long (and approximately 100 μm thick).

Furthermore, Spatial Light Modulators (SLM) can be used for beam shaping. The use of SLMs for spatial modulation of the phase or the intensity or the phase and intensity of an incident light beam is known to the person skilled in the art. The use of Liquid Crystal on Silicon (LCoS) SLMs for beam splitting is described in the literature and is also conceivable in the apparatus according to the invention. In addition, SLMs can also be used to focus the sub-beams on the substrate. Such an SLM can be controlled optically, electronically or acoustically.

All the optical elements described below are arranged in the optical path (3) of the laser. For the purposes of the invention, the optical path of the laser refers to the path of both the laser beam emitted by the laser radiation source and the path of the sub-beams split by a beam splitter element. However, the optical axis of the optical path (3) is understood to be the optical axis of the laser beam emitted by the laser radiation source (1). Unless otherwise explained, all optical elements are arranged perpendicular to the optical axis of the optical path (3).

### Beam Splitter Element

A beam splitter element (2) is located in the optical path (3) of the laser, behind the laser radiation source (1). The beam splitter element (2) can be a diffractive or a refractive beam splitter element. Diffractive beam splitter elements are also referred to as diffractive optical elements (DOE) for short. For the purposes of the invention, a diffractive beam splitter element refers to an optical element which contains microstructures or nanostructures, preferably microstructures, which split an incoming beam into different beams according to the different diffraction orders. For the purposes of the invention, a refractive beam splitter element refers to a beam splitter element in which the beams are split on the basis of refractive index differences at surfaces, these usually being transparent optical elements, such as a prism or a double prism. Preferably, the beam splitter element (2) is a diffractive optical beam splitter element.

According to a preferred embodiment, the beam splitter element is a single optical element, in particular a diffractive or refractive optical element, which is constructed in such a way that the subdivision of the incident laser beam is based on the optical properties of the beam splitter element. This advantageously ensures that a simpler optical structure can be realized compared to a multi-part beam splitter element, which consists of several optical elements (e.g. mirrors, prisms, etc.). The desired beam splitting can be achieved without the need to calibrate or adjust the arrangement of several optical elements in relation to each other. The mobility of the beam splitter element in the optical path is also easy to realize, as only a single optical element needs to be moved. In addition, the use of a one-piece beam splitter element results in less components that are susceptible to wear and may need to be replaced.

According to one possible embodiment, the beam splitter is designed as a polarizing beam splitter, in which one of the resulting beams has a different polarization than the other, or as a non-polarizing beam splitter, in which the polarization plays no role in the splitting of the beam.

In a preferred embodiment, the beam splitter element (2) splits the emitted laser beam into at least 3, preferably at least 4, in particular 4 to 8, i.e. 4, 5, 6, 7 or 8 sub-beams.

In a further embodiment, the beam splitter element (2) splits the emitted laser beam into at least 2, preferably at least 3 to 4, in particular 4 to 10, i.e. 4, 5, 6, 7, 8, 9 or 10 sub-beams.

The beam splitter element (2) is freely movable along its optical axis. In other words, it can be moved along its optical axis towards or away from the laser radiation source. The movement of the beam splitter element (2) changes the expansion of the at least 3 sub-beams so that they hit a focusing element at different distances from each other. As a result, the angle θ at which the sub-beams hit the substrate (5), preferably extensive and/or transparent substrate, can be changed. This results in a seamless change in the interference period pₙ from a superposition of four sub-beams to

$$p = \frac{λ}{\sqrt{2} sin θ}$$

where λ is the wavelength of the emitted laser beam.

According to a preferred embodiment of the present invention, the beam splitter element is designed as a rotating element. This advantageously allows the polarization of the sub-beams to be modified.

Particularly preferably, the angle θ at which the partial beams hit the substrate (5), preferably extensive and/or transparent substrate, is 0.1° to 90°.

The angle θ is also dependent on the distances between the optical elements, in particular the distance between the optical elements and the beam splitter element, especially the distance between the focusing element and the beam splitter element. Depending on the desired interference period to be generated on or in the extensive and/or transparent substrate, the position of the beam splitter element can be adjusted or calculated in such a way that the desired interference period can be set. The position of the optical elements comprised by the apparatus, in particular the position of the focusing element in relation to the beam splitter element, is taken into account in such a way that the position of the beam splitter element can be adjusted accordingly if the distance between the optical elements is greater or smaller.

In order to generate a patterned substrate with anti-reflection properties, it has been found to be particularly advantageous if a distance of 10 mm to 50 mm or from 150 mm to 200 nm is set from the beam splitter element (2) to the deflecting element (7).

According to a preferred embodiment of the invention, the apparatus also comprises a measuring device, in particular a measuring device which operates by means of a laser or an optical sensor, which is configured to measure the position of the beam splitter element and, if appropriate, the distance of the beam splitter element from the other optical elements, in particular the position of the focusing element.

Furthermore, the apparatus according to the invention can comprise a control device which is connected to the measuring device in terms of signal technology and which is connected in particular to a computing unit in such a way that the measured position of the beam splitter element can be compared with a first predetermined comparison value, the control device being configured in terms of programming so that, if the distance of the beam splitter element to the other optical elements, in particular the position of the focusing element and/or the deflecting element (7) is greater or smaller than the first predetermined comparison value, then a control signal is generated via the control device, with which at least one position of an optical element, in particular of the beam splitter element (2), is changed in such a way, in particular of the beam splitter element (2) in relation to the deflecting element (7), that the desired interference period is generated on the substrate.

In this context, the method for producing a substrate with a dot structure in the micro- or sub-micrometer range, in particular after step (a), can also comprise the following steps:
(i) measuring the position of the beam splitter element (2) and, if necessary, the distance of the beam splitter element to the further optical elements or to at least one of the further optical elements, in particular to the position of the focusing element (4) and/or the deflecting element (7),
(ii) comparing the measured position of the beam splitter element with a first predetermined reference value, and
(iii) if the measured distance of the beam splitter element to the other optical elements or to at least one of the other optical elements, in particular to the position of the focusing element (4) and/or the deflecting element (7), is greater or smaller than the first predetermined reference value: changing the position of the optical element, in particular of the beam splitter element (2) (in particular in relation to the other optical elements, especially preferably of the beam splitter element (2) in relation to the deflecting element (7)), in such a way that the desired interference period is produced on the substrate.

The laser beam division within the beam splitter element (2) can be conducted either by a partially reflective beam splitter element, for example a semi-transparent mirror, or by a transmissive beam splitter element, for example a dichroic prism.

In a preferred embodiment, further beam splitter elements are arranged in succession of the beam splitter element (2) in the optical path of the laser. These beam splitter elements are arranged in such a way that they split each of the at least three sub-beams into at least two further sub-beams. This allows a higher number of sub-beams to be generated, which are directed onto the substrate, preferably extensive and/or transparent substrate, so that they interfere on the surface or inside the substrate. This allows the interference period of the interference pattern to be adjusted.

### Focusing Element (4)

Furthermore, a focusing element (4) is arranged in succession of the beam splitter element (2) in the optical path (3) of the laser, which is configured so that the sub-beams pass through it in such a way that the sub-beams interfere on the surface or inside a substrate (5) to be patterned in an interference region. The focusing element (4) focuses the at least three sub-beams in a spatial direction without focusing the at least three sub-beams in the spatial direction perpendicular thereto. For example, the focusing element (4) can be a focusing optical lens. In the context of the invention, focusing means bundling the at least three sub-beams on the surface or inside a substrate, preferably extensive and/or transparent substrate.

The focusing element (4) can be freely movable in the optical path (3). According to a preferred embodiment of the present invention, the focusing element (4) is fixed in the optical path or along the optical axis.

It is understood that the optical elements defined herein can, for example, be arranged in a common housing for beam splitting and for aligning the sub-beams in the direction of a substrate to be patterned accordingly.

In a preferred embodiment, the focusing element (4) is a spherical lens. The spherical lens is configured so that the incident at least three sub-beams pass through it in such a way that they interfere in an interference region on the surface or inside the substrate (5) to be patterned, preferably extensive and/or transparent substrate. The width of the interference region is preferably 1 to 600 μm, particularly preferably 10 to 400 μm, most preferably 20 to 200 μm. In this way, a high patterning rate, for example as defined herein, can be set at the same time.

In a particularly preferred embodiment, the focusing element (4) is a cylindrical lens. The cylindrical lens is configured so that the area in which the at least three sub-beams overlap on the surface or inside the substrate (5), preferably extensive and/or transparent substrate, is stretched in a spatial direction. As a result, the area of the substrate on which the interference pattern can be generated takes on an elliptical shape. The large half-axis of this ellipse can reach a length of 20 μm to 15 mm. This increases the area that can be patterned within one irradiation.

### First Deflecting Element

In a particularly preferred embodiment, a deflecting element (7) is located before the focusing element (4) and in succession of the beam splitter element (2), which is preferably arranged in the optical path (3) of the laser. This deflecting element (7) is used to widen the distances between the at least three sub-beams and can thus also change the angle at which the sub-beams hit the substrate (5), preferably extensive and/or transparent substrate. It is configured so that it increases the divergence of the at least three sub-beams and thus moves the area in which the at least three sub-beams interfere along the optical axis of the optical path (3) away from the laser radiation source (1).

In the context of the invention, widening the distances between the at least three sub-beams is understood to mean that the angle of the respective sub-beams to the optical axis of the laser beam emitted by the laser radiation source (1) is increased.

The widening and the resulting deflection of the sub-beams has the advantage that the sub-beams can be bundled more strongly by the focusing element (4). This results in a higher intensity in the area in which the at least three sub-beams interfere on the surface or inside the substrate (5), preferably extensive and/or transparent substrate.

The appropriate choice of deflecting element means that a unit for controlling the intensity of the laser beam can be dispensed with. In a preferred embodiment of the apparatus, a deflecting element (7) is used which, by expanding the at least three sub-beams, allows the at least three sub-beams to be focused on the substrate (5) by means of a focusing element (4), whereby the intensity of the interference points on the surface or inside the substrate, preferably extensive and/or transparent substrate, can be achieved without additional adjustment of the intensity of the laser radiation source (1). This has the advantage that laser radiation sources with low intensity (power per area) can also be used for patterning the substrate while generating the periodic dot structure, whereby the optical elements are protected against wear and lower structure depths are easier to generate.

### Further Deflecting Element

Furthermore, it can be provided that a further deflecting element (6) is arranged in succession of the beam splitter element (3) in the optical path (3) of the laser radiation source (1), which deflects the sub-beams in such a way that they run essentially parallel to one another after emerging from the further deflecting element (6). As a result, the apparatus can be configured so that the processing point, i.e. the point at which the at least three sub-beams interfere on the surface or inside the substrate, preferably extensive and/or transparent substrate, remains constant when the beam splitter element is moved in the optical path of the laser along its optical axis. The term “essentially parallel” should be understood in the context of this document to mean an angular offset of between +15° and −15°, in particular only between +10° and −10°, very preferably between +5° and −5° between the two sub-beams, though in particular of course not an angular offset of 0°.

The further deflecting element (6) can be a conventional refractive lens. Alternatively, however, the further deflecting element (6) can also be designed as a diffractive lens (e.g. Fresnel lens). Diffractive lenses have the advantage that they are considerably thinner and lighter, which simplifies miniaturization of the apparatus disclosed herein.

By appropriately selecting the refractive indices of the optical elements (4), (6) and (7), the distances between the optical elements and the substrate as well as the interference period p can be adjusted. All optical elements, with the exception of the beam splitter element (2), can preferably be fixed within the optical path (3) of the laser. This particularly preferred embodiment therefore offers the advantage that only one element, namely the beam splitter element (2), needs to be moved to adjust the interference region or the interference angle. This saves process steps when configuring the apparatus, such as calibrating the apparatus to the desired interference period. Furthermore, a fixed setting, i.e. where preferably all optical elements are fixed within the optical path (3) of the laser, prevents wear of the optical elements.

### Polarization Element

In a further embodiment, a polarization element (8) is located behind the deflecting element, particularly preferably in a setup with two deflecting elements (6), (7) behind the further deflecting element (6), and in front of the focusing element (4) in at least one of the optical paths of the at least 3 sub-beams there is one polarization element per sub-beam. The polarization elements can modify the polarization of the sub-beams relative to one another. This allows the resulting interference pattern, which the at least 3 sub-beams map on the surface or in the volume of a substrate, preferably extensive and/or transparent substrate, to be modified. By arranging a polarization element (8) in at least one of the optical paths of the sub-beams, preferably not in each optical path of the sub-beams, preferably in an optical path up to (n−1) optical paths, where n is the number of sub-beams generated in the application process, the polarization plane of at least one sub-beam in the beam path can be advantageously rotated and thus the pattern of an interference pixel in the plane of the substrate can be “disturbed”.

In particular, the interfering sub-beams can therefore be non-polarized, linearly polarized, circularly polarized, elliptically polarized, radially polarized or azimuthally polarized.

### Optical Element for Beam Shaping

In a further embodiment, the laser radiation source (1) has a radiation profile that corresponds to a Gaussian profile as described above. In such an embodiment, a further optical element for beam shaping can be located behind the laser radiation source (1) and in front of the beam splitter element (2). This element is used to adjust the radiation profile of the laser radiation source to a top-hat profile.

An optical element with a concave parabolic or planar reflective surface can also be provided in the apparatus according to the invention, whereby the optical element is designed to be rotatable about at least one axis or displaceable along the optical path (3), for example. As a result, an additional focusing element (4) positioned in the optical path (3) or an additional deflecting element (6) can be dispensed with if necessary. For example, this optical element can be used to direct laser beams or laser sub-beams onto the surface of the focusing element (4) or another focusing optical element before the beams reach the substrate to be patterned to form structure elements.

Alternatively, for example, at least one optical element with a concave parabolic or planar reflective surface can also be provided, which is designed to be rotatable about at least one axis or displaceable along the optical path (3), for example, this optical element being positioned in succession of the first deflecting element (7) and the further deflecting element (6) in the optical path. For example, the sub-beams can be deflected in the optical path (deflecting mirror) or focused in the optical path in such a way that the substrate to be patterned can be positioned in a fixed position during processing (so-called focusing mirror or galvo mirror (laser scanner) (9)).

An embodiment comprising a polygon scanner is also conceivable. In this embodiment, at least one optical element comprises a periodically rotating prism, preferably a periodically rotating mirror prism, in particular a polygon mirror or polygon wheel, as well as a focusing element (4) arranged in succession of the periodically rotating prism in the optical path. The focusing element is configured so that the sub-beams pass through it in such a way that the sub-beams interfere on the surface or inside a substrate (5) to be patterned in an interference region. In a preferred embodiment, the optical element further comprises at least one further deflecting element, for example a reflective deflecting element for deflecting the sub-beams in the optical path. The at least one further deflecting element can be arranged preceding and/or in succession of the periodically rotating prism in the optical path. The at least one further deflecting element is arranged preceding of the focusing element in the optical path.

Such a setup advantageously allows a surface of a substrate to be scanned quickly, so that a high patterning rate of up to 3 m²/min, in particular in the range of 0.05 to 2 m²/min, especially preferably in the range of 0.1 to 1 m²/min, most preferably in the range of 0.1 to 0.9 m²/min can be achieved. The exact patterning rate depends in particular on the available laser power. With future technologies that have a higher laser power, even higher patterning rates can therefore be achieved.

### Holding Device for the Substrate

In a further embodiment, the substrate (5), preferably extensive and/or transparent substrate, is movable in the xy plane. By moving the substrate (5), preferably extensive and/or transparent substrate, in the xy plane, extensive processing by means of laser interference patterning can be ensured. In each processing step (i.e. laser pulse that hits the substrate to be patterned), an interference pixel (as defined herein) is generated, which has a size D depending on the angle of incidence and the intensity distribution of the laser beam, as well as the focusing properties of the optical elements. The distance between the different interference pixels, the pixel density Pd, is determined by the repetition rate of the laser radiation source (1) and the movement of the substrate in relation to the focusing point of the optical elements, i.e. the point at which the interference region is generated on the surface or inside the substrate. If the pixel density Pd is smaller than the size of the interference pixels D, homogeneous processing over a large area is possible.

By moving the substrate in relation to the focusing point (which generates the interference pixel) in combination with pulsed laser (sub-) beams, an extensive, optionally homogeneous and periodic dot structure can be generated on the surface or inside a substrate, preferably extensive and/or transparent substrate.

As an alternative to moving the substrate in relation to the focusing point, the focusing point can also be moved over the sample or the substrate (e.g. using scanner-based methods). Moving the substrate to be patterned, preferably extensive and/or transparent substrate, in the laser beam can be comparatively time-consuming and slow due to the relatively large masses moved in the process. It is therefore advantageous to provide the substrate, preferably extensive and/or transparent substrate, in a fixed position during processing and to realize the extensive patterning of the substrate by focusing the sub-beams on the surface or the volume of the substrate by manipulating the sub-laser beams with optical elements (focusing mirrors or galvo mirrors (laser scanners)) in the beam direction. As the masses moved in this process are relatively small, this is possible with far less effort, which is to say much faster. Preferably, the substrate is stationary during the process.

### Use

A further aspect of the invention relates to the use of a substrate defined herein, in particular an optoelectronically active layer, a contacting layer or a cover layer, the outer surface and/or inner surface of which is formed from a patterned and an unpatterned region for an optoelectronic device and/or an optoelectronic module.

For example, the invention also includes the use of a substrate, in particular as an optoelectronically active layer, as a contacting layer or as a cover layer for an optoelectronic device, wherein the substrate comprises an outer surface and an inner surface, wherein the substrate is at least partially transparent, wherein the outer surface and/or inner surface and/or in the volume, in particular within a plane in the volume, of the substrate is formed from a patterned and an unpatterned region, wherein the patterned region comprises a first periodic dot structure, wherein the first dot structure is formed from at least one first interference pixel with a first interference period (pixel), of the substrate is formed from a patterned and an unpatterned region, wherein the patterned region comprises a first periodic dot structure, wherein the first dot structure is formed from at least one first interference pixel with a first interference period (p1), wherein the first interference pixel comprises a periodic lattice of at least three cones or inverse cones, and wherein the first interference period of the first periodic dot structure is in the region of 50 nm to 50 μm.

The present invention also comprises the use of a substrate as a cover layer for an optoelectronic device, in particular with anti-smut properties (as defined herein), wherein the substrate comprises an outer surface and an inner surface, wherein the substrate is at least partially transparent, wherein the outer surface of the substrate is formed from a patterned and an unpatterned region, wherein the patterned region comprises a first periodic dot structure wherein the first dot structure is formed from at least one first interference pixel (10) with a first interference period (p1), wherein the first interference pixel (10) comprises a periodic lattice of at least three cones or inverse cones, wherein the interference period of the first periodic dot structure is in the region of 200 nm to 50 μm, and wherein the water contact angle of the outer surface of the cover layer is less than 20° or greater than 150°.

Furthermore, the present invention relates to the use of a substrate, in particular as an optoelectronically active layer, as a contacting layer or as a cover layer for an optoelectronic device, in particular with anti-reflection properties (as defined herein), wherein the substrate comprises an outer surface and an inner surface, wherein the substrate is at least partially transparent, wherein the outer surface and/or inner surface and/or in the volume, in particular within a plane in the volume, of the substrate is formed from a patterned and an unpatterned region, wherein the patterned region comprises a first periodic dot structure, wherein the first dot structure is formed from at least one first interference pixel (10) with a first interference period (p1), wherein the first interference pixel (10) comprises a periodic lattice of at least three cones or inverse cones, and wherein the first interference period of the first periodic dot structure is in the region of 100 nm to 1,000 nm.

### EXAMPLES OF EMBODIMENTS

The present invention is explained in more detail using the following figures and examples of embodiments, without limiting the invention to these.

Herein shows

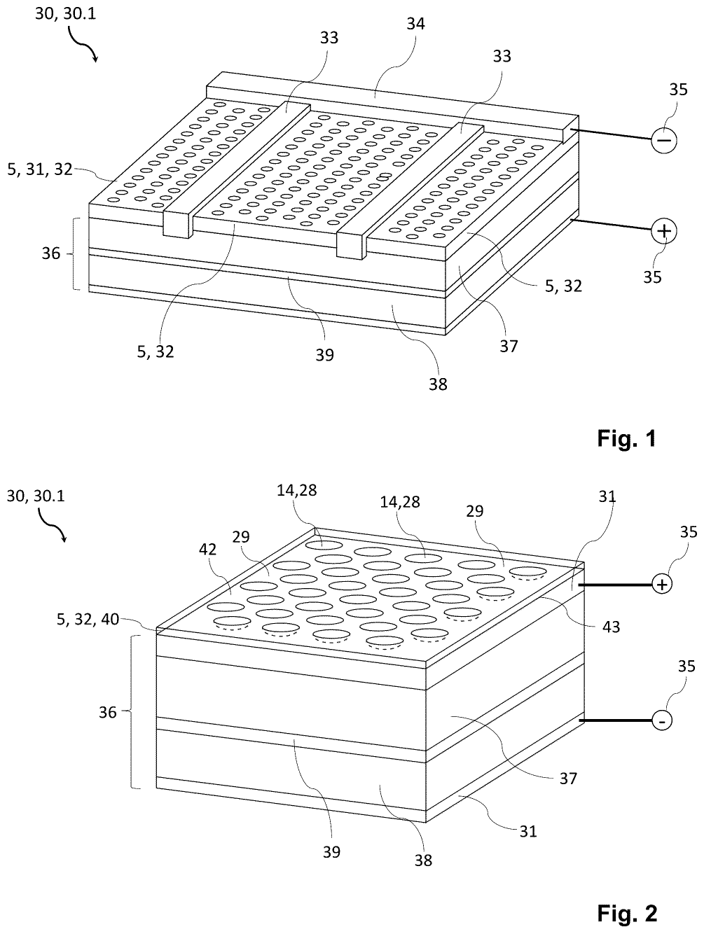

FIG. 1: an optoelectronic device in the form of a photovoltaic cell with a cover layer in the form of a contacting layer.

FIG. 2: An optoelectronic device in the form of a photovoltaic cell with a cover layer in the form of an encapsulation layer.

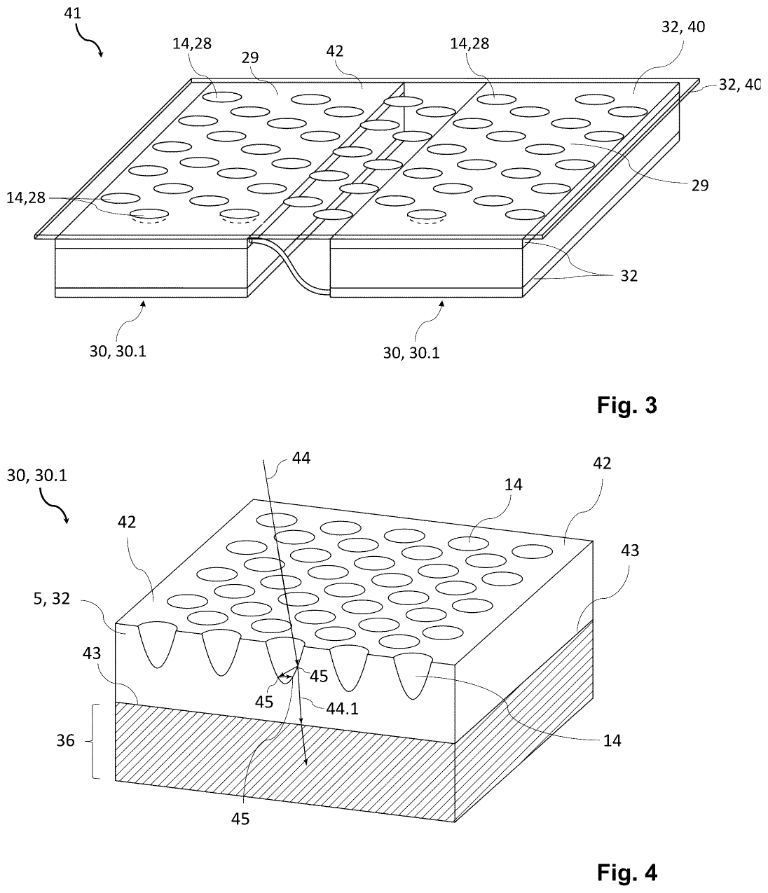

FIG. 3: An optoelectronic module comprising several photovoltaic cells with a cover layer formed as an encapsulation layer.

FIG. 4: A schematic sectional view of a photovoltaic device with structuring on the outer surface of the cover layer.

FIG. 5: A schematic sectional view of a photovoltaic device with a structure on the inner surface of the cover layer.

FIG. 6: A schematic sectional view of an LED with structuring on the inner surface of the cover layer

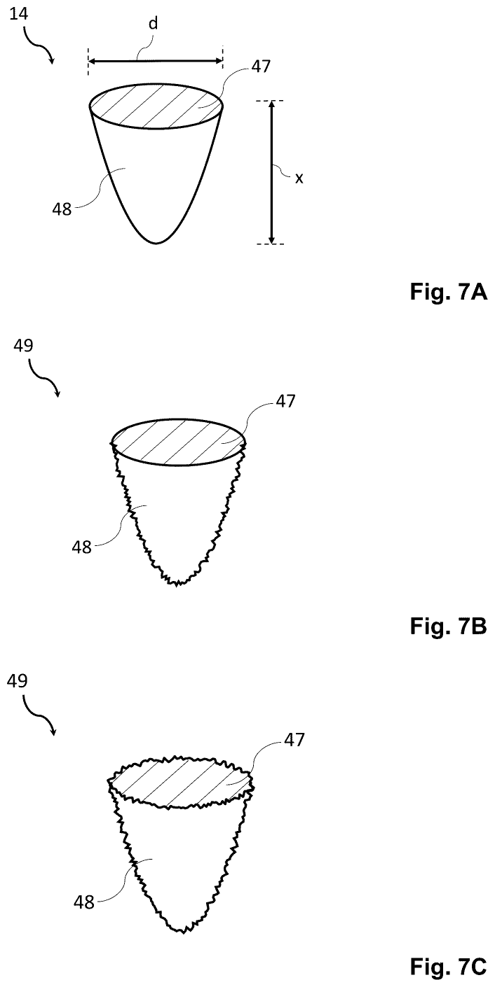

FIG. 7A: a schematic representation of an inverse cone.

FIG. 7B: a schematic representation of a cone-like depression with a circular base.

FIG. 7C: a schematic representation of a cone-like depression with an irregular base.

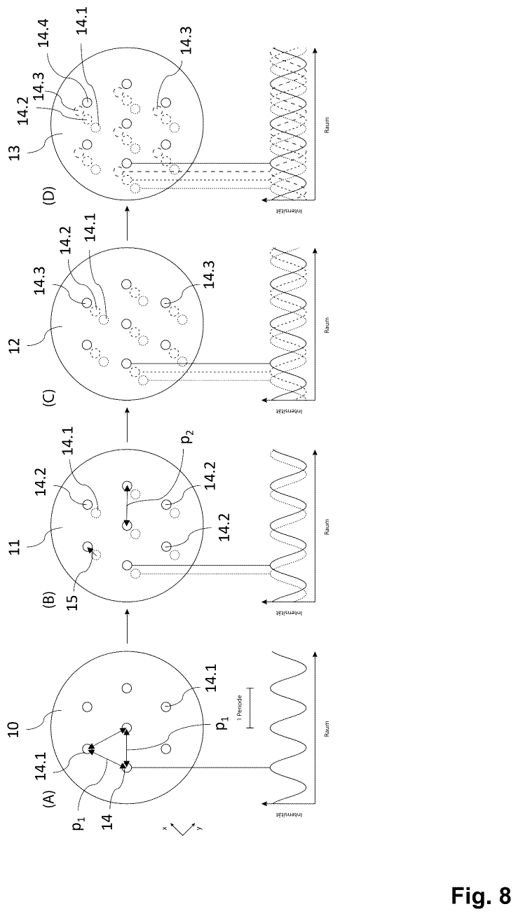

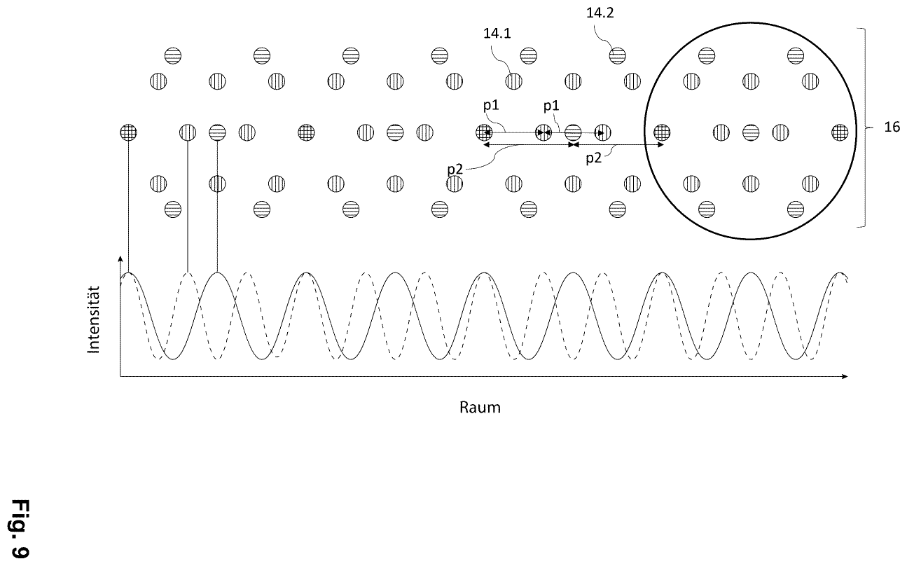

FIG. 8: a cumulative structure of the dot structure from a superposition of several interference pixels

FIG. 9: a dot structure formed from the superposition of several first and second interference pixels

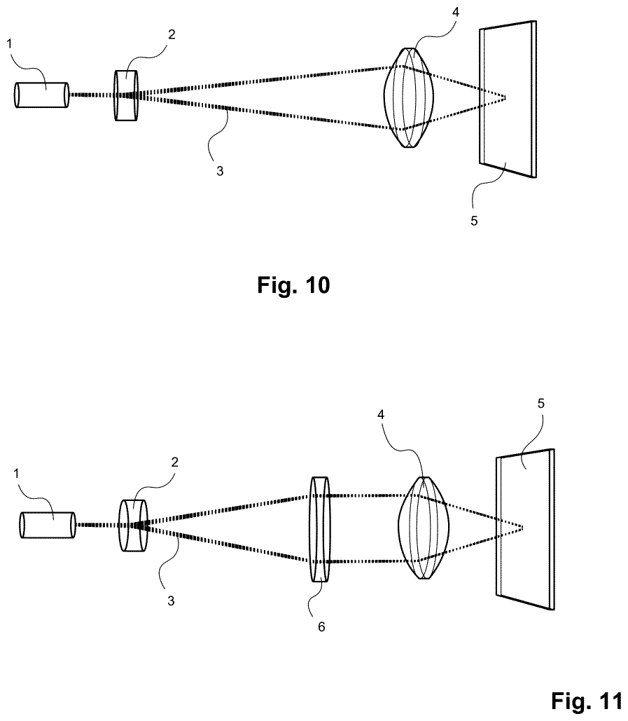

FIG. 10: a schematic perspective view of an apparatus for carrying out the method according to the invention.

FIG. 11: a schematic perspective view of an apparatus for carrying out the method according to the invention, which contains a deflecting element (6) for parallelizing the partial beams.

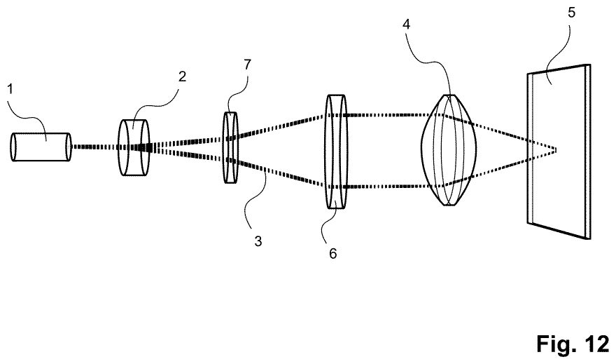

FIG. 12: a schematic perspective view of an apparatus for carrying out the method according to the invention, which contains a deflecting element (7) for widening the angle of the partial beams relative to the optical axis of the beam path (3).

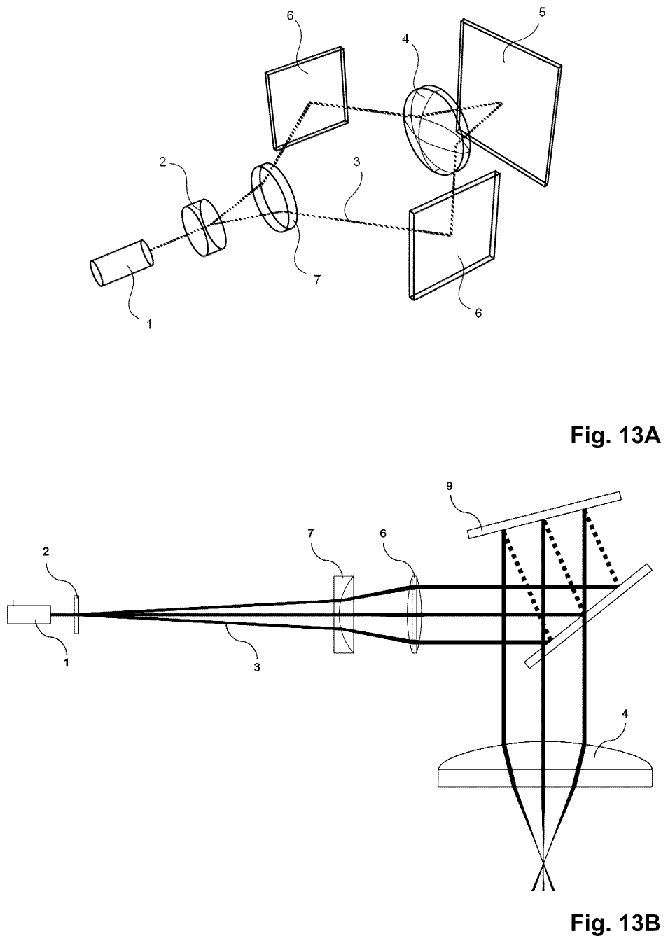

FIG. 13A: a schematic perspective view of an apparatus for carrying out the method according to the invention, which contains optical elements (6) with a planar, reflective surface which deflect the partial beams onto the focusing element (4).

FIG. 13B: a schematic perspective view of an apparatus for carrying out the method according to the invention, which comprises a galvo mirror (9) as an optical element for beam shaping, which permits stationary positioning of the substrate to be patterned during the patterning process.

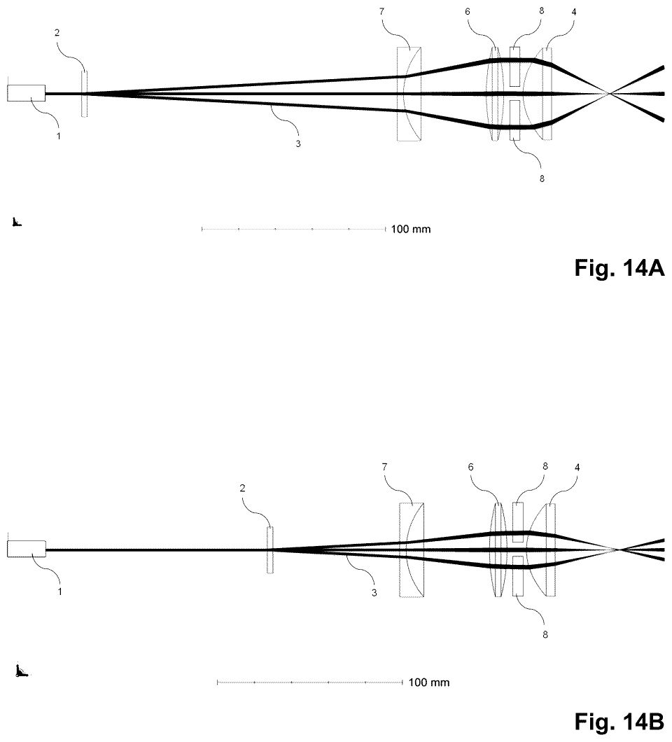

FIG. 14: a schematic perspective view of an apparatus for carrying out the method according to the invention, wherein the apparatus contains a polarization element (8) which shifts the phase course of the partial beams relative to one another, wherein
a) the beam splitter element (2) is positioned in the beam path (3) close to the laser radiation source (1).
the beam splitter element (2) is positioned close to the deflecting element (7) in the beam path (3).

FIG. 15: a schematic view of the interference pixels resulting on the surface or inside the substrate with the width D, and the distribution of the individual interference pixels on the surface or inside the substrate, the interference pixels being shifted relative to one another with the pixel density Pd.

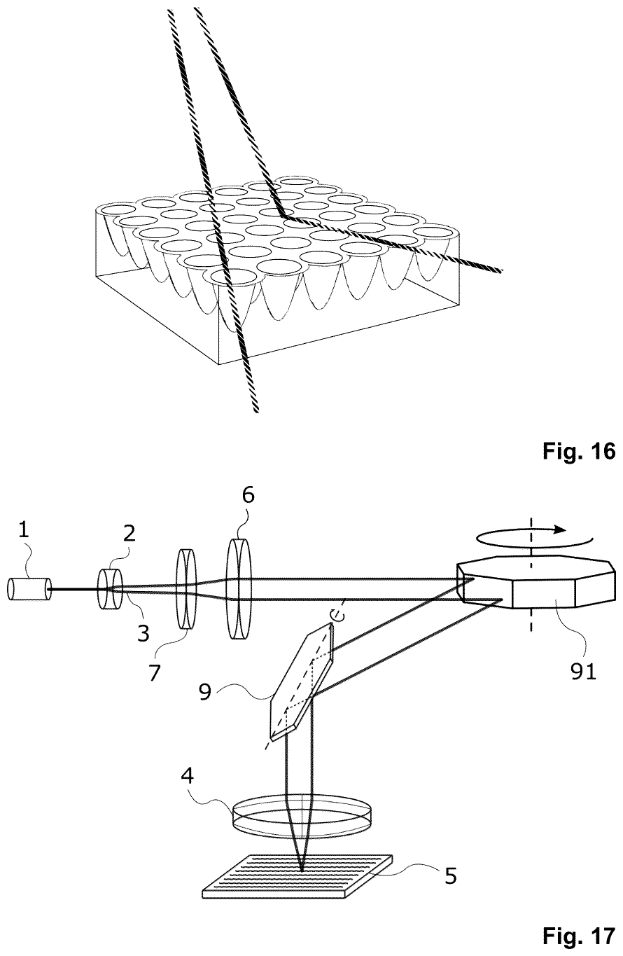

FIG. 16: a schematic perspective view of the patterned substrate (5) with the generated periodic dot structures, consisting of inverse cones, with dimensions in the micro- and sub-micrometer range, and symbolically the transmission of incident electromagnetic waves with wavelengths greater than the interference period of the generated structures, as well as the diffraction of incident electromagnetic waves with wavelengths in the range of or smaller than the generated structures.

FIG. 17: a schematic perspective view of an apparatus for carrying out the method according to the invention, which contains as an optical element a galvo mirror (9) with a planar, reflective surface, which deflects the partial beams onto the focusing element (4), and a polygon wheel (91).

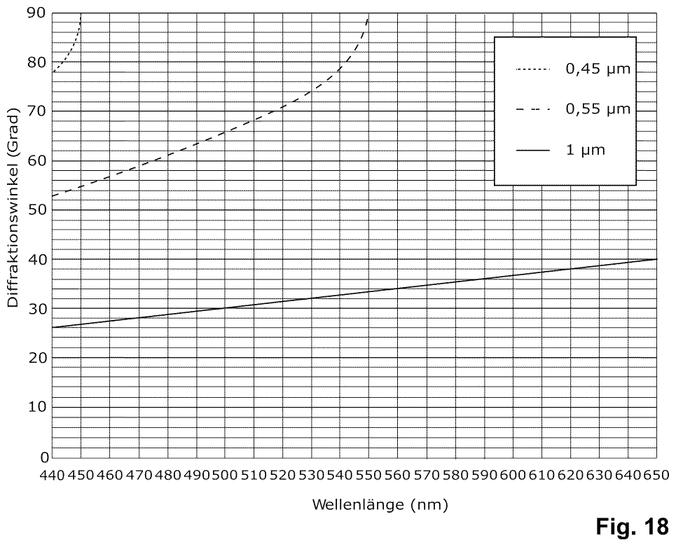

FIG. 18: A graphical representation of the angle of diffraction of incident light versus the wavelength of the incident light for patterned substrates with three different structure widths.

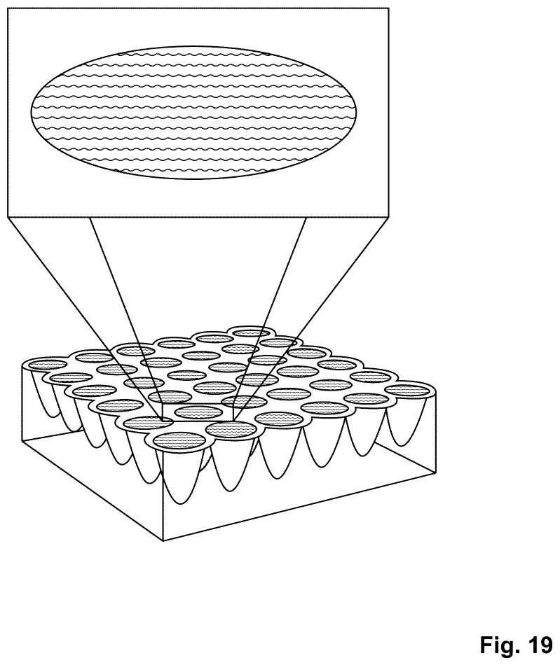

FIG. 19: a schematic perspective view of the patterned substrate (5) with the generated periodic dot structures, consisting of inverse cones, with dimensions in the micrometer range, on which a quasi-periodic wave structure in the sub-micrometer range is superimposed.

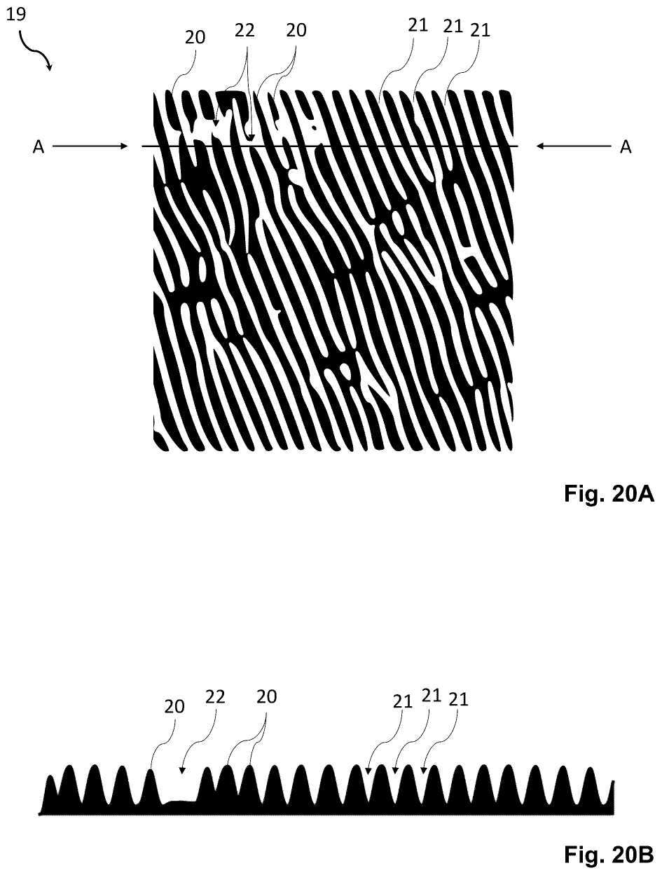

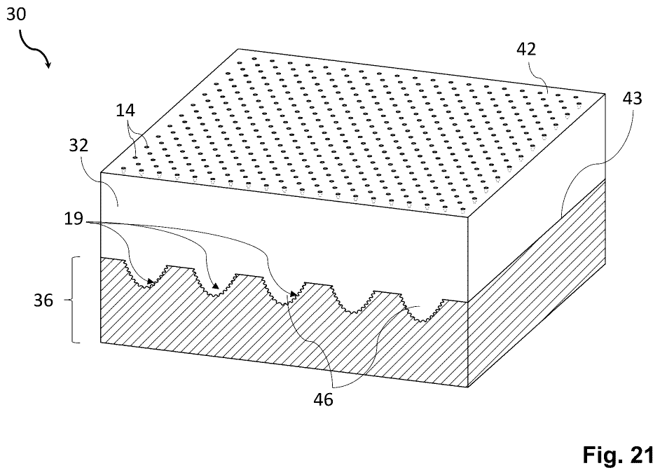

FIG. 20: a schematic
a) plan view and
b) a sectional view
of a quasi-periodic wave structure in the sub-micrometer range.

FIG. 21: an optoelectronic device with a cover layer whose inner surface comprises a superposition of a dot structure and a quasi-periodic wave structure and whose outer surface comprises a dot structure.

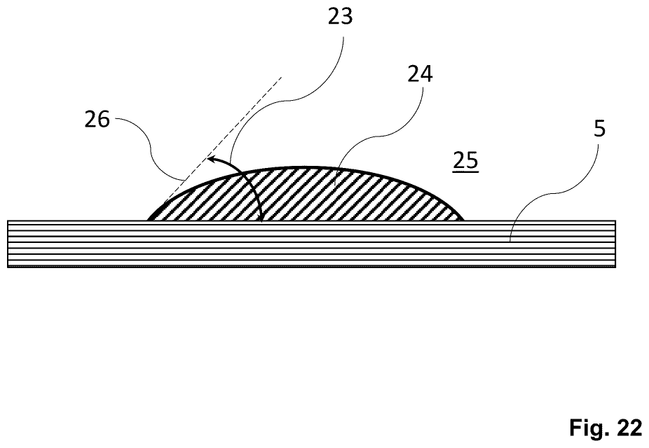

FIG. 22: a visualization of the water contact angle

FIG. 1 shows a perspective, schematic view of an optoelectronic device (30) in the form of a photovoltaic cell (30.1). In this embodiment example, a contacting layer 31 is formed as a cover layer 32. The cover layer (32) is designed as a substrate (5) for sealing off the photovoltaic cell (30.1) from the environment and thus forms an upward seal. In this embodiment example, three cover layers (32) are arranged on the photovoltaic cell (30.1), which are separated from each other by means of contact rails (33), for example made of a metal such as aluminum. The contact bars (33) are electrically connected to a busbar (34), which establishes the electrical connection to an external contact (35).

Functional layers (36) adjacent to the cover layer (32) are arranged underneath the multiple cover layers (32). These comprise an n-doped layer (37), a p-doped layer (38) and a boundary layer (39) arranged therebetween, as well as a further contacting layer (31) for forming an electrical connection to a further external contact (35).

In this embodiment example, the cover layer (32) is formed as an at least partially transparent contacting layer 31, which consists, for example, of a transparent conductive oxide (TCO).

A further embodiment example of an optoelectronic device (30) designed as a photovoltaic device (30.1) is shown in FIG. 2. Here, the cover layer (32) is designed as an encapsulation layer (40) which, as a substrate (5), protects the photovoltaic device (30.1), also photovoltaic cell, from moisture and other environmental influences. The layers (36) adjacent to the cover layer (32) comprise not only the optoelectronically active layers, i.e. in this case the n-doped layer (37), the p-doped layer (38) and the boundary layer (39), but also two contacting layers (31) for establishing the electrical connection to one of the external contacts (35).

The encapsulation layer (40) forms the cover layer (32) and improves the optical properties and efficiency. The cover layer (32) forms a substrate (5) comprising a periodic dot structure formed by inverse cones (14), in particular a first periodic dot structure. A patterned region (28) is formed by the inverse cones (14). The dot structure arranged on the cover layer (32) thus forms the patterned region (28). Furthermore, the cover layer has an unpatterned region (29) that does not comprise any pegs or other structures. The unpatterned region (29) is therefore the entirety of the surface, which comprises no structures, in particular no dot structures and no line structures. The patterned region is in turn the entirety of the surface, which is patterned. The sum of the patterned region (28) and the unpatterned region (29) therefore forms the entire surface, in particular the outer surface (42) or the inner surface (43).

An optoelectronic module 41 with a plurality of photovoltaic devices 30.1, also photovoltaic cells, is shown in FIG. 3. Here, the photovoltaic devices 30.1 are electrically connected to each other, with at least some of the photovoltaic devices 30.1 being connected in series to increase the generated voltage. The cover layer 32 comprises an outer surface 42 with inverse cones 14 and is designed here as an encapsulation layer 40, which protects all the photovoltaic cells 30.1 arranged on the module 41 from environmental influences such as moisture. The inverse cones 14 arranged on the outer surface 42 form the patterned region, whereby the unpatterned region 29 is the section of the surface which comprises no structures, here in particular no inverse cones 14. The surface of the cover layer 32, in particular the outer surface 42, is thus completely divided into the patterned region 28 and the unpatterned region 29.

Preferably, according to a possible embodiment not shown here, one of the contacting layers of the photovoltaic cells is additionally formed as a cover layer with a patterned region 28 comprising cones or inverse cones.

A schematic sectional view of an optoelectronic device is shown in FIG. 4 to visualize the reduction in reflection due to the trap effect. A cover layer 32 formed as a terminating substrate 5 is shown pointing upwards. Functional layers 36 adjacent to the cover layer 32 are shown below the cover layer 32. The cover layer 32 comprises an outer surface 42 and an inner surface 43, with the outer surface facing away from the functional layers 36 adjacent to the cover layer 32. The inner surface 43 of the cover layer 32 faces the functional layers 36 adjacent to the cover layer 32, i.e. is directly adjacent thereto.

The outer surface 42 of the cover layer 32 comprises inverse cones 14, with the sectional view lying straight in a row of inverse cones 14. Light 44 incident on the outer surface 42 also partially strikes an interface point 45 arranged within an inverse cone 14, whereby a portion of the light 44 at this interface point 45 is already transmitted through the interface into the interior of the cover layer 32. However, a further portion of the light 44 is reflected and strikes a further interface point 45 arranged within an inverse cone 14. There, too, a portion of the light 44 is transmitted through the interface between the cover layer 32 and the adjacent layer and a smaller portion is reflected. In this embodiment, this reflected portion also reaches a further interface point 45, where again a portion of the light 44 is transmitted. As a result, the total amount of light 44.1 transmitted through the interface can be significantly increased compared to an outer surface 42 without inverse cones 14.

FIG. 5 shows a sectional view of an optoelectronic device 30 in which the inner surface 43 of the cover layer comprises cones 46. These can be generated, for example, by means of a negative mold comprising inverse cones, which is not shown here.

The light 44 is also partially reflected here at the interface points 45 and this part is directed to further interface points 45, where the light 44 is transmitted proportionally through the interface in each case, i.e. penetrates into the layers 36 adjacent to the interface 32 and is not reflected at the interface. Thus, here too, the total amount of light 44.1 transmitted through the interface can be increased or the total amount of light 44 reflected at the interface can be reduced.

A sectional view of an optoelectronic device 30 in the form of an LED 30.2 is shown in FIG. 6. A cover layer 32 with inverse cones 14 arranged on the inner surface 43 is arranged above the functional layers 36 adjacent to the cover layer 32. The light 44 generated within the functional layers 36 adjacent to the cover layer 32 strikes an interface point 45, where it is proportionally reflected and transmitted. The reflected light 44 again strikes one or more further interface points 45, so that the total amount of transmitted light 44.1 is also increased here. As a result, a larger proportion of the generated light 44 is also decoupled from the LED 30.2.

FIG. 7A shows a schematic view of an inverse cone 14 generated by means of a laser interference process, which has the structure depth x. The base surface 47 of the inverse cone 14 is circular with a diameter d. The side surfaces 48 are smooth.

A schematic representation of a cone-like depression 49, such as can be generated by means of an etching process using a mask with circular openings, not shown here, is shown in FIG. 7B. Although the base surface 47 shown is circular, the side surfaces 48 are irregular in shape.

FIG. 7C shows a schematic view of a cone-like depression 49 with an irregular base surface 47 and irregular, completely variable side surfaces 48. Such a depression is generated, for example, during etching without a mask.

FIG. 8 visualizes the cumulative build-up of the dot structure from a superposition of several interference pixels (10, 11, 12, 13). Each interference pixel (10, 11, 12, 13) consists of several inverse cones (14) introduced into the substrate by means of laser interference patterning.

Subfigure (A) shows the first interference pixel (10), which has several inverse cones (14, 14.1). Subfigure (B) visualizes a superposition of the first interference pixel (10) and the second interference pixel (11), this superposition consisting of inverse cones (14.1) of the first interference pixel (10) and inverse cones (14.2) of the second interference pixel (11).

There is an offset (15) between the first interference pixel (10) and the second interference pixel (11), whereby the inverse cones (14.2) of the second interference pixel (11) are displaced by this offset (15) relative to the inverse cones (14.1) of the first interference pixel (10).

Subfigure (C) visualizes a superposition in which a third interference pixel (12) is additionally superimposed with the first two interference pixels (10, 11). The superimposed structure in subimage (C) thus comprises inverse cones (14.1) of the first interference pixel (10), inverse cones (14.2) of the second interference pixel (11) and inverse cones (14.3) of the third interference pixel (12). In this embodiment example, the third interference pixel (12) is displaced relative to the second interference pixel (11) in the same spatial direction along the x-axis as the second interference pixel (11) is displaced relative to the first interference pixel (10).

Subfigure (D) shows a superimposition in which a fourth interference pixel (13) is also superimposed, whereby this is shifted in a different spatial direction along the y-axis with respect to the third interference pixel (12). Thus, the section in partial image (D) comprises a point structure consisting of a superposition of four interference pixels (10, 11, 12, 13).

The graphs, which are arranged below the interference pixels (10, 11, 12, 13), are used to visualize the periodic structures within an interference pixel (10, 11, 12, 13). Due to the formation of the interference pixels (10, 11, 12, 13) via the process of laser interference patterning, i.e. corresponding to the interference image of the laser (partial) beams, each individual interference pixel (10, 11, 12, 13), which has been formed within an illumination or irradiation process within a selected pulse duration, has a periodic arrangement of the inverse cones (14). The spacing of the inverse cones (14.1) of the first interference pixel (10), which results from the spacing of the intensity maxima of the interference image generating the first interference pixel (10), represents the interference period (p₁). The intensity corresponds to the intensity required to generate the inverse cones (14.1) in the interference pattern of the laser (partial) beams. Thus, the distance between the intensity maxima of the interference image corresponds to the interference period (p1). The second interference pixel (11) has a second interference period (p₂).

FIG. 9 shows a dot structure (16), which is formed from the superposition of several first interference pixels (10) with a first interference period (p₁) and several second interference pixels (11) with a second interference period (p₂). The first interference pixels (10) have inverse cones (14.1), which are shown here with a vertical pattern fill. The second interference pixels (11) have inverse cones (14.2), which are shown with a horizontal pattern fill. The interference period (p₁) of the first interference pixel (10) is smaller than the second interference period (p₂) of the second interference pixel (11).

In an optional setting of the interference pixels (10, 11) such that the number of inverse cones (14.1, 14.2) within the interference pixels (10, 11) is identical, the area of the interference pixels (10, 11) consequently varies, which is visualized here by the circles. One of the first interference pixels (10) is schematically represented here by all inverse cones (14.1) with vertical pattern filling within the smaller circle. One of the second interference pixels is again visualized by the inverse cones (14.2), which are shown with a horizontal pattern structure, within the larger circle.

In this case, the plurality of first interference pixels (10) are arranged adjacent to one another with a repetitive offset and the plurality of first interference pixels (10) thus form a pattern with the interference period (p1). Furthermore, the plurality of second interference pixels (11) are arranged adjacent to each other in a repetitive offset manner and the plurality of second interference pixels (11) thus form a pattern with the second interference period (p₂) which differs from the first interference period (p₁).

The graph below the dot structure (16) visualizes the arrangement of the inverse cones (14.1, 14.2) along a line through the dot structure (16). The maxima of the intensity correspond to the center of the inverse cones (14.1, 14.2). As in FIG. 12, this graph serves to illustrate the principle. The intensity corresponds to the intensity required to generate the inverse cones (14.1, 14.2) in the interference pattern of the laser (partial) beams.

FIG. 10 visualizes in a first embodiment example the apparatus according to the invention, comprising a laser radiation source (1) for emitting a laser beam. A beam splitter element (2) is located in the beam path (3) of the laser beam behind the laser beam source (1) and is arranged movably in the beam path (3). A focusing element (4) is located in the optical path (3) of the laser beam behind the beam splitter element (2). A holding device, on which a substrate (5), preferably extensive and/or transparent substrate, is mounted, is arranged in the optical path (3) of the laser beam behind the focusing element (4).

In this embodiment, the laser radiation source (1) emits a pulsed laser beam. In this case, the laser radiation source is a UV laser with a wavelength of 355 nm and a pulse duration of 12 ps. In this embodiment, the radiation profile of the laser radiation source corresponds to a top-hat profile.

In this embodiment, the beam splitter element (2) corresponds to a diffractive beam splitter element. A diffractive beam splitter element here is a beam splitter element that contains micro- or nanostructures. The beam splitter element (2) divides the laser beam into 4 sub-beams.

In this embodiment, the focusing element (4) corresponds to a refractive, spherical lens that directs the sub-beams, which run essentially parallel to each other, onto the substrate (5), preferably extensive and/or transparent substrate, in such a way that they interfere there in an interference region. In this embodiment, the interference angle corresponds to 27.2°, resulting in a interference period of 550 nm for the periodic dot structure in the same polarization state.

According to this embodiment example, the extensive substrate is irradiated once, resulting in a processing time per structural unit, i.e. per interference pixel, of 12 ps.

The substrate (5), preferably extensive and/or transparent substrate, is a glass, in particular a quartz glass, which is mounted on a holding device so that it can be moved in the xy plane, perpendicular to the optical path of the laser beam emitted by the laser radiation source (1).

FIG. 11 visualizes in a further embodiment the apparatus as described in FIG. 10, additionally comprising a deflecting element (6), which is located in the optical path (3) of the laser after the beam splitter element (2) and the focusing element (4).

In this embodiment, the deflecting element is a conventional, refractive, convex lens. The sub-beams hit the deflecting element (6) in such a way that they are essentially parallel to each other after passing through the deflecting element. This allows the point at which the sub-beams interfere on the surface or inside the substrate to be adjusted.

FIG. 12 visualizes in a further embodiment an apparatus based on the setup shown in FIG. 10 and FIG. 11. In addition, this setup comprises a further deflecting element (6), which is arranged in the optical path (3) of the laser between the beam splitter element (2) and the deflecting element (7).

In this embodiment, the further deflecting element (7) is a conventional, refractive, concave lens. The sub-beams hit the further deflecting element in such a way that their angle to the optical axis of the optical path is widened. This allows the interference angle with which the sub-beams interfere on the surface or inside the substrate, preferably extensive and/or transparent substrate, to be changed.

In this embodiment, all optical elements apart from the beam splitter element (2) are fixed along the optical axis of the optical path (3). The interference angle of the sub-beams on the substrate is set by moving the beam splitter element (2) along the optical axis of the optical path.

FIG. 13A shows in a further embodiment an apparatus as in FIG. 12, comprising the optical elements (6) with a planar, reflective surface, which are configured so that they deflect the sub-beams onto the focusing element (4).

In this embodiment, the at least three sub-beams are deflected onto the substrate at a preferred angle by shifting the optical elements (6). This means that a deflecting element in the form of a lens (reference sign (6) in FIG. 3) can be dispensed with.

FIG. 13B shows a schematic perspective view of a device according to the invention, which comprises a galvo mirror (9) as an optical element for beam shaping, which allows stationary positioning of the substrate to be patterned during the patterning process.

FIG. 14 visualizes in a further embodiment an apparatus as in FIG. 12, additionally comprising one polarization element (8) per sub-beam, which are arranged in the optical path (3) of the laser beam between the deflecting element (6) and the focusing element (4).

The polarization element is arranged in such a way that it changes the polarization of the individual sub-beams in relation to each other in such a way that a change in the interference pattern results.

This embodiment is shown in two different configurations. In FIG. 14 a), the beam splitter element (2) is positioned close to the laser radiation source (1) in the optical path (3). In FIG. 14 b), the beam splitter element (2) is positioned close to the deflecting element (7) in the optical path (3). In this way, the interference pattern of the interfering sub-beams on the surface of the substrate (5) can be infinitely adjusted without having to move the other optical elements in the setup or the substrate.

It would also be conceivable for the arrangement to contain an additional optical element for beam shaping, which is arranged in succession of the laser radiation source (1) in the optical path (3) of the laser beam. In this embodiment, the radiation profile of the laser radiation source corresponds to a Gaussian profile. The optical element for beam shaping converts this profile into a top-hat profile.

FIG. 15 contains a schematic view of the interference pixels resulting on the surface or inside the substrate with the width D, and the distribution of the individual interference pixels on the surface or inside the substrate, whereby the interference pixels are shifted relative to one another with the pixel density Pd.

In this embodiment, the pixel density Pd is smaller than the width of an interference pixel, D. Thus, by moving the substrate (5) by means of a pulsed laser beam, an extensive homogeneous periodic dot structure can be generated on the surface or in the interior of a substrate, preferably extensive and/or transparent substrate.

Preferably, the interference pixels applied one after the other are arranged next to each other. In this embodiment, there is an overlap between two interference pixels arranged next to each other. Due to the multiple irradiation, self-organization processes are preferably stimulated within the patterned region, i.e. within the inverse cones 14. This allows a hierarchical structure to be generated efficiently.

FIG. 16 visualizes the patterned substrate (5) produced by the method according to the invention with the generated periodic dot structures, consisting of inverse cones, with dimensions in the micro- and sub-micrometer range. The transmission of incident electromagnetic waves with wavelengths greater than the interference period of the generated structures and the diffraction of incident electromagnetic waves with wavelengths in the range of or smaller than the generated structures are also symbolically illustrated.

FIG. 17 shows in a further embodiment an apparatus as in FIG. 13B, comprising the optical element (91) with a planar, reflective surface, which is a polygon wheel that is configured so that it rotates about a marked axis. The incident sub-beams are deflected in such a way that they hit a galvo mirror (9), which directs the beams onto the substrate via a focusing element (4). The rotation of the polygon wheel causes the point at which the beams are focused on the substrate to move along a line during the exposure process. The sub-beams therefore scan the substrate, which leads to an increased process speed.

FIG. 18 shows a graphical representation of the transmission and diffraction capability of a patterned substrate as a function of the structure width. The diffraction angle of light is shown as a function of its wavelength for structures with three different structure widths. If the wavelength of the incident light is greater than the structure width, the light is completely transmitted. At wavelengths in the range of the structure width or smaller, diffraction occurs. The diffraction angles can be taken from the diagram.

FIG. 19 visualizes the patterned substrate (5) generated by the method according to the invention with the generated periodic dot structures, consisting of inverse cones, with dimensions in the micrometer range. Superimposed on this periodic dot structure in the micrometer range is a periodic wave structure in the sub-micrometer range, which can also be produced in one production step by the method according to the invention described herein.

FIG. 20A visualizes a quasi-periodic wave structure in a plan view and FIG. 20B in a sectional view, as it is exhibited by a patterned substrate which can be produced by a method disclosed herein, in particular by a multiple irradiation or by a single irradiation with high intensity. The sectional view of FIG. 14B represents a cross-section through the structure shown in FIG. 14A approximately along the sectional line A-A. Self-organization processes occurring in the materials lead to the formation of wave-shaped structures with wave crests 10 and wave troughs 11 within an area irradiated in this way. The resulting structures generally exhibit a certain periodicity, although defects 12, i.e. irregularities, also occur. Thus, in contrast to a truly periodic structure, such a structure exhibits both deviations in the structure dimensions, in particular in the distances between the wave crests and troughs, and defects, so that the generated wave structure is not homogeneous.

FIG. 21 shows an optoelectronic device 30 with a cover layer 32. The cover layer 32 comprises an outer surface 42, which seals the optoelectronic device 30 from the environment, and an inner surface 43. The functional layers 36 adjoining the cover layer 32 are adjacent to the inner surface 43. According to this embodiment, the inner surface 43 comprises cones 46 which form a dot structure, wherein a superimposed structure, which is formed here as a quasi-periodic wave structure 19, is arranged on the cones 46. A periodic dot structure of inverse cones 14 is arranged on the outer surface 42, the interference period of the dot structures on the outer surface 42 being significantly smaller than that of the dot structure on the inner surface 43.

A visualization of the water contact angle 13 is shown in FIG. 22. A liquid 14 is arranged here in droplet form on a substrate 5. Outside the drop of liquid, air is present in the gaseous phase. The water contact angle 13 is the angle between the surface of the substrate 5 and the tangent 16 adjacent to the drop of liquid. The tangent 16 is considered to be in contact with the surface of the substrate 5. To determine the water contact angle 23, a shadow image of a drop of water 24 is usually taken.

### LIST OF REFERENCE SIGNS

1 laser radiation source
2 beam splitter element
3 optical path
4 focusing element
5 substrate
6 further deflecting element
7 deflecting element
8 polarization element
9 focusing mirror or galvo mirror
31 optical axis
91 polygon wheel
10 first interference pixel
11 second interference pixel
12 third interference pixel
13 fourth interference pixel
14 inverse cones
14.1 inverse cones of the first interference pixel
14.1 inverse cones of the second interference pixel
14.1 inverse cones of the third interference pixel
14.1 inverse cones of the fourth interference pixel
15 offset
16 dot structure
p₁ first interference period
p₂ second interference period
19 quasi-periodic wave structure
20 wave crest
21 wave trough
22 defect
23 water contact angle
24 water droplet
25 gaseous phase
26 tangent
A-A cutting line
28 patterned region
29 unpatterned region
30 optoelectronic device
30.1 photovoltaic cell, photovoltaic device
30.2 LED (light-emitting diode)
31 contacting layer
32 cover layer
33 metal rail
34 Busbar
35 External contact
36 Functional layers adjacent to the cover layer
37 n-doped layer
38 p-doped layer
39 Boundary layer
40 Encapsulation layer
41 optoelectronic module
42 outer surface
43 inner surface
44 light
44.1 transmitted light
45 Interface point
46 cone
47 base
48 lateral surface
49 depression
D width of the interference pixel
Pd pixel density
d diameter
x structure depth

1-30. (canceled)

31. An optoelectronic device (30) comprising
a cover layer (32) which has an outer surface (42) and an inner surface (43),
wherein the cover layer (32) is at least partially transparent,
at least one functional layer which is arranged at least partially on the inner surface (43) of the cover layer (32),
wherein the functional layer is an optoelectronically active layer or a contacting layer,
characterized in that the outer surface (42) and/or inner surface (43) is formed from a patterned region (28) and an unpatterned region (29),
wherein the patterned region (28) comprises a first periodic dot structure,
wherein the first dot structure is formed from at least one first interference pixel (10) with a first interference period (p1),
wherein the first interference pixel (10) comprises a periodic lattice of at least three cones (46) or inverse cones (14),
wherein the interference period (p1) of the first periodic dot structure is in the range of 50 nm to 50 μm.

32. The optoelectronic device (30) according to claim 31, wherein the patterned region (28) is formed from the first periodic dot structure, wherein the first periodic dot structure consists of one or more interference pixels arranged with an offset to each other.

33. The optoelectronic device (30) according to claim 31, wherein the patterned region (28) further comprises a second periodic dot structure, wherein the second periodic dot structure is formed of at least one second interference pixel (11) having a second interference period (p2), wherein the second interference pixel (11) comprises a periodic lattice of at least three cones (46) or inverse cones (14) with a second interference period (p2).

34. The optoelectronic device (30) according to claim 31, wherein the patterned region (28) comprises a periodic line structure with an interference period in the micro- or sub-micrometer range.

35. The optoelectronic device (30) according to claim 31, wherein the water contact angle (23) of the outer surface (42) of the cover layer (32) is less than 20° or greater than 130°.

36. The optoelectronic device (30) according to claim 31, wherein the cones (46) or inverse cones (14) of the first interference pixel (10) comprise an average structure depth in the statistical mean d50 in the range of 10 nm to 500 nm, preferably of at most 1 μm.

37. The optoelectronic device (30) according to claim 31, wherein the first dot structure comprises an aspect ratio of at least 0.5 or at most 0.1.

38. The optoelectronic device (30) according to claim 31, wherein the cones (46) or inverse cones (14) of the patterned region (28) comprise side surfaces (48), wherein the side surfaces (48) comprise a superimposed quasi-periodic line structure or a smooth surface.

39. The optoelectronic device (30) according to claim 31, wherein the base surface (47) of the cone (46) or the inverse cone (14) is circular or elliptical.

40. The optoelectronic device (30) according to claim 31, wherein the cover layer (32) comprises a transmittance in a sub-range of the electromagnetic spectrum of at least 50% for each wavelength in the sub-range, preferably in the range of visible light or near-infrared light.

41. The optoelectronic device (30) according to claim 31, wherein the cover layer (32) comprises a first cover layer and a second cover layer.

42. An optoelectronic module (41), comprising at least two optoelectronic devices (30) according to one of the preceding claims.

43. The optoelectronic module (41) according to claim 42, wherein the cover layer (32) is formed as a single-layer or multi-layer cover layer (32) extending over the optoelectronic module (41).

44. A method of manufacturing an optoelectronic device (30, in particular according to claim 31, comprising the following steps:
a) providing a first terminating layer comprising an inner surface (43),
b) applying a functional layer, preferably an optoelectronically active layer or a contacting layer, to at least a partial area of the inner surface (43) of the first terminating layer,
c) applying a second terminating layer to at least a partial area of the functional layer,
wherein the first or the second terminating layer is formed as a cover layer (32) of the optoelectronic device (30),
wherein the cover layer (30) comprises an outer surface (42) and an inner surface (43),
the outer surface (42) and/or the inner surface (43) of the cover layer (32) being formed from a patterned (28) and an unpatterned region (29), or
the outer surface (42) and/or the inner surface (43) of the cover layer (32) being patterned following step (c) so that it is formed from a patterned region (28) and an unpatterned region (29),
wherein the functional layer is an optoelectronically active layer or a contacting layer,
characterized in that
the patterned region (28) comprises a first periodic dot structure
wherein the first dot structure is formed of at least a first interference pixel (10) with a first interference period (p1),
wherein the first interference pixel (10) comprises a periodic lattice of at least three cones (46) or inverse cones (14),
wherein the first interference period (p1) of the first periodic dot structure is in the range of 50 nm to 50 μm.

45. The method according to claim 44, wherein a direct laser interference patterning is generated, wherein the first periodic dot structure is generated by superimposing at least three laser beams.

46. The method according to claim 44, wherein the periodic dot structure is first generated on a negative mold by means of a laser interference process and is applied to the cover layer (32) by means of the negative mold.

47. The method according to claim 44, wherein in the laser interference process partial beams are generated by means of a beam splitter element (2) and the interference period (p) of an interference pixel, preferably the first interference period (p1) of the first interference pixel (10), is continuously adjusted by means of a displacement of the beam splitter element (2), wherein preferably the further optical elements are fixed.

48. The method according to claim 44, wherein the periodic dot structure within an interference pixel is generated by applying a single laser pulse by means of single irradiation.

49. The method according to claim 44, wherein a hierarchical structure with a line structure arranged in the cones (46) or inverse cones (14) is generated by means of multiple irradiation of an interference pixel with identical method parameters.

50. The method according to claim 44, wherein a periodic line and/or dot structure superimposed on the first periodic structure is generated by means of a multiple irradiation with varied process parameters.
